(19) United States
(12) Patent Application Publication
(10) Pub. No.: US 2026/0353791 A1
(43) Pub. Date: Nov. 5, 2026

(54) SEMICONDUCTOR DEVICE AND METHOD

(71) Applicant: Taiwan Semiconductor Manufacturing Co., Ltd., Hsinchu (TW)

(72) Inventors: Ta-Chun Lin, Hsinchu (TW); Jhon Jhy Liaw, Zhudong Township (TW)

(21) Appl. No.: 19/734,720

(22) Filed: Jul. 8, 2026

Related U.S. Application Data
(63) Continuation of application No. 18/797,658, filed on Aug. 8, 2024.

(51) Int. Cl. H10D 84/85; H10D 30/01; H10D 30/43; H10D 30/67; H10D 62/10; H10D 64/01; H10D 84/01; H10D 84/03

(52) U.S. Cl. CPC H10D 84/856; H10D 30/014; H10D 30/43; H10D 30/6735; H10D 30/6757; H10D 62/121; H10D 64/017; H10D 84/0167; H10D 84/0184; H10D 84/038; H10D 30/6736

(57) ABSTRACT

A semiconductor device and the method of forming the same are provided. The semiconductor device may include a first region and a second region. The first region may include a first nanostructure and a second nanostructure, a first gate structure with a first length between the first nanostructure and the second nanostructure, a first dielectric layer on a sidewall of the first gate structure, and a first source/drain region. The second region may include a third nanostructure and a fourth nanostructure, a second gate structure with a second length between the third nanostructure and the fourth nanostructure, a second dielectric layer on a sidewall of the second gate structure, and a second source/drain region. The second length may be larger than the first length. The first dielectric layer and the second dielectric layer may include a same material.

### CROSS-REFERENCE TO RELATED APPLICATIONS

This application is a continuation of U.S. Patent Application No. 18/797,658, filed on Aug. 8, 2024, and entitled “Semiconductor Device and Method,” which application is incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 13D, 14A, 14B, 14C, 15A, 15B, 15C, 16A, 16B, 16C, 17A, 17B, 17C, 18A, 18B, 18C, 19A, 19B, 19C, 20A, 20B and 20C are views of intermediate processes of the manufacturing of a semiconductor device (e.g., a nano-FET), in accordance with some embodiments.

FIGS. 21A, 21B, 21C, 22A, 22B, 22C, 23A, 23B, 23C, 24A, 24B, 24C, 25A, 25B and 25C are views of intermediate processes of the manufacturing of a semiconductor device (e.g., a nano-FET), in accordance with some embodiments.

FIGS. 26A, 26B, 26C, 27A, 27B, 27C, 28A, 28B, 28C, 29A, 29B, 29C, 30A, 30B, 30C, 31A, 31B and 31C are views of intermediate processes of the manufacturing of a semiconductor device (e.g., a nano-FET), in accordance with some embodiments.

FIGS. 32A, 32B, 32C, 33A, 33B, 33C, 34A, 34B, 34C, 35A, 35B, 35C, 36A, 36B, 36C, 37A, 37B and 37C are views of intermediate processes of the manufacturing of a semiconductor device (e.g., a nano-FET), in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices and methods of forming the same. The semiconductor devices may be nano-FETs including n-type regions and p-type regions. The n-type region and the p-type region may each include channel regions, source/drain regions on sidewalls of the channel regions, gate structures between adjacent channel regions, and inner spacers on sidewalls of the gate structures. Some embodiments provide methods of forming the nano-FETs with inner spacers and gate structures in the n-type region having different shapes and sizes from the inner spacers and gate structures in the p-type region. As a result, sufficient electrical insulation between the source/drain regions and the gate structures as well as reduced resistance in the channel regions in the p-type region may be achieved, thereby improving the performance and reliability of the semiconductor devices.

Some embodiments discussed herein are described in the context of a semiconductor device including nano-FETs. However, various embodiments may be applied to dies including other types of transistors (e.g., fin field effect transistors (FinFETs), vertical field-effect transistors (VFETs), complementary field-effect transistors (CFETs), planar transistors, or the like) in lieu of or in combination with the nano-FETs.

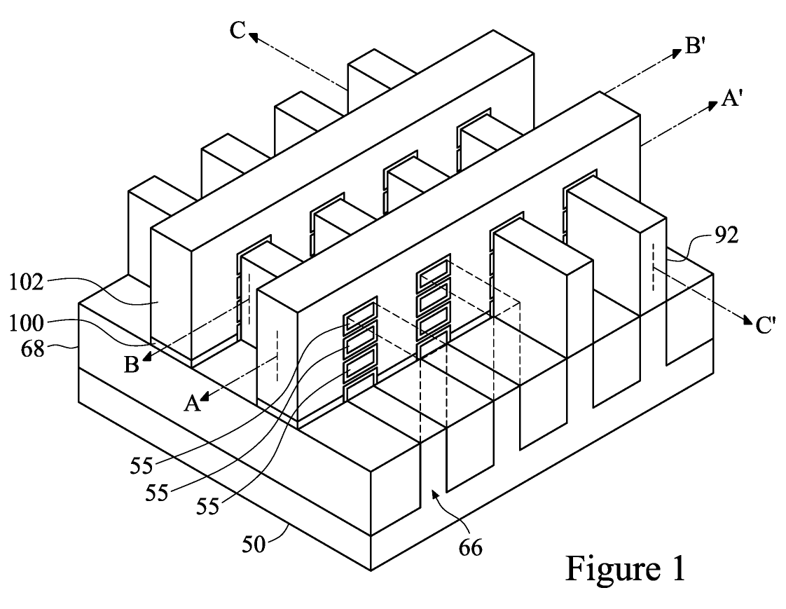

FIG. 1 illustrates an example of nano-FETs (e.g., nanowire FETs, nanosheet FETs, or the like) in a three-dimensional view. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68. Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Reference cross-section A-A’ is along a longitudinal axis of a gate electrode 102 and in a direction, for example, perpendicular to the direction of current flow between the epitaxial source/drain regions 92 of a nano-FET. Reference cross-section B-B’ is parallel to the reference cross-section A-A’ and extends through epitaxial source/drain regions 92 of multiple nano-FETs. Reference cross-section C-C’ is perpendicular to the reference cross-section A-A’ and is parallel to a longitudinal axis of a fin 66 of the nano-FET and in a direction of, for example, a current flow between the epitaxial source/drain regions 92 of the nano-FET. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in FinFETs.

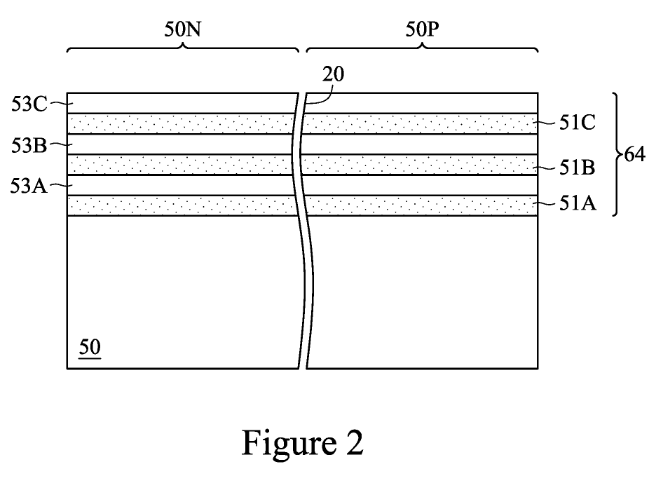

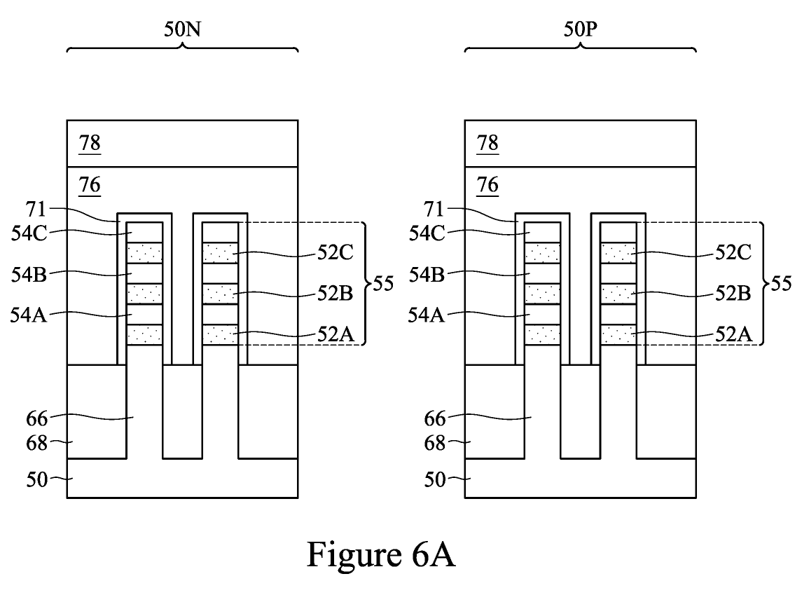

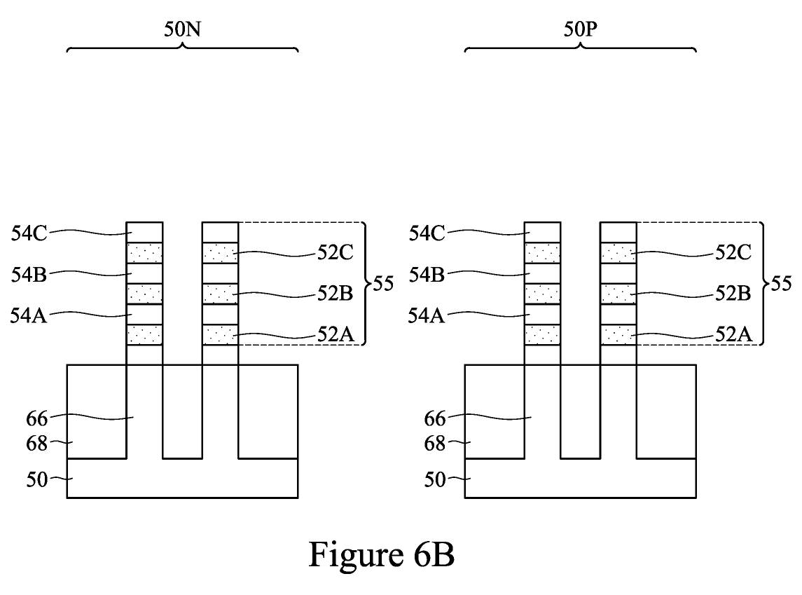

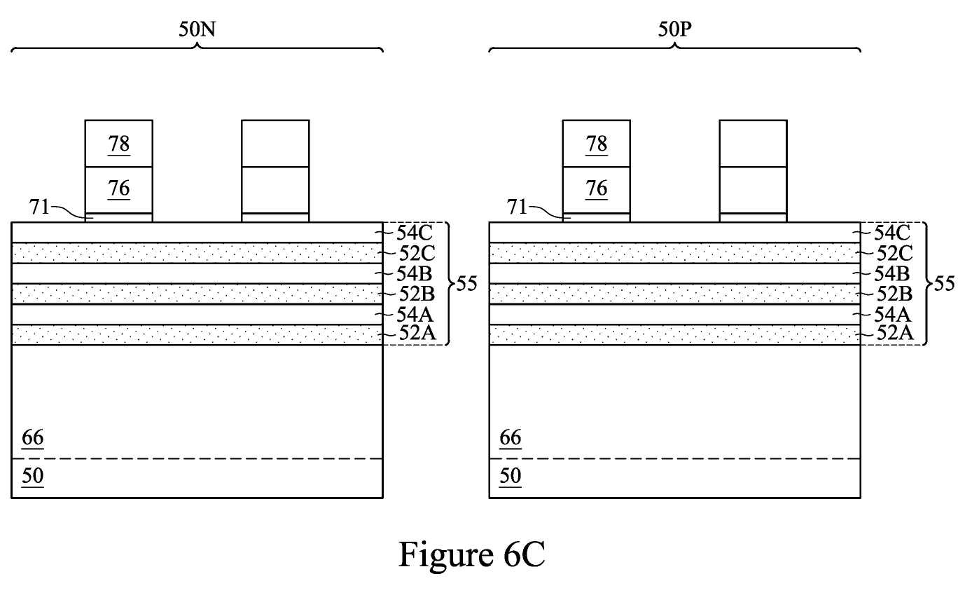

FIGS. 2 -20C are views of intermediate processes of the manufacturing of a semiconductor device (e.g., a nano-FET), in accordance with some embodiments. FIGS. 2, 3, 4, 5, 6A, 7A, 8A, 9A, 10A, 11A, 12A, 13A, 14A, 15A, 16A, 17A, 18A, 19A and 20A illustrate cross-sectional views along the reference cross-section A-A’ illustrated in FIG. 1. FIGS. 6B, 7B, 8B, 9B, 10B, 11B, 12B, 13B, 13D, 14B, 15B, 16B, 17B, 18B, 19B and 20B illustrate cross-sectional views along the reference cross-section B-B’ illustrated in FIG. 1. FIGS. 6C, 7C, 8C, 9C, 10C, 11C, 12C, 13C, 14C, 15C, 16C, 17C, 18C, 19C and 20C illustrate cross-sectional views along the reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 may be removed and the second semiconductor layers 53 may be patterned to form channel regions of nano-FETs in the n-type region 50N and the p-type region 50P. In some embodiments, the first semiconductor layers 51 are removed and the second semiconductor layers 53 are patterned to form channel regions of nano-FETs in the n-type region 50N, and the second semiconductor layers 53 are removed and the first semiconductor layers 51 are patterned to form channel regions of nano-FETs in the p-type region 50P. In some embodiments, the second semiconductor layers 53 are removed and the first semiconductor layers 51 are patterned to form channel regions of nano-FETs in the n-type region 50N, and the first semiconductor layers 51 are removed and the second semiconductor layers 53 are patterned to form channel regions of nano-FETs in the p-type region 50P. In some embodiments, the second semiconductor layers 53 are removed and the first semiconductor layers 51 are patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon or the like.

The first semiconductor materials and the second semiconductor materials may be materials having a high etching selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

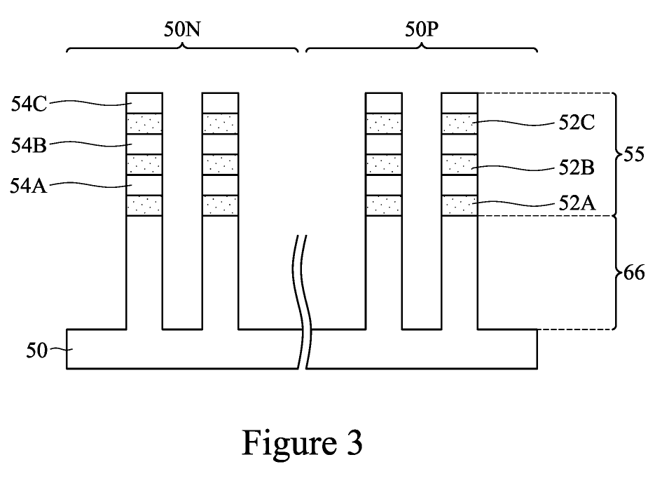

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etching process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

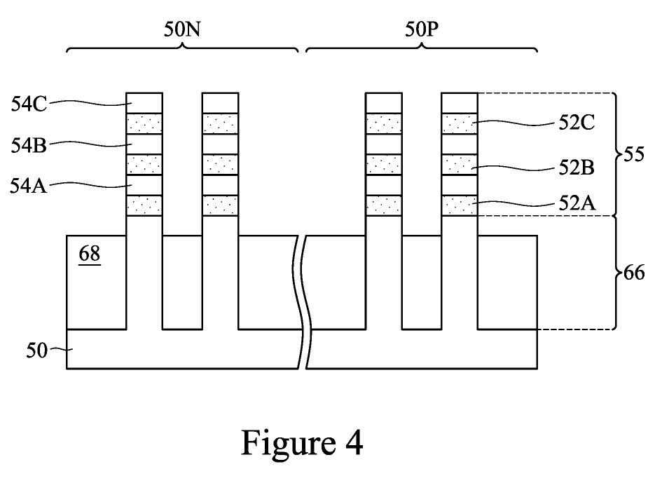

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, such as silicon nitride, the like, or a combination thereof, and may be formed by high-density plasma CVD (HDP-CVD), flowable CVD (FCVD), the like, or a combination thereof. Other insulation materials formed by any acceptable process may be used. An anneal process may be performed once the insulation material is formed. Although the insulation material is illustrated as a single layer, some embodiments may utilize multiple layers.

A removal process may be then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material may be substantially co-planar or level after the planarization process is complete. The insulation material may be then recessed to form the STI regions 68. The insulation material may be recessed such that upper portions of fins 66 in the n-type region 50N and the p-type region 50P protrude from between neighboring STI regions 68. The STI regions 68 may be recessed using an acceptable etching process, such as one that is selective to the material of the insulation material and etches the material of the insulation material at a faster rate than the material of the fins 66 and the nanostructures 55. For example, dilute hydrofluoric acid may be used when the insulation material is an oxide. After the removal process, the top surfaces of the STI regions 68 may have a flat surface as illustrated, a convex surface, a concave surface, or a combination thereof.

The process described above with respect to FIGS. 2 - 4 is one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) are illustrated and discussed herein as comprising the same materials in the p-type region 50P and the n-type region 50N, and the second semiconductor layers 53 (and resulting second nanostructures 54) are illustrated and discussed herein as comprising the same materials in the p-type region 50P and the n-type region 50N for illustrative purposes. In some embodiments, the first semiconductor layers 51 may comprise different materials in the p-type region 50P and the n-type region 50N. In some embodiments, the second semiconductor layers 53 may comprise different materials in the p-type region 50P and the n-type region 50N. In some embodiments, the first semiconductor layers 51 may comprise different materials in the p-type region 50P and the n-type region 50N, and the second semiconductor layers 53 may comprise different materials in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implantation, the photoresist may be removed, such as by an acceptable ashing process. After the implantations of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

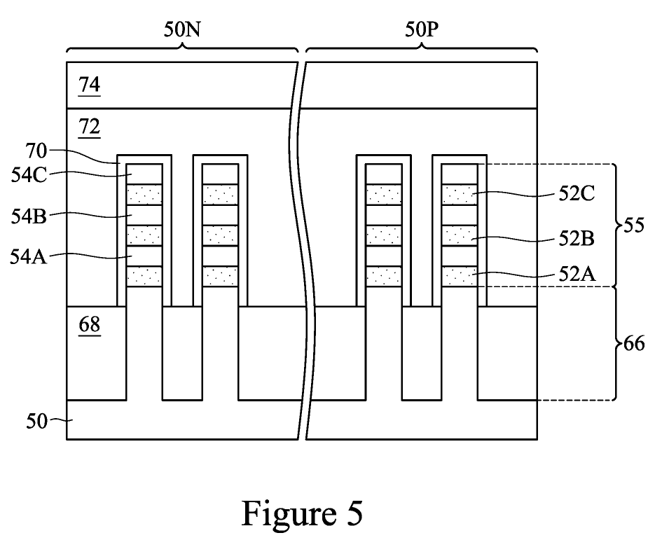

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may comprise a material, which may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may comprise other materials that have a high etching selectivity to the etching of isolation regions. The mask layer 74 may comprise silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A - 20C illustrate various additional processes in the manufacturing of the semiconductor device (e.g., a nano-FET), in accordance to some embodiments. FIGS. 6A - 20C show n-type region 50N and the p-type region 50P as separate regions for illustrative purposes, wherein like numerals refer to like features formed by like processes. The n-type region 50N and the p-type region 50P may be on the same substrate 50 and may be parts of the same semiconductor device.

In FIGS. 6A - 6C, masks 78, dummy gates 76, and dummy gate dielectrics 71 are formed. The dummy gates 76 and dummy gate dielectrics 71 may be collectively referred to as dummy gate structures. The mask layer 74 (see FIG. 5) may be patterned using suitable photolithography and etching processes to form the masks 78. The pattern of the masks 78 then may be transferred to the dummy gate layer 72 and to the dummy dielectric layer 70 to form the dummy gates 76 and the dummy gate dielectrics 71, respectively, using suitable etching processes. The dummy gates 76 cover respective channel regions of the fins 66 and the overlying respective nanostructures 55. The pattern of the masks 78 may be used to separate each of the dummy gates 76 from adjacent dummy gates 76. The dummy gates 76 may also have a lengthwise direction substantially perpendicular to the lengthwise direction of respective fins 66.

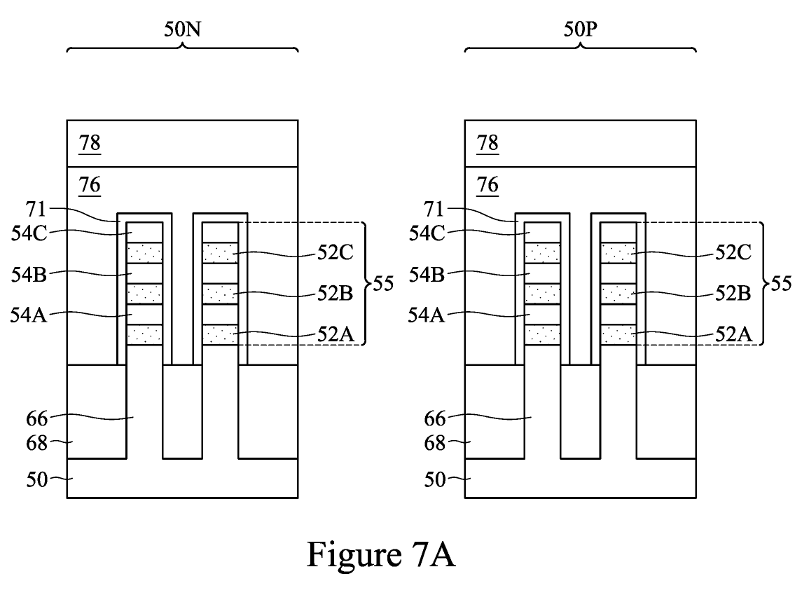

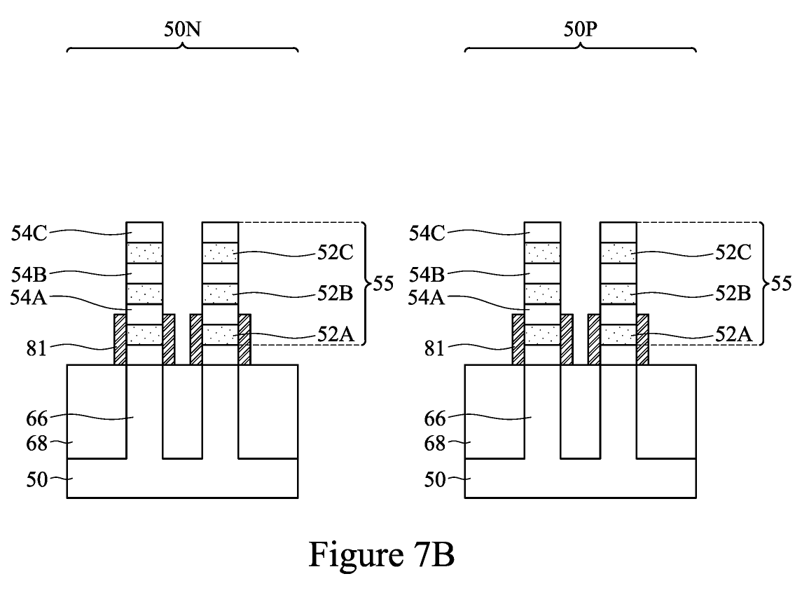

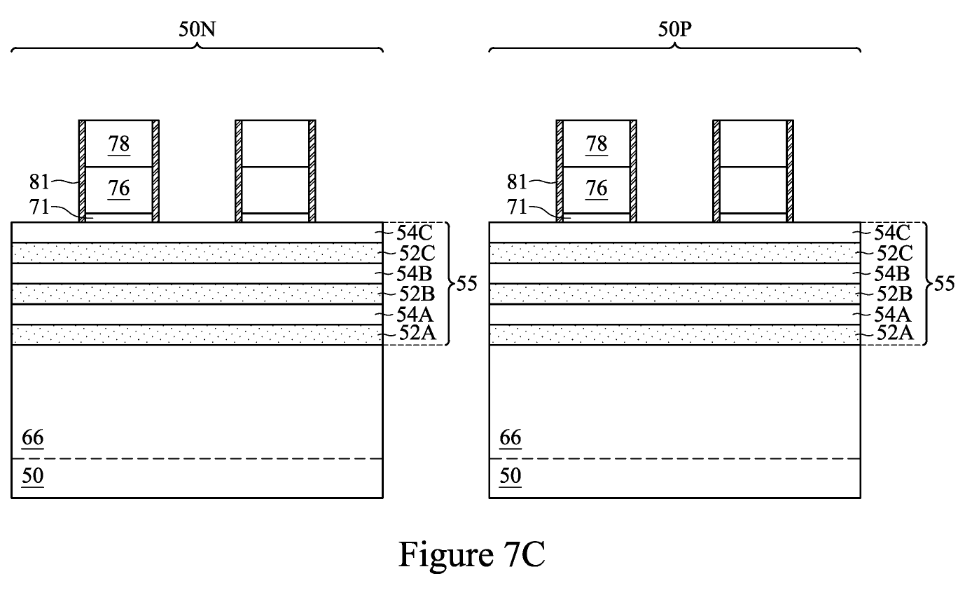

In FIGS. 7A - 7C, spacers 81 are formed. The spacers 81 may self-align subsequently formed source/drain regions, as well as protect the dummy gate dielectrics 71 and the dummy gate 76 during subsequent etching processes. The spacers 81 may be a single layer of one material or multiple sub-layers of different materials with different etch rates. In some embodiments, the spacers 81 comprise two sub-layers with different materials of different etch rates, which may be selected from silicon oxide, silicon nitride, silicon oxynitride, or the like. The spacers 81 may be formed by forming a spacer layer by thermal oxidation or a suitable deposition process, such as CVD, ALD, or the like, and then patterning the spacer layer by a suitable etching process, such as an isotropic etching process (e.g., a wet etching process), an anisotropic etching process (e.g., a dry etching process), or the like. The spacer layer may be formed on top surfaces of the STI regions 68; top surfaces and sidewalls of the fins 66, the nanostructures 55, and the masks 78; and sidewalls of the dummy gates 76 and the dummy gate dielectrics 71. After the etching process, the spacers 81 may remain on sidewalls of the fins 66 and/or nanostructures 55 as illustrated in FIG. 7B; and sidewalls of the masks 78, the dummy gates 76, and the dummy gate dielectrics 71 as illustrated in FIG. 7C.

In the embodiments in which the spacers 81 comprise two sublayers with different materials, after the first sublayer is formed and prior to forming the second sublayer, implants for lightly-doped source/drain (LDD) regions (not separately illustrated) may be performed. Similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly-doped source/drain regions may have a concentration of impurities in a range from about 1x10¹⁵ atoms/cm³to about 1x10¹⁹ atoms/cm³. An annealing may be used to repair implant damage and to activate the implanted impurities.

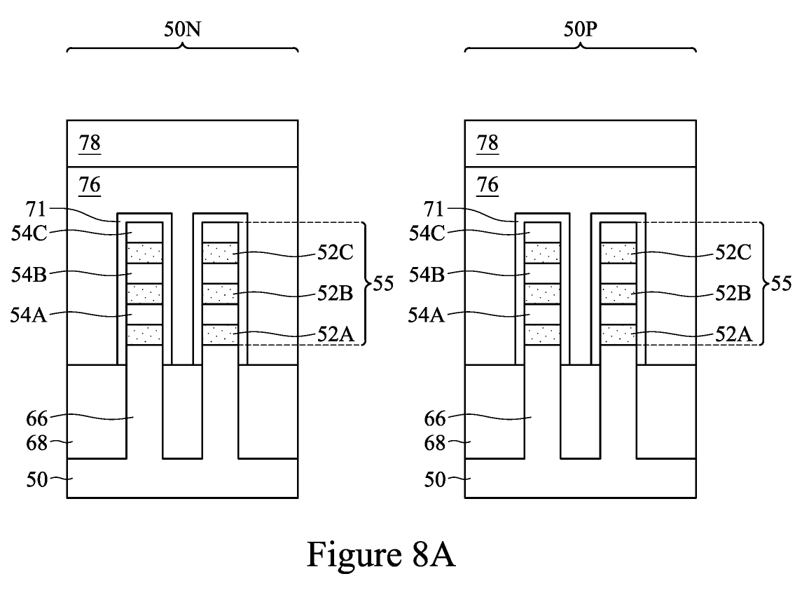

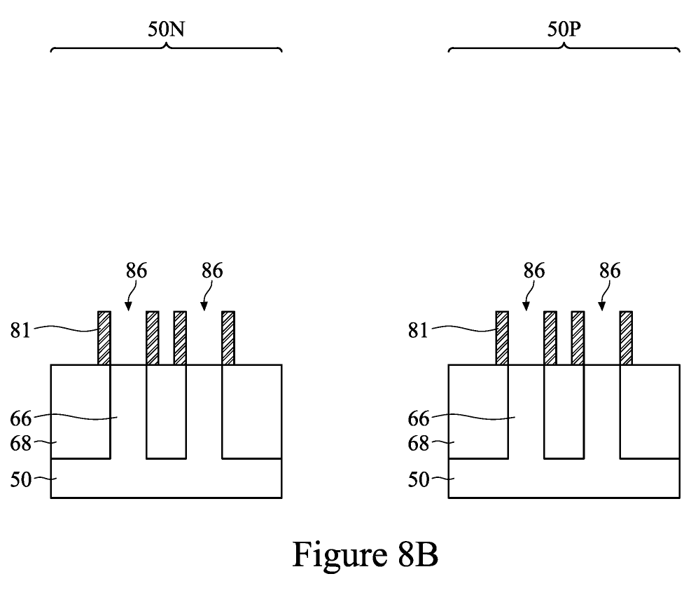

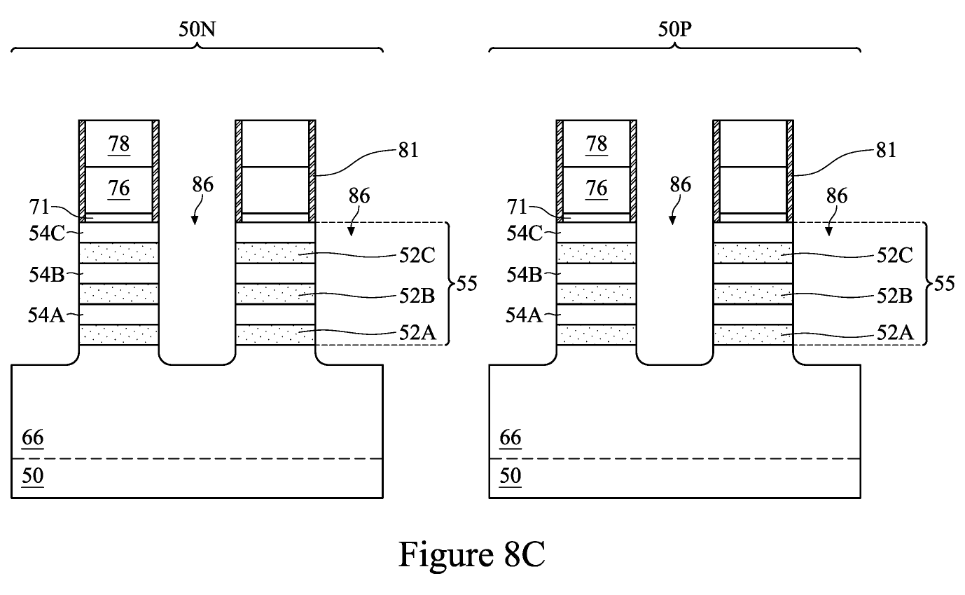

In FIGS. 8A - 8C, first recesses 86 are formed in the fins 66 and the nanostructures 55. The first recesses 86 may extend through the first nanostructures 52 and the second nanostructures 54, and into the fins 66. As illustrated in FIG. 8B, top surfaces of the STI regions 68 (e.g., top surfaces of the fins 66) may be level with bottom surfaces of the first recesses 86. In some embodiments, the bottom surfaces of the first recesses 86 are disposed below the top surfaces of the STI regions 68. The first recesses 86 may be formed by etching the fins 66, the nanostructures 55, and the substrate 50 using anisotropic etching processes, such as RIE, NBE, or the like. The spacers 81 and the masks 78 may mask portions of the fins 66, the nanostructures 55, and the substrate 50 during the etching processes used to form the first recesses 86. A single etching process or multiple etching processes may be used to etch each layer of the nanostructures 55 and/or the fins 66. Timed etching processes may be used to stop the etching after the first recesses 86 reach desired depths.

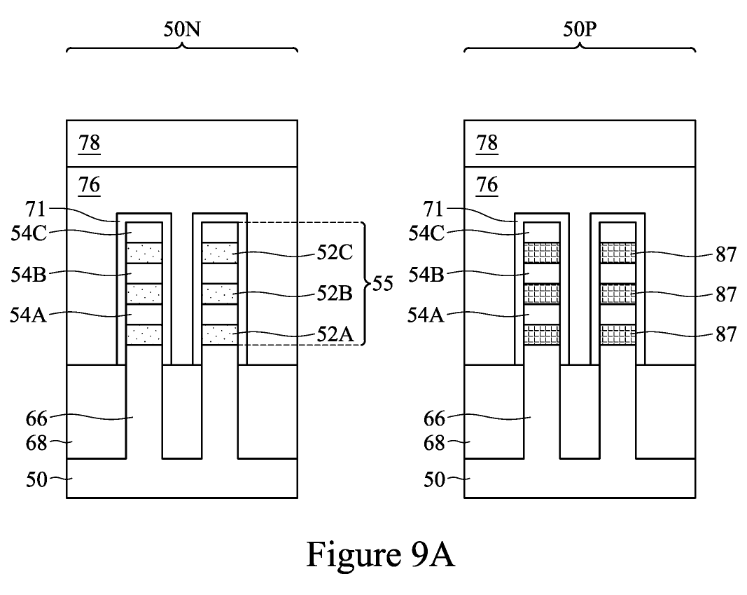

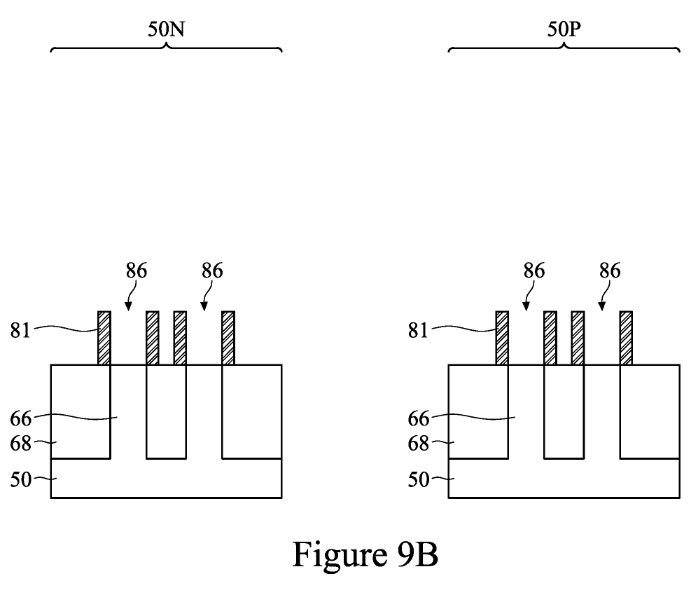

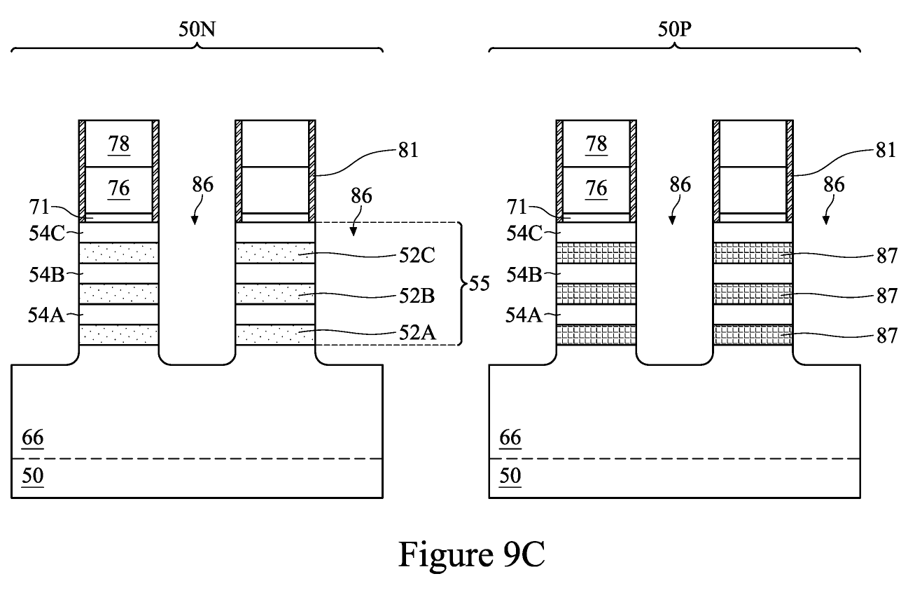

In FIGS. 9A - 9C, the first nanostructures 52 in the p-type region 50P are replaced with first sacrificial layers 87. Replacing the first nanostructures 52 with the first sacrificial layers 87 in the p-type region 50P may reduce or prevent defects from forming on surfaces of the second nanostructures 54 adjacent the first nanostructures 52 during subsequent annealing processes. The n-type region 50N may be covered and protected by a hard mask (not separately illustrated) during the replacement process. The hard mask may be formed by a suitable photolithography process. The replacement process in the p-type region 50P may include first removing the first nanostructures 52 using a suitable etching process, such as an isotropic etching process, performed through the first recesses 86. The etching process may be a wet or drying etching process using fluorine based chemicals as etchants. The etching process may selectively remove the material of the first nanostructures 52 without significantly removing materials of the second nanostructures 54 or the semiconductor fins 66.

Subsequently, the first sacrificial layers 87 may be formed in spaces where the first nanostructures 52 occupied before being removed in the p-type region 50P. The first sacrificial layers 87 may be formed by a suitable deposition process, such as CVD, ALD, or the like. The first sacrificial layers 87 layer may comprise a first dielectric material, such as silicon nitride, silicon oxide, silicon oxynitride, silicon carbonitride, silicon oxycarbonitride, silicon oxycarbide, or the like. The first dielectric material may have a high etching selectivity to the second nanostructures 54 and other subsequently formed features as described in greater details below. The hard mask covering and protecting the n-type region 50N may be removed after the replacement process in the p-type region 50P.

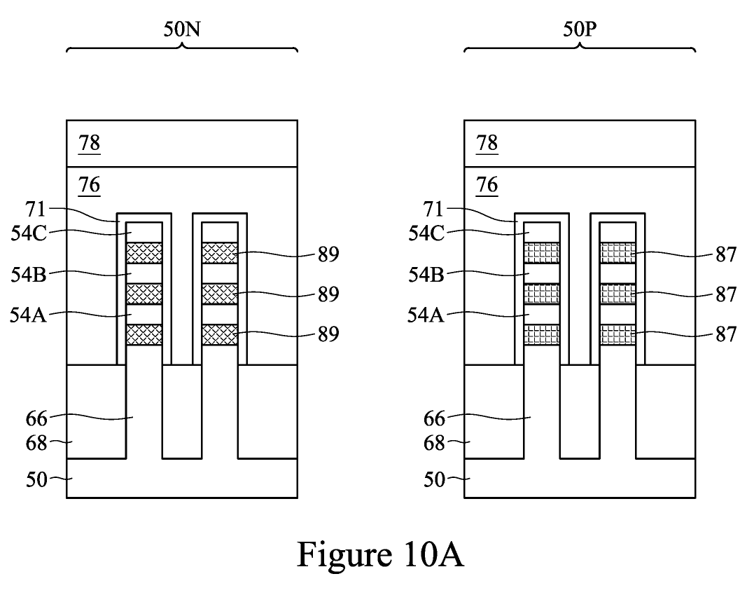

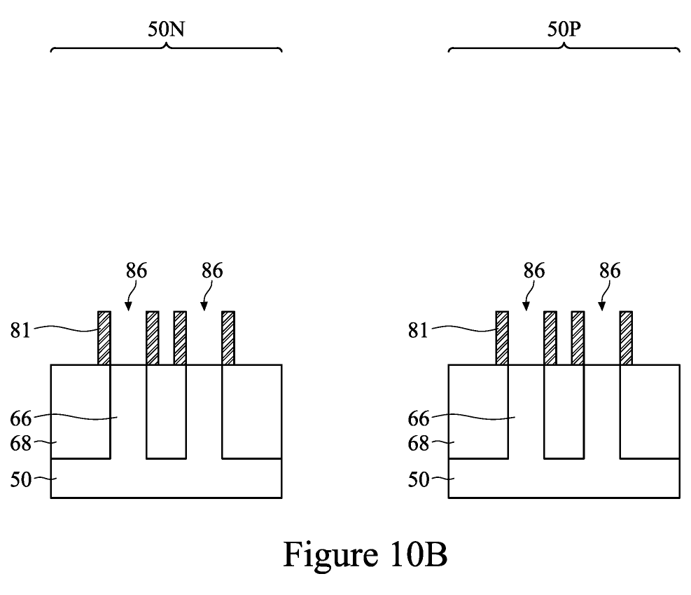

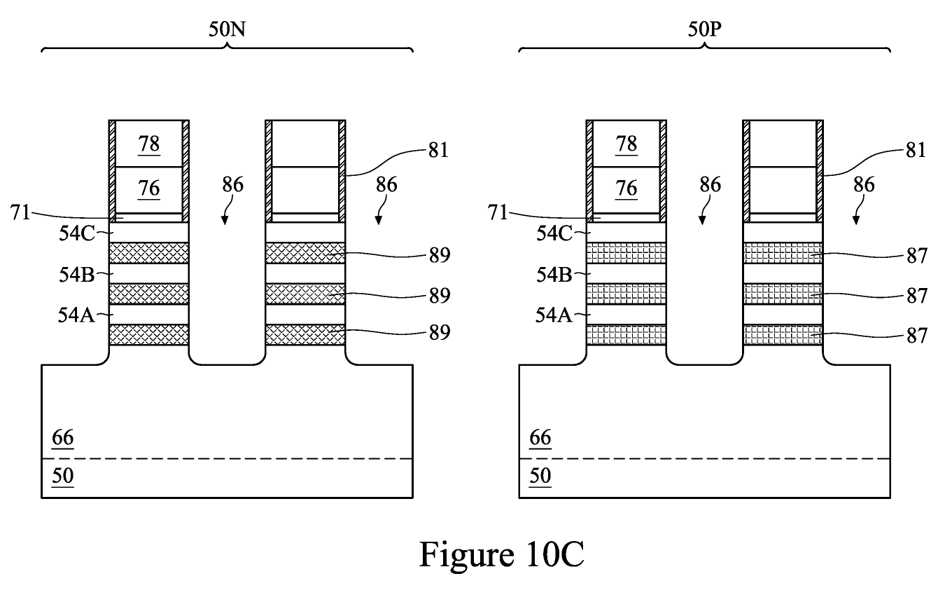

In FIGS. 10A - 10C, the first nanostructures 52 in the n-type region 50N are replaced with second sacrificial layers 89. Replacing the first nanostructures 52 with the second sacrificial layers 89 in the n-type region 50N may reduce or prevent defects from forming on surfaces of the second nanostructures 54 adjacent the first nanostructures 52 during subsequent annealing processes. The p-type region 50P may be covered and protected by a hard mask (not separately illustrated) during the replacement process. The hard mask may be formed by a suitable photolithography process. The replacement process in the n-type region 50N may include first removing the first nanostructures 52 using a suitable etching process, such as an isotropic etching process, performed through the first recesses 86. The etching process may be a wet or drying etching process using fluorine based chemicals as etchants. The etching process may selectively remove the material of the first nanostructures 52 without significantly removing materials of the second nanostructures 54 or the semiconductor fins 66.

Subsequently, the second sacrificial layers 89 may be formed in spaces where the first nanostructures 52 occupied before being removed in the n-type region 50N. The second sacrificial layers 89 may be formed by a suitable deposition process, such as CVD, ALD, or the like. The second sacrificial layers 89 layer may comprise a second dielectric material, such as silicon nitride, silicon oxide, silicon oxynitride, silicon carbonitride, silicon oxycarbonitride, silicon oxycarbide, or the like. In some embodiments, the chemical composition of the second dielectric material in the second sacrificial layers 89 is different from the chemical composition of the first dielectric material in the first sacrificial layers 87. In some embodiments, the chemical composition of the second dielectric material in the second sacrificial layers 89 is same as the chemical composition of the first dielectric material in the first sacrificial layers 87, and the density of the first dielectric material is higher than the density of the second dielectric material. The second dielectric material may have a high etching selectivity to the first dielectric material, the second nanostructures 54, and other subsequently formed features as described in greater details below. The hard mask covering and protecting the p-type region 50P may be removed after the replacement process in the n-type region 50N.

FIGS. 9A - 10C illustrate forming the first sacrificial layers 87 in the p-type region 50P before forming the second sacrificial layers 89 in the n-type region 50N as an example. In some embodiments, the second sacrificial layers 89 are formed in the n-type region 50N before the first sacrificial layers 87 are formed in the p-type region 50P.

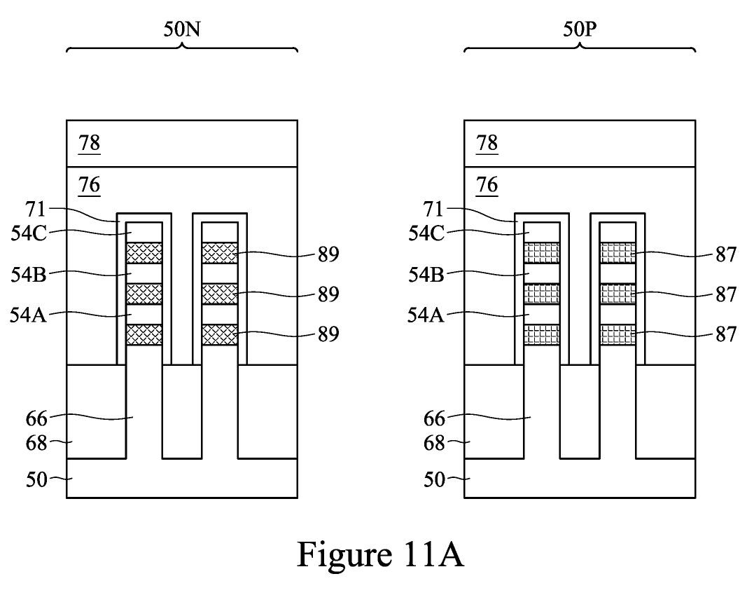

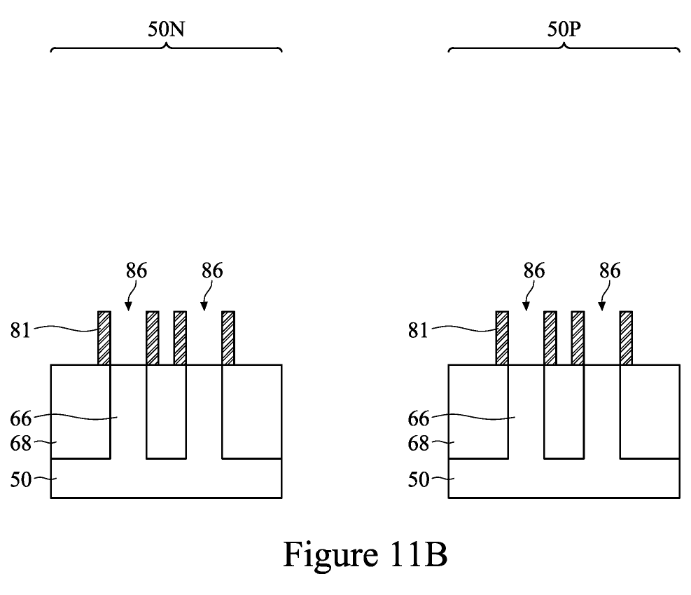

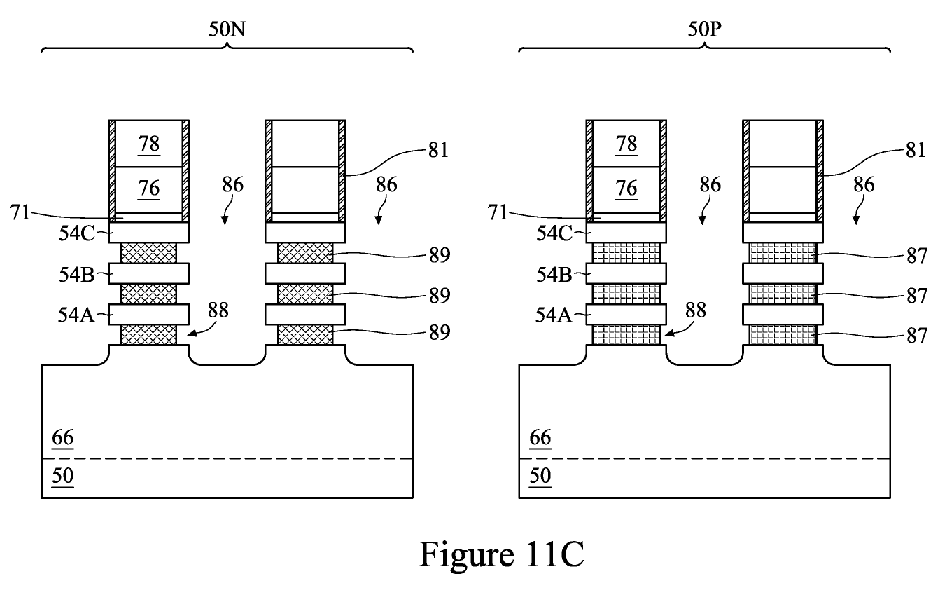

In FIGS. 11A - 11C, the first sacrificial layers 87 in the p-type region 50P and the second sacrificial layers 89 in the n-type region 50N are partially removed by an etching process to form second recesses 88. During the etching process, the second sacrificial layers 89 may be etched at a faster rate than the first sacrificial layers 87, and the second nanostructures 54 and the semiconductor fins 66 may be substantially intact. After the etching process, sidewalls of the first sacrificial layers 87 may be recessed from sidewalls of the second nanostructures 54 in the p-type region 50P and sidewalls of the second sacrificial layers 89 may be recessed from sidewalls of the second nanostructures 54 in the n-type region 50N. The second sacrificial layers 89 may be further recessed than the first sacrificial layers 87. The first sacrificial layers 87 may be wider than the second sacrificial layers 89. In the embodiments illustrated in FIG. 11C, the sidewalls of the first sacrificial layers 87 and the sidewalls of the second sacrificial layers 89 are substantially straight. The etching process may be a wet or drying isotropic etching process using fluorine based chemicals as etchants.

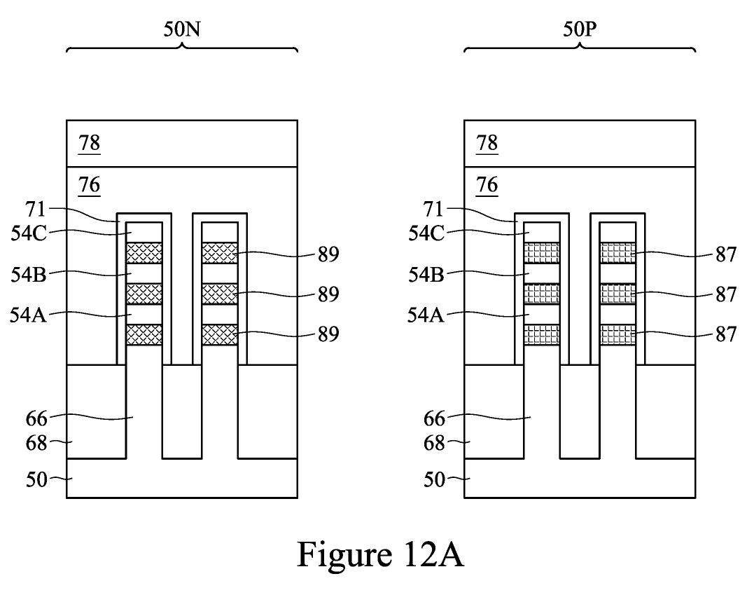

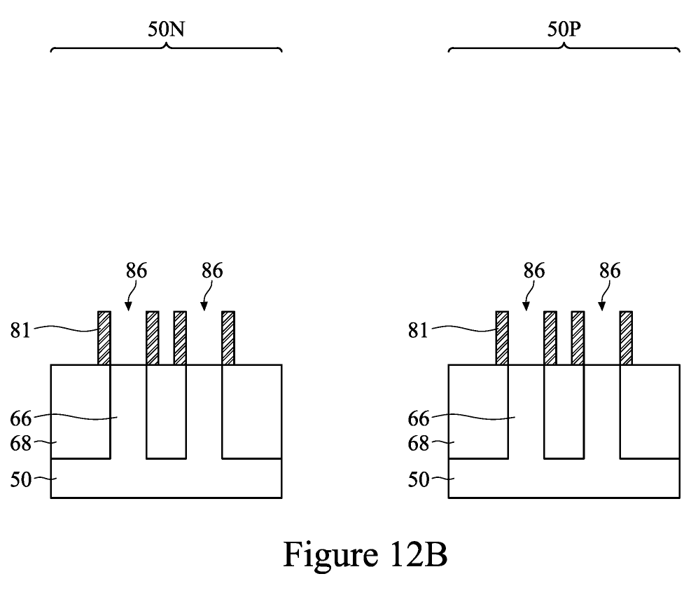

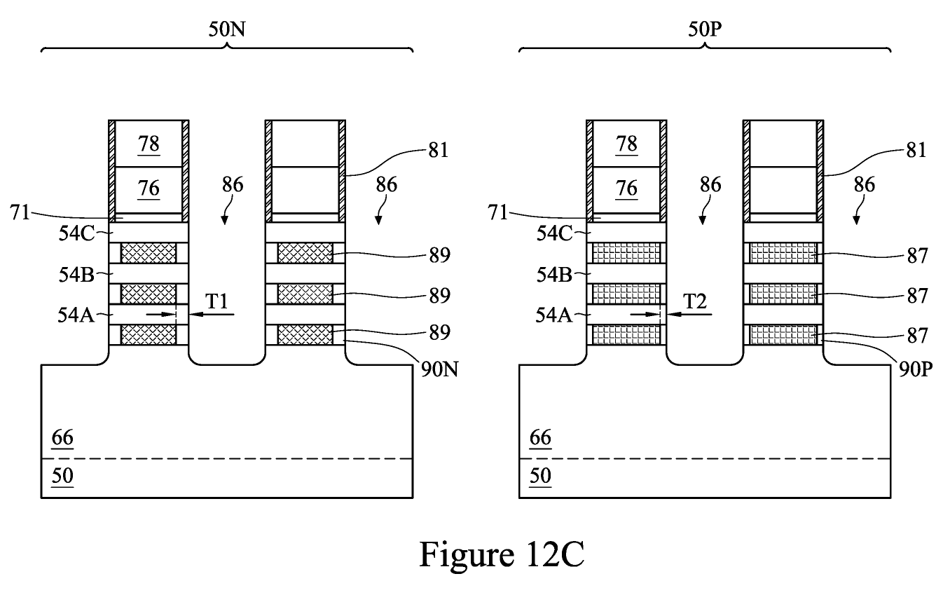

In FIGS. 12A - 12C, inner spacers 90N are formed in the second recesses 88 in the n-type region 50N and inner spacers 90P are formed in the p-type region 50P. The inner spacers 90P may extend along sidewalls of the first sacrificial layers 87 in the p-type region 50P and the inner spacers 90N may extend along sidewalls of the second sacrificial layers 89 in the n-type region 50N. The inner spacers 90P and the inner spacers 90N may be in contact with top surfaces and bottom surfaces of the second nanostructures 54, as well as top surfaces of the fins 66. The inner spacers 90N may comprise a same material as the inner spacers 90P. The material of the inner spacers 90N may have a high etching selectivity to the second sacrificial layers 89 and the second nanostructures 54. The material of the inner spacers 90P may have a high etching selectivity to the first sacrificial layers 87 and the second nanostructures 54.

The inner spacers 90N may have a thickness T1 and the inner spacers 90P may have a thickness T2. The thickness T1 may be a width of top surfaces or bottom surfaces of the inner spacers 90N in contact with the second nanostructures 54 or the fins 66 in the n-type region 50N. The thickness T2 may be a width of top surfaces or bottom surfaces of the inner spacers 90P in contact with the second nanostructures 54 or the fins 66 in the p-type region 50P. The thickness T1 may be larger than the thickness T2, which may lead to sufficient electrical insulation between the subsequently formed source/drain regions and the subsequently formed gate structures as well as reduced resistance in the channel regions (e.g., the second nanostructures 54) in the p-type region 50P as discussed in greater details below. The thickness T1 may be in a range from about 1 nm to about 50 nm. The thickness T2 may be in a range from about 0.5 nm to about 49.5 nm.

The inner spacers 90N and the inner spacers 90P may be formed by depositing an inner spacer layer (not separately illustrated) over the structures shown in FIGS. 11A - 11C in the n-type region 50N and the p-type region 50P, and then etching the inner spacer layer. The inner spacer layer may be formed by a suitable deposition process, such as CVD, ALD, or the like. The inner spacer layer may comprise a dielectric material, such as silicon nitride, silicon oxynitride, silicon oxycarbonitride, or the like. The inner spacer layer may comprise a material different from the materials of the first sacrificial layers 87 and the second sacrificial layers 89. The inner spacer layer may be etched to form the inner spacers 90N and the inner spacers 90P by an anisotropic etching process, such as RIE, NBE, or the like. Outer sidewalls of the inner spacers 90N and the inner spacers 90P are illustrated in FIG. 12C as being flush with sidewalls of the second nanostructures 54 as an example, the outer sidewalls of the inner spacers 90 may extend beyond or be recessed from sidewalls of the second nanostructures 54 in some embodiments.

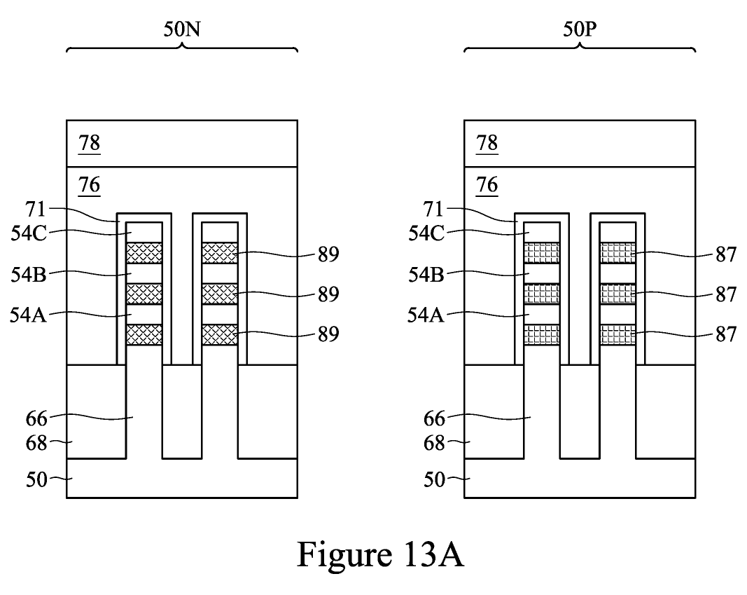

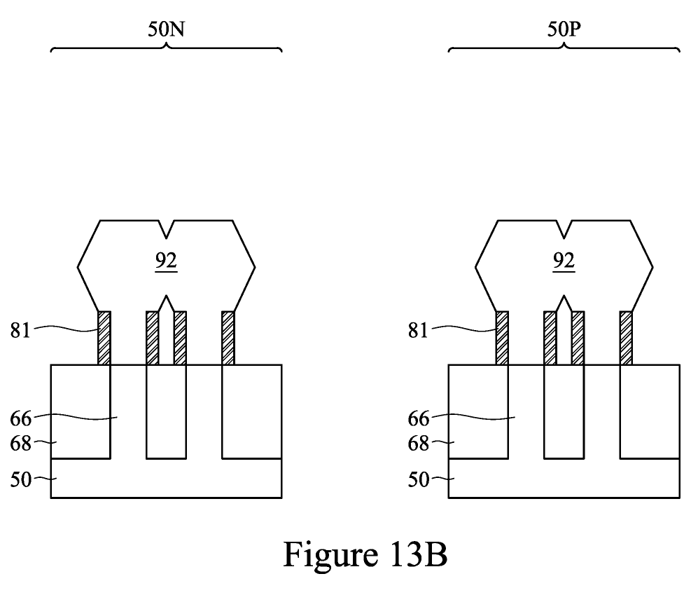

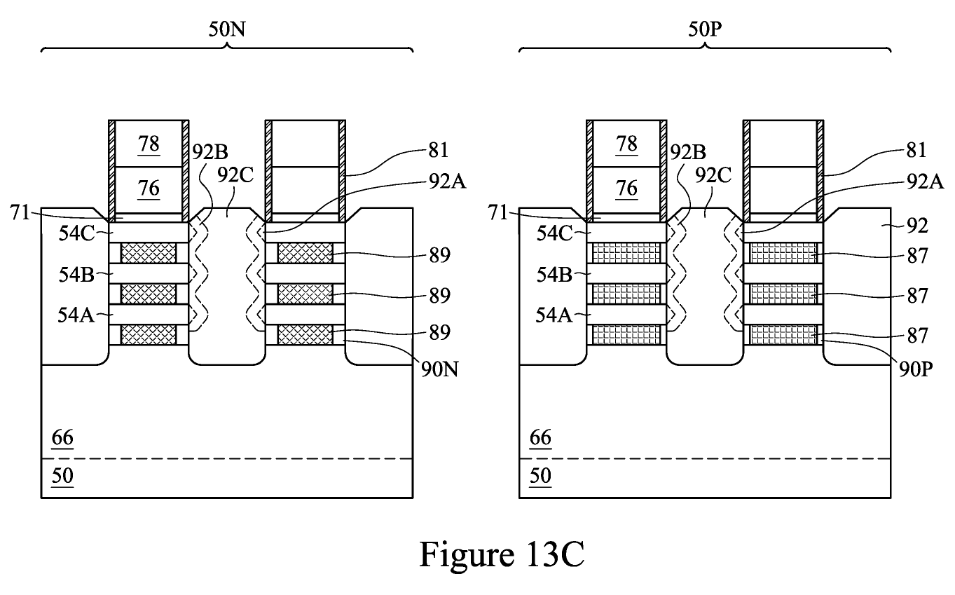

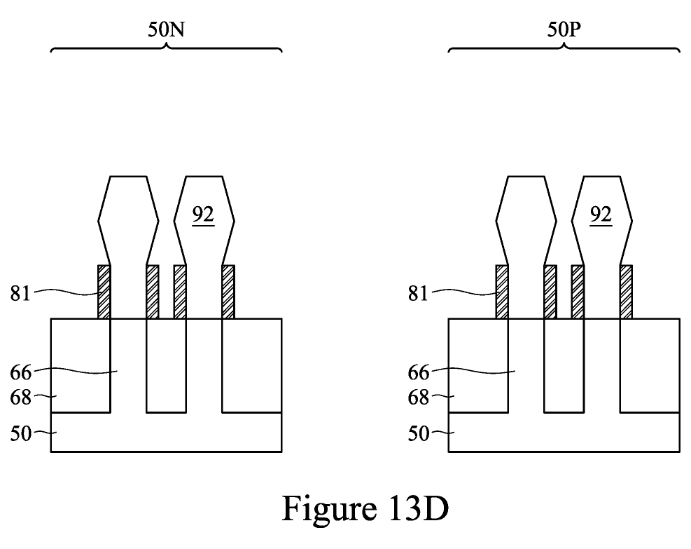

In FIGS. 13A - 13C, epitaxial source/drain regions 92 are formed in the first recesses 86. In some embodiments, the epitaxial source/drain regions 92 may exert stress on the second nanostructures 54, thereby improving performance. As illustrated in FIG. 13C, the epitaxial source/drain regions 92 are formed in the first recesses 86 such that each dummy gate 76 and the second nanostructures 54 below are disposed between respective neighboring pairs of the epitaxial source/drain regions 92.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the second nanostructures 54 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may have surfaces raised from respective surfaces of the second nanostructures 54 and may have facets.

The epitaxial source/drain regions 92 may be implanted with dopants to form source/drain regions, similar to the process previously discussed for forming lightly-doped source/drain regions, followed by an annealing process. The source/drain regions may have an impurity concentration of between about 1x10¹⁹ atoms/cm³ and about 1x10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 may have facets which expand laterally outward beyond sidewalls of the second nanostructures 54. In some embodiments, these facets cause adjacent epitaxial source/drain regions 92 of a same nano-FET to merge as illustrated by FIG. 13B. In some embodiments, adjacent epitaxial source/drain regions 92 remain separated after the epitaxy process is completed as illustrated by FIG. 13D.

The epitaxial source/drain regions 92 may comprise one or more semiconductor material layers. In some embodiments, the epitaxial source/drain regions 92 comprise first liner layers 92A on the sidewalls of the second nanostructures 54, second liner layers 92B on the first liner layers 92A, and fill layers 92C on the second liner layers 92B, as shown in FIG. 13C. The first liner layers 92A, the second liner layers 92B, and the fill layers 92C may be formed of different semiconductor materials and/or may be doped to different dopant concentrations. The first liner layers 92A may be grown first, the second liner layers 92B may be grown on the first liner layers 92A, and the fill layers 92C may be grown on the second liner layers 92B.

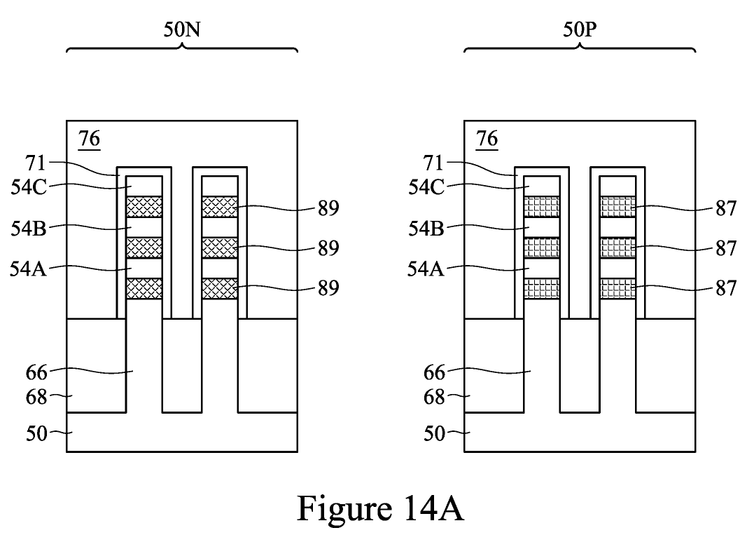

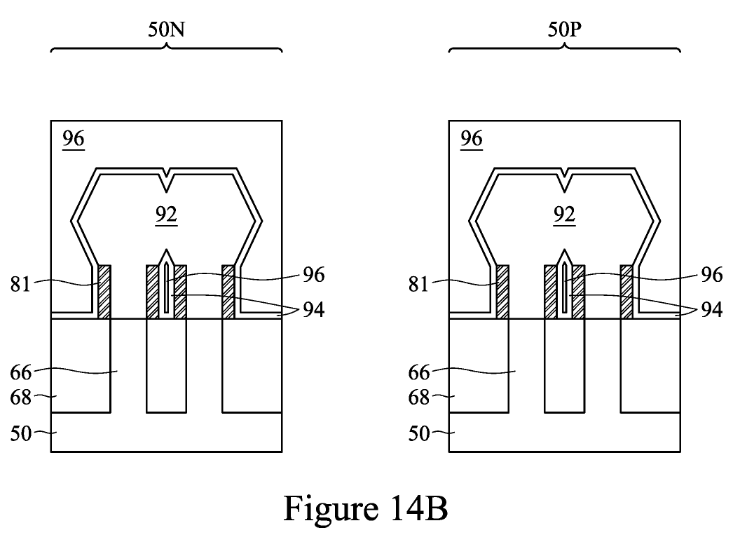

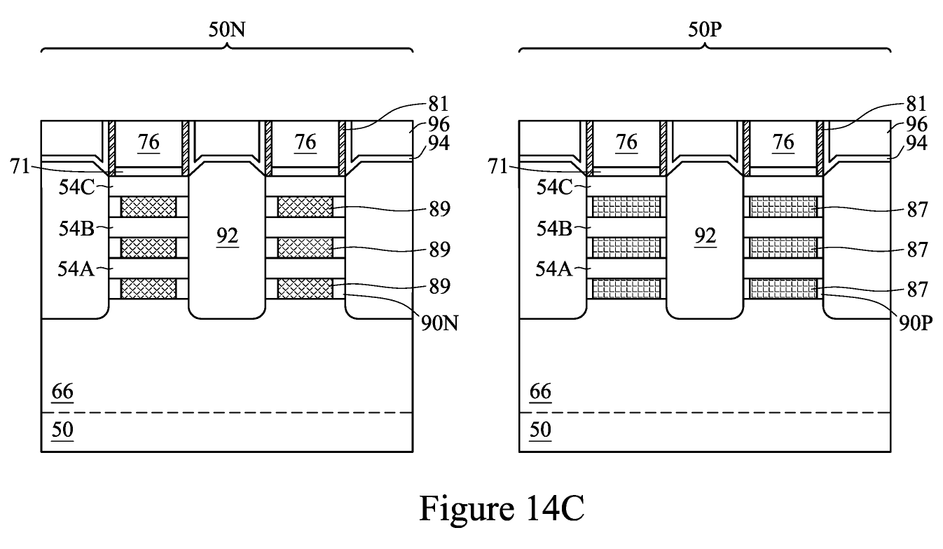

In FIGS. 14A - 14C, a first interlayer dielectric (ILD) 96 is deposited over the structure illustrated in FIGS. 13A - 13C and a planarization process may be performed to level the top surface of the first ILD 96 with the top surfaces of the dummy gates 76 or the masks 78. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, the spacers 81, and the dielectric layers 91. The CESL 94 may comprise a dielectric material, such as, silicon nitride, silicon oxide, silicon oxynitride, or the like, having a different etch rate than the material of the overlying first ILD 96. In some embodiments, the dielectric layers 91 comprise a different material from the CESL 94.

Then a planarization process, such as CMP, may be performed to level the top surface of the first ILD 96 with the top surfaces of the dummy gates 76 or the masks 78. The planarization process may also remove the masks 78 on the dummy gates 76, and portions of the spacers 81 along sidewalls of the masks 78. After the planarization process, top surfaces of the dummy gates 76, the spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the spacers 81.

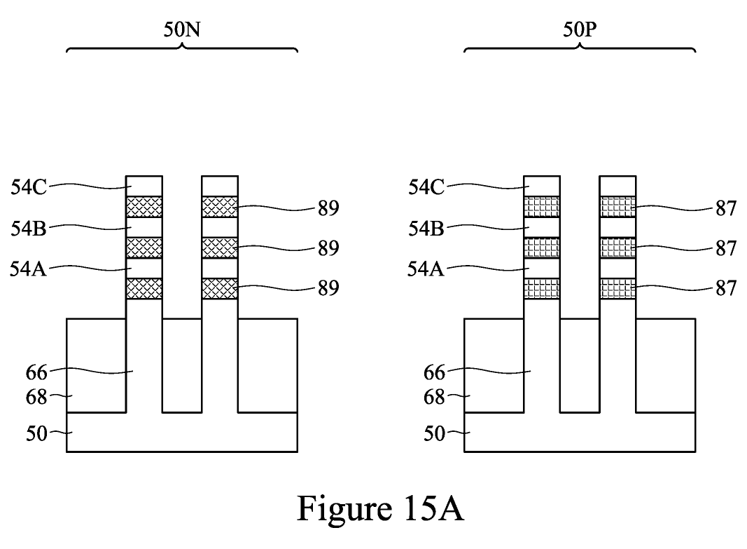

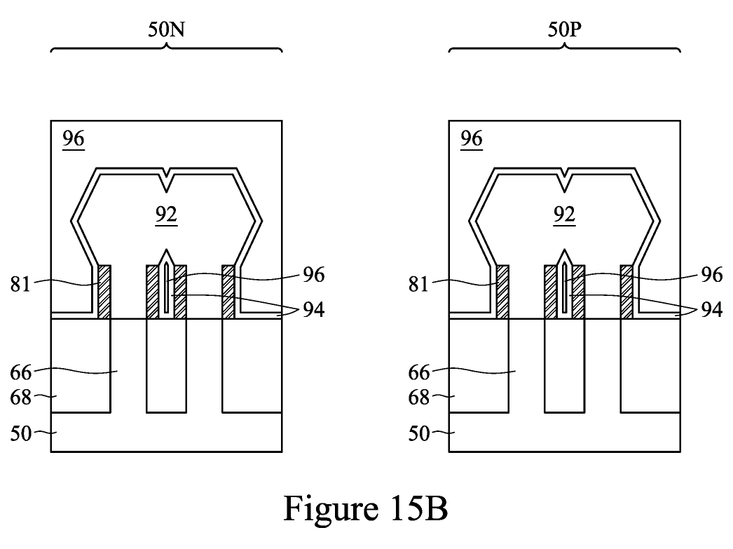

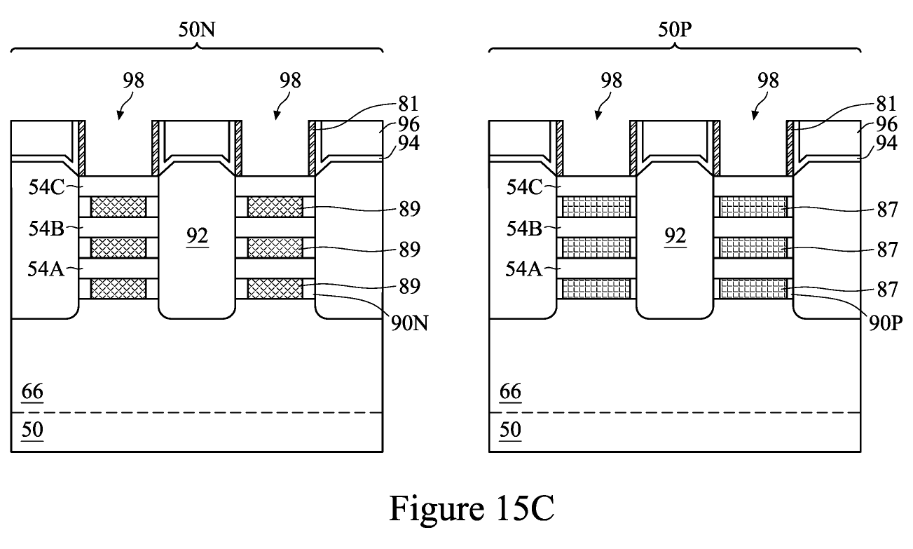

In FIGS. 15A - 15C, the dummy gates 76 and the dummy gate dielectrics 71 are removed in one or more etching processes to form third recesses 98. In some embodiments, the dummy gates 76 and the dummy gate dielectrics 71 are removed by an anisotropic dry etching process. For example, the etching processes may include dry etching processes using reaction gas(es) that selectively etch the dummy gates 76 and the dummy gate dielectrics 71 at faster rates than the second nanostructures 54, the first sacrificial layers 87, the second sacrificial layers 89, the first ILD 96 and/or the spacers 81. Each of the third recess 98 exposes and/or overlies portions of second nanostructures 54, which act as channel regions in subsequently completed nano-FETs. Portions of the second nanostructures 54, which may act as the channel regions, are disposed between neighboring pairs of the epitaxial source/drain regions 92. During the etching processes, the dummy gate dielectrics 71 may be used as etch stop layers when the dummy gates 76 are removed and may be removed after the removal of the dummy gates 76.

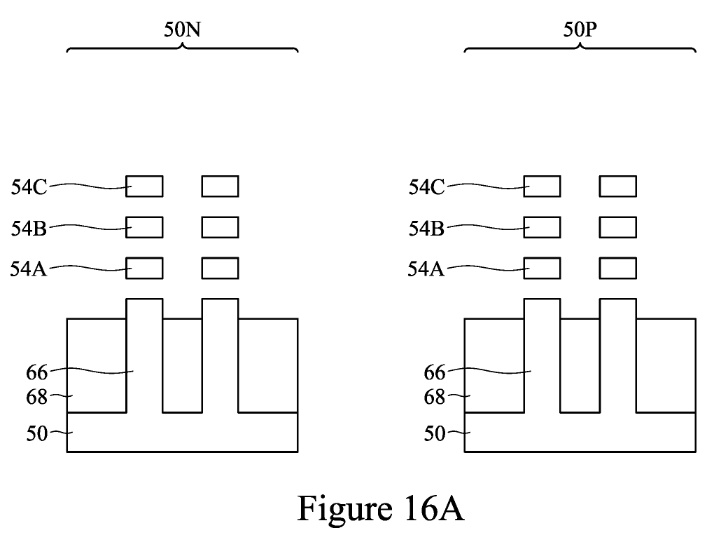

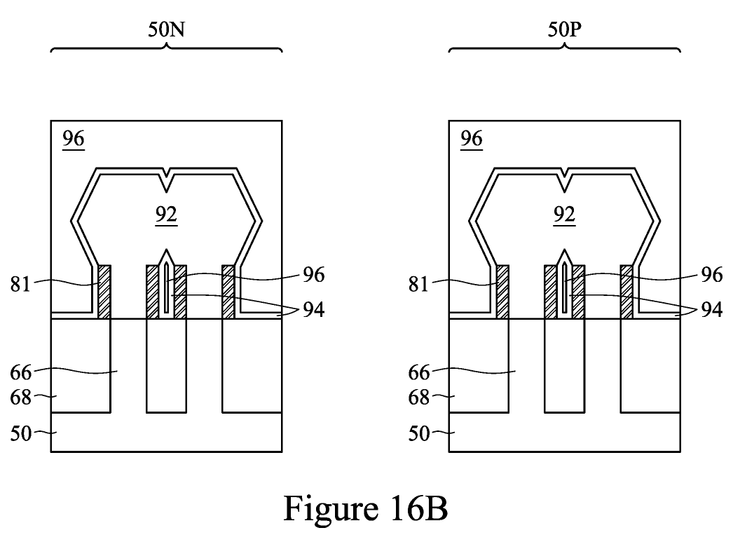

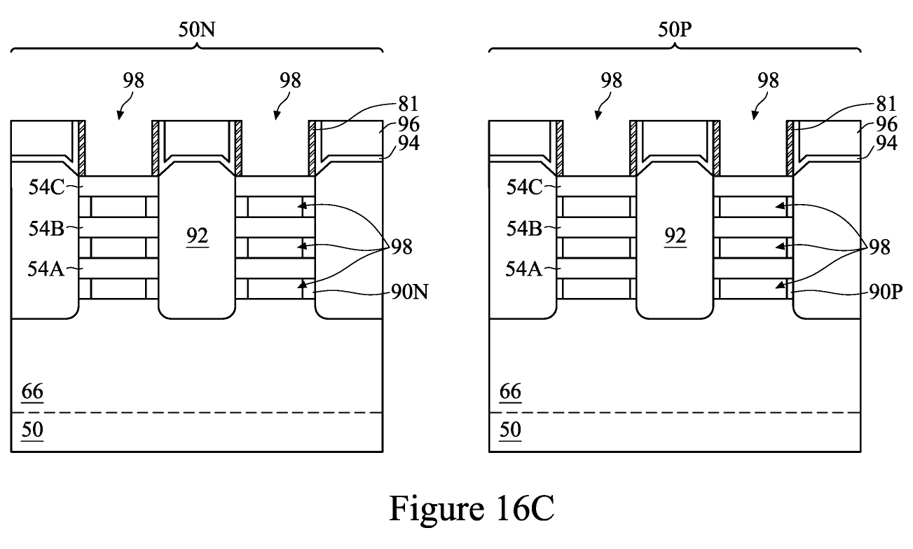

In FIGS. 16A - 16C, the first sacrificial layers 87 in the p-type region 50P and the second sacrificial layers 89 in the n-type region 50N are removed, which extends the third recesses 98. The first sacrificial layers 87 and the second sacrificial layers 89 may be removed using one or more suitable etching processes, such as an isotropic etching process. The etching processes may be wet or drying etching processes using fluorine based chemicals as etchants. During the etching processes, the second nanostructures 54, the inner spacers 90, and the epitaxial source/drain regions 92 may be substantially intact.

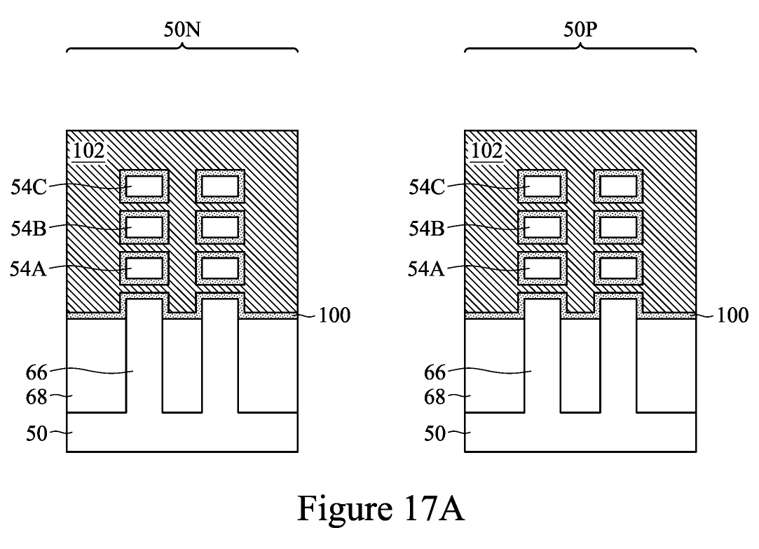

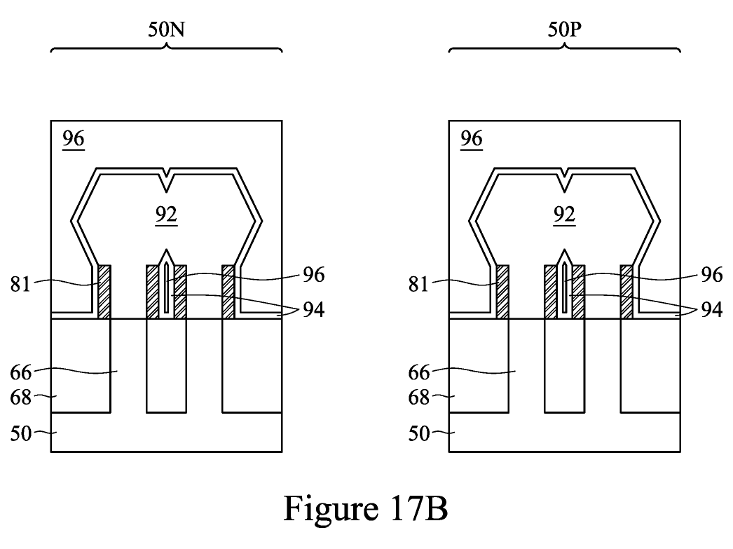

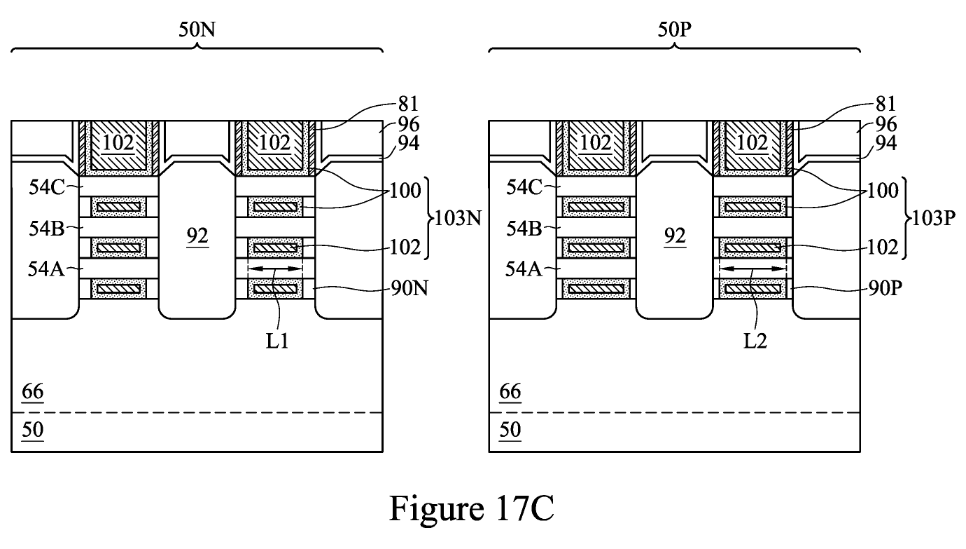

In FIGS. 17A - 17C, gate dielectric layers 100 and gate electrodes 102 are formed in the third recesses 98. The gate electrodes 102 and the gate dielectric layers 100 in the n-type region 50N may be collectively referred to as gate structures 103N. The gate electrodes 102 and the gate dielectric layers 100 in the p-type region 50P may be collectively referred to as gate structures 103P. The gate structures 103N may have a length L1 and the gate structures 103P may have a length L2. The length L1 may be a length of top surfaces or bottom surfaces of the gate structures 103N in contact with the second nanostructures 54 or the fins 66 and the length L2 may be a length of top surfaces or bottom surfaces of the gate structures 103P in contact with the second nanostructures 54 or the fins 66. The length L1 may be a distance by which the inner spacers 90N on each side of gate structures 103N are spaced apart and the length L2 may be a distance by which the inner spacers 90P on each side of gate structures 103P are spaced apart. The length L2 may be larger than the length L1, which may lead to closer distances between the epitaxial source/drain regions 92 and the gate structures 103P in the p-type region 50P. As a result, sufficient electrical insulation between the epitaxial source/drain regions 92 and the gate structures 103P as well as reduced resistance in the channel regions (e.g., the second nanostructures 54) in the p-type region 50P may be achieved, thereby improving the performance and reliability of the subsequently formed semiconductor device. The length L1 may be in a range from about 5 nm to about 100 nm. The length L2 may be in a range from about 6 nm to about 101 nm. In some embodiments, the gate structures 103P has a larger volume than the gate structures 103N.

The gate dielectric layers 100 may be deposited conformally in the third recesses 98. The gate dielectric layers 100 may be formed on top surfaces and sidewalls of the fins 66 and on top surfaces, sidewalls, and bottom surfaces of the second nanostructures 54. The gate dielectric layers 100 may also be deposited on top surfaces of the first ILD 96, the CESL 94, the spacers 81, and the STI regions 68 as well as on sidewalls of the spacers 81, the inner spacers 90N, and the inner spacers 90P. In some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material with a dielectric constant (k) value greater than about 7.0, and may include a metal oxide or a metal silicate. The metal may include hafnium, aluminum, zirconium, lanthanum, manganese, barium, titanium, lead, and combinations thereof. The gate dielectric layers 100 may be formed by a suitable deposition method, such as molecular-beam deposition (MBD), ALD, PECVD, or the like.

The gate electrodes 102 may be deposited over the gate dielectric layers 100, and fill the remaining portions of the third recesses 98. The gate electrodes 102 may include a conductive material such as titanium nitride, titanium oxide, tantalum nitride, tantalum carbide, cobalt, ruthenium, aluminum, tungsten, combinations thereof, or multi-layers thereof. The gate electrodes 102 are illustrated in FIGS. 17A and 17C as single layers as an example, the gate electrodes 102 may comprise any number of liner layers, any number of work function tuning layers, and a fill material. Any combination of the layers which make up the gate electrodes 102 may be deposited between adjacent ones of the second nanostructures 54 and between the second nanostructure 54A and the substrate 50.

In some embodiments, the formation of the gate dielectric layers 100 in the n-type region 50N and the p-type region 50P occur simultaneously, such that the gate dielectric layers 100 in both regions are formed of the same materials, and the formation of the gate electrodes 102 in the n-type region 50N and the p-type region 50P occur simultaneously, such that the gate electrodes 102 in both regions are formed of the same materials. In some embodiments, the gate dielectric layers in the n-type region 50N and the p-type region 50P may be formed by separate processes, such that the gate dielectric layers 100 may comprise different materials and/or different structures in each region, and/or the gate electrodes 102 in the n-type region 50N and the p-type region 50P may be formed by separate processes, such that the gate electrodes 102 may comprise different materials and/or structures in each region. Various masking steps may be used to mask and expose appropriate regions when using separate processes. After the filling of the third recesses 98, a planarization process, such as CMP, may be performed to remove the excess portions of the gate dielectric layers 100 and the material of the gate electrodes 102.

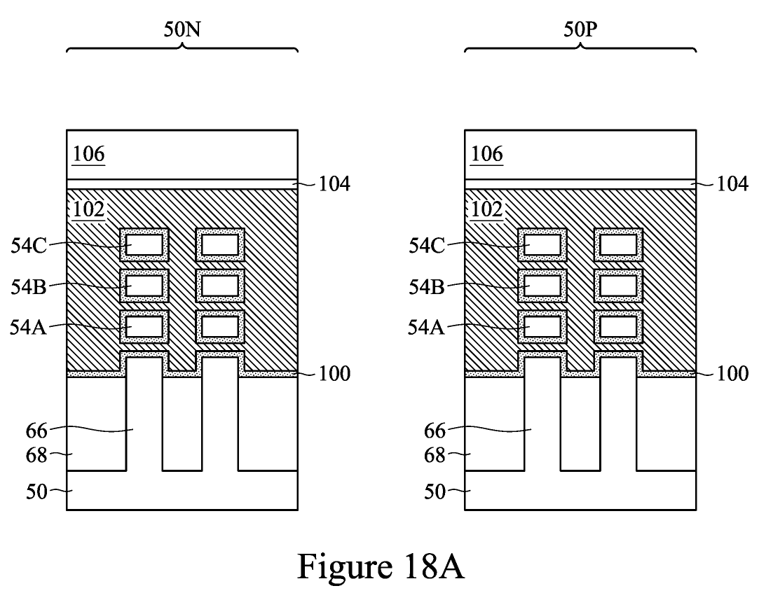

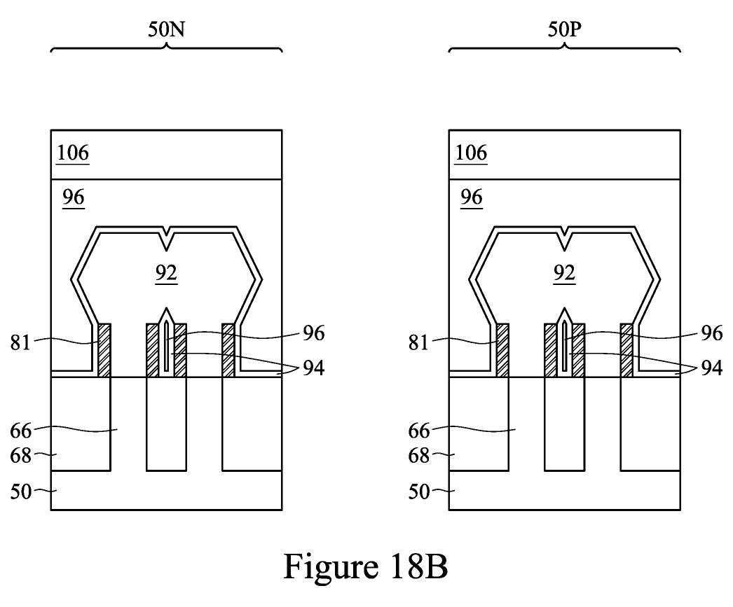

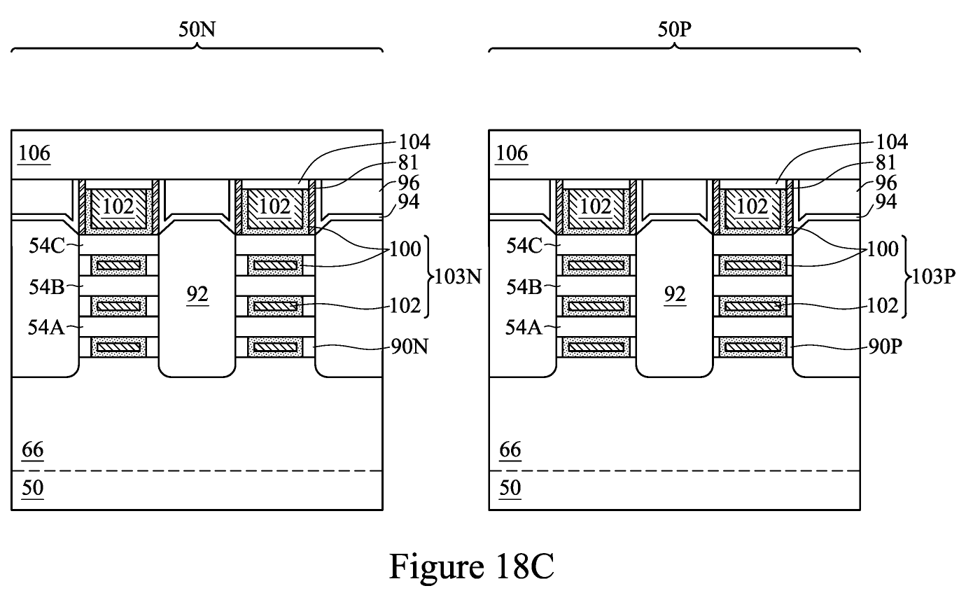

In FIGS. 18A - 18C, the gate structures (including the gate dielectric layers 100 and the corresponding overlying gate electrodes 102) are recessed, gate masks 104 are formed in the recesses, and a second ILD 106 is formed over the first ILD 96 and the gate masks 104. The recesses may be formed directly over the gate structures and between opposing portions of spacers 81. Gate masks 104 may comprise one or more layers of dielectric material, such as silicon nitride, silicon oxynitride, or the like. A planarization process may be performed to remove excess material of the gate masks 104. The second ILD 106 may be formed of a dielectric material, such as PSG, BSG, BPSG, USG, or the like, and may be formed by a suitable deposition method, such as CVD, PECVD, FCVD, or the like.

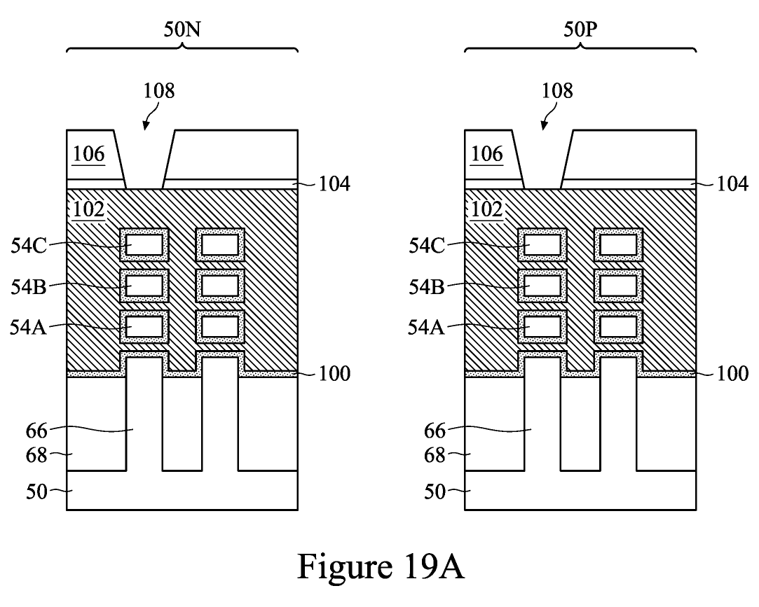

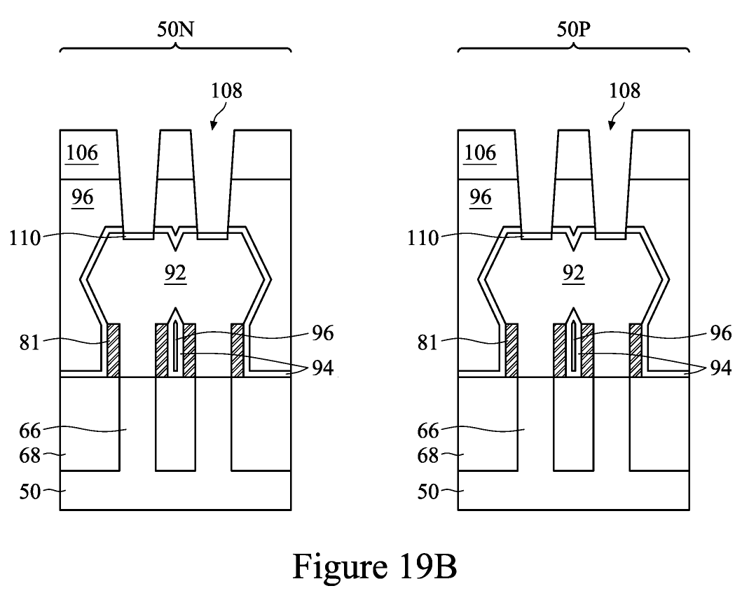

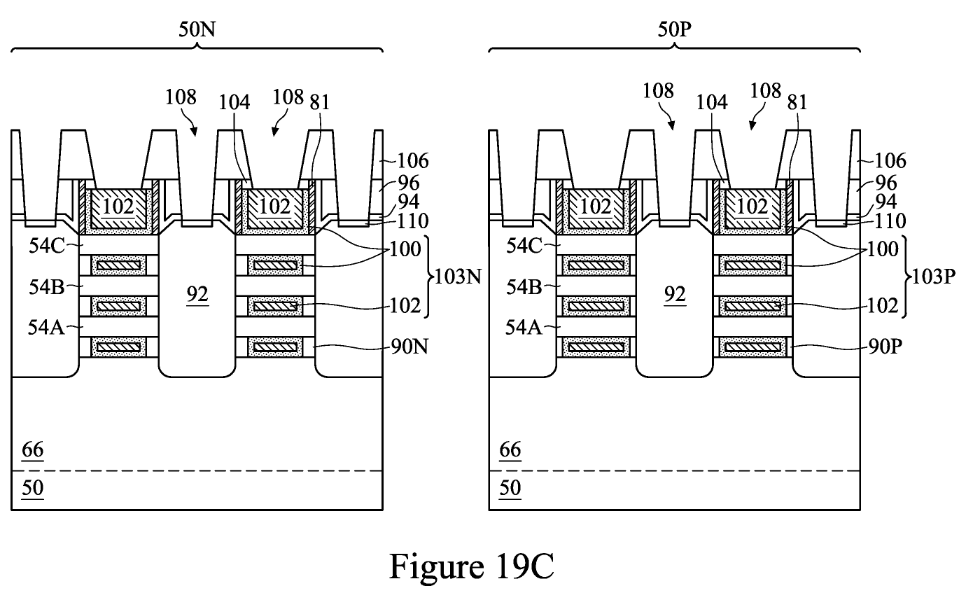

In FIGS. 19A - 19C, the second ILD 106, the first ILD 96, the CESL 94, and the gate masks 104 are etched to form fourth recesses 108 exposing surfaces of the epitaxial source/drain regions 92 and/or some of the gate structures. The fourth recesses 108 may be formed by etching using an anisotropic etching process, such as RIE, NBE, or the like. In some embodiments, the fourth recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the fourth recesses 108 extend into the epitaxial source/drain regions 92 and/or some of the gate structures, and a bottom of the fourth recesses 108 may be level with (e.g., at a same level, or having a same distance from the substrate 50), or lower than (e.g., closer to the substrate 50) the epitaxial source/drain regions 92 and/or some of the gate structures.

After the fourth recesses 108 are formed, first silicide regions 110 are formed over the epitaxial source/drain regions 92. In some embodiments, the first silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal annealing process to form the first silicide regions 110. The un-reacted portions of the deposited metal are then removed, e.g., by an etching process. Although the first silicide regions 110 are referred to as silicide regions, the first silicide regions 110 may also be germanide regions, or silicon germanide regions (e.g., regions comprising silicide and germanide).

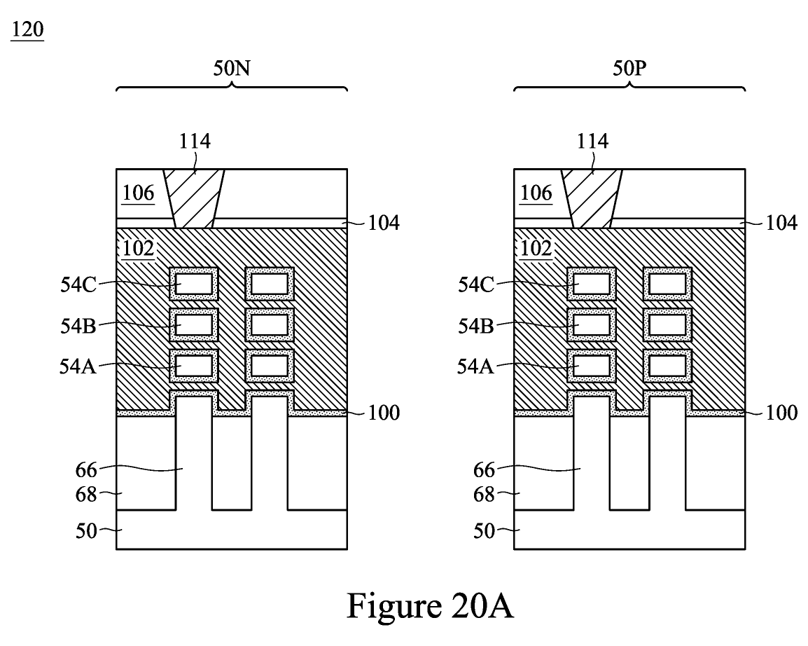

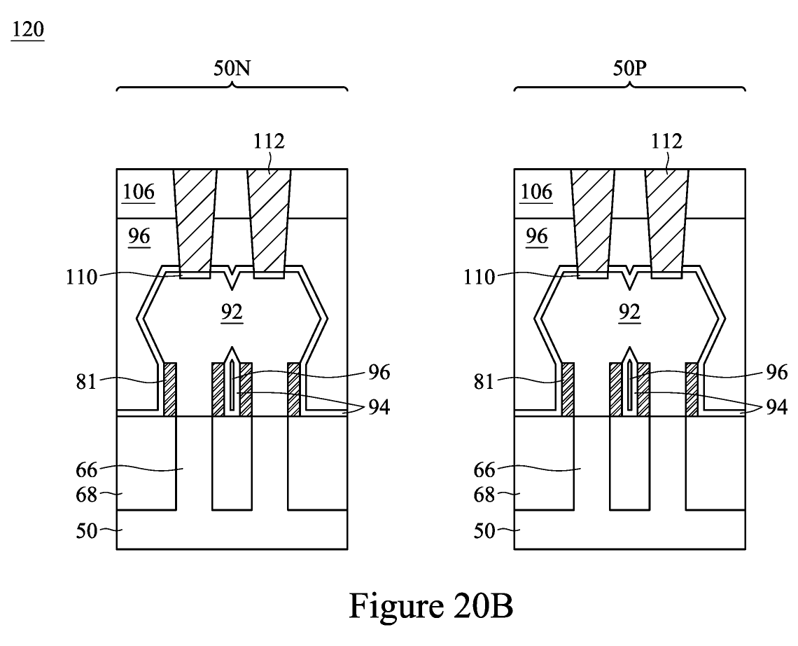

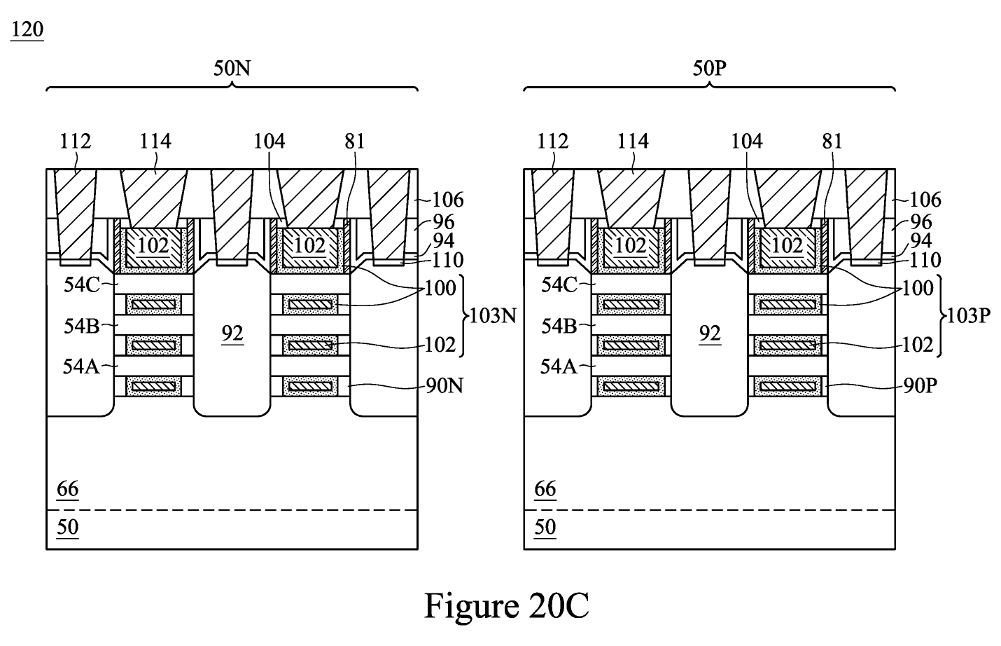

In FIGS. 20A - 20C, source/drain contacts 112 and gate contacts 114, which may be also referred to as conductive contacts, are formed in the fourth recesses 108. The source/drain contacts 112 and the gate contacts 114 may each comprise one or more layers, such as barrier layers, diffusion layers, and fill materials. For example, in some embodiments, the source/drain contacts 112 and the gate contacts 114 each include a barrier layer and a conductive material, and are each electrically connected to an underlying conductive feature (e.g., a gate electrode 102 and/or a first silicide region 110). The gate contacts 114 are electrically connected to the gate electrodes 102 and the source/drain contacts 112 are electrically connected to the first silicide regions 110. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as CMP, may be performed to remove excess material from surfaces of the second ILD 106. The structure shown in FIGS. 20A - 20C may be referred to as a semiconductor device 120.

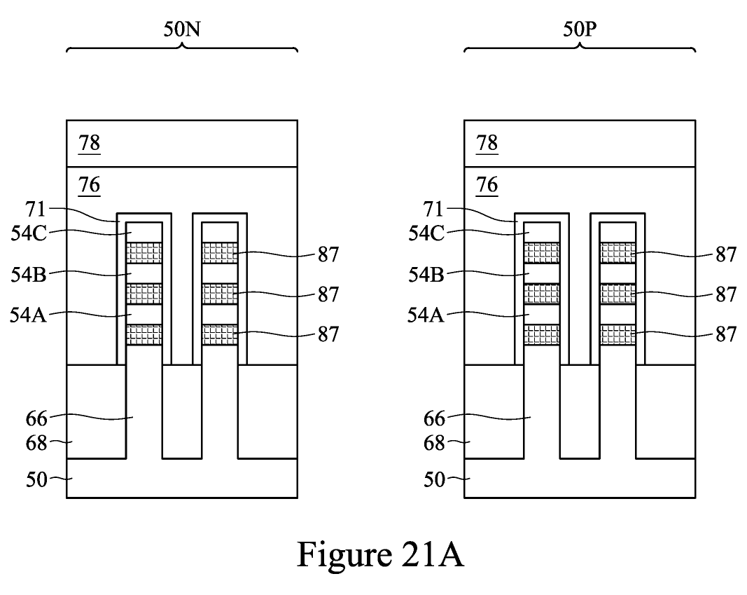

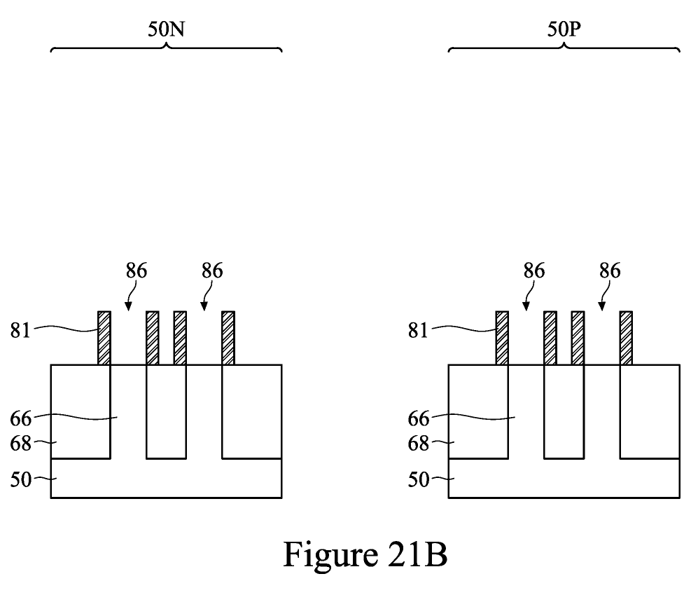

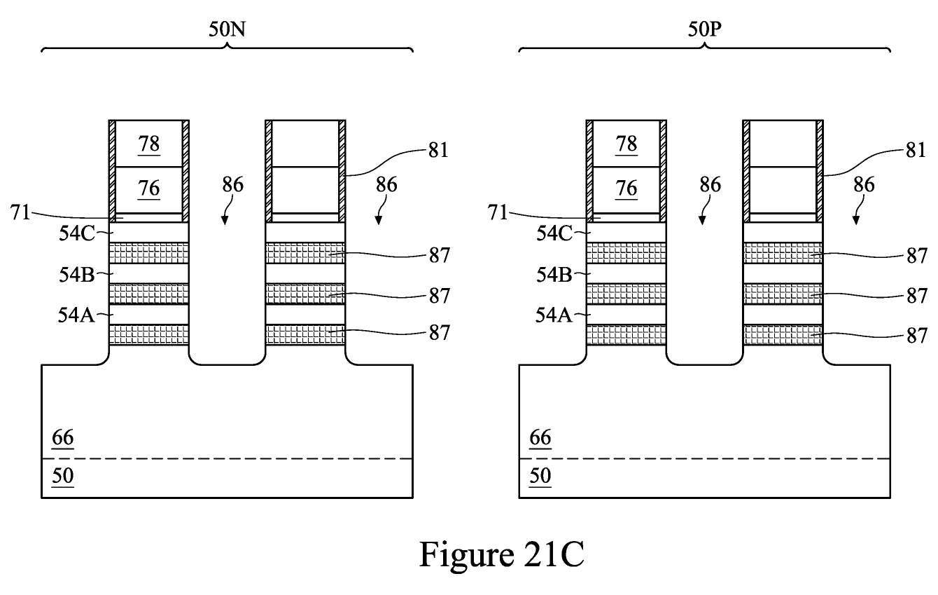

FIGS. 21A - 25C are views of intermediate processes of the manufacturing of the semiconductor device 120, in accordance with some embodiments. FIGS. 21A, 22A, 23A, 24A and 25C illustrate cross-sectional views along the reference cross-section A-A’ illustrated in FIG. 1. FIGS. 21B, 22B, 23B, 24B and 25B illustrate cross-sectional views along the reference cross-section B-B’ illustrated in FIG. 1. FIGS. 21C, 22C, 23C, 24C and 25C illustrate cross-sectional views along the reference cross-section C-C’ illustrated in FIG. 1.

FIGS. 21A - 21C illustrate structures same or similar to the ones shown in FIGS. 9A - 9C, which may be based on structures formed by the processes same or similar to the ones shown in FIGS. 1 - 8C, wherein like numerals refer to like features formed by like processes. In FIGS. 21A - 21C, the first nanostructures 52 in both the n-type region 50N and the p-type region 50P are replaced with the first sacrificial layers 87. The replacement process shown in FIGS. 21A - 21C may be same or similar to the replacement process described with respect to FIGS. 9A - 9C.

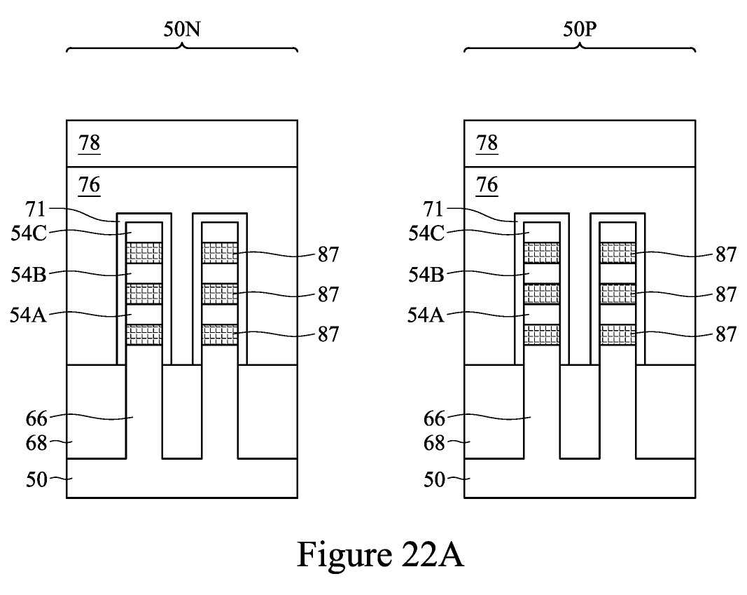

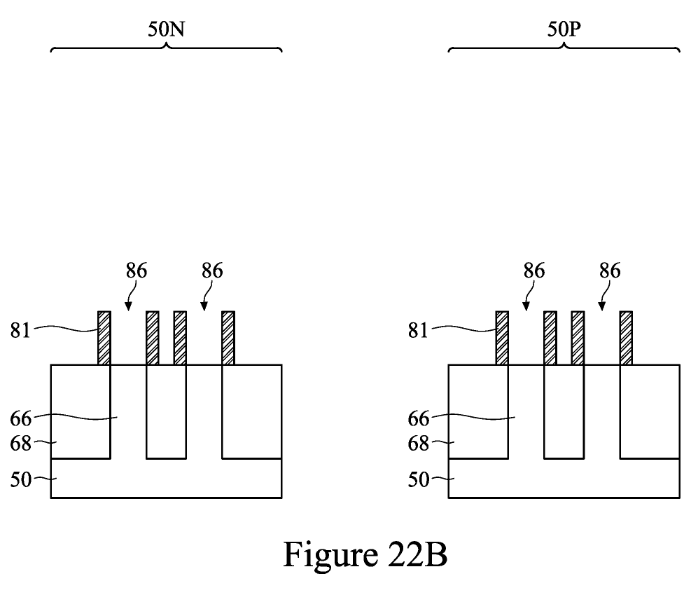

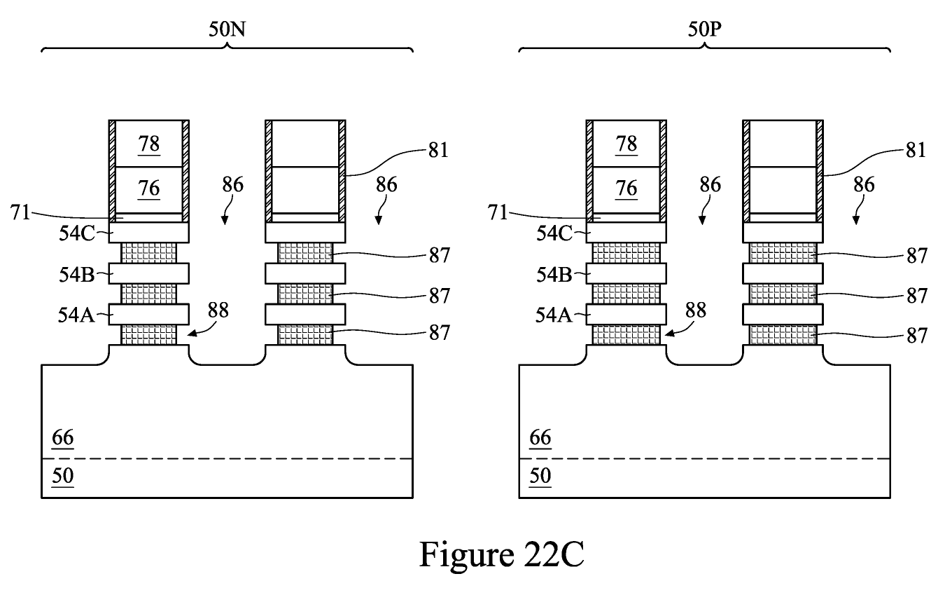

In FIGS. 22A - 22C, the first sacrificial layers 87 in both the n-type region 50N and the p-type region 50P are partially removed by a series of masking and etching processes to form second recesses 88. In some embodiments, the series of masking and etching processes include forming a hard mask over the p-type region 50P, etching the first sacrificial layers 87 in the n-type region 50N while the first sacrificial layers 87 in the p-type region 50P are protected by the hard mask, removing the hard mask over the p-type region 50P, and etching the first sacrificial layers 87 in both the n-type region 50N and the p-type region 50P. During the etching processes, the second nanostructures 54 and the semiconductor fins 66 may be substantially intact. After the etching process, the sidewalls of the first sacrificial layers 87 in both the n-type region 50N and the p-type region 50P may be recessed from sidewalls of the second nanostructures 54. The first sacrificial layers 87 in the n-type region 50N may be further recessed than the first sacrificial layers 87 in the p-type region 50P. The first sacrificial layers 87 in the p-type region 50P may be wider than the first sacrificial layers 87 in the n-type region 50N. In the embodiments illustrated in FIG. 22C, the sidewalls of the first sacrificial layers 87 in both the n-type region 50N and the p-type region 50P are substantially straight. The etching processes may be wet and/or drying isotropic etching processes using fluorine based chemicals as etchants.

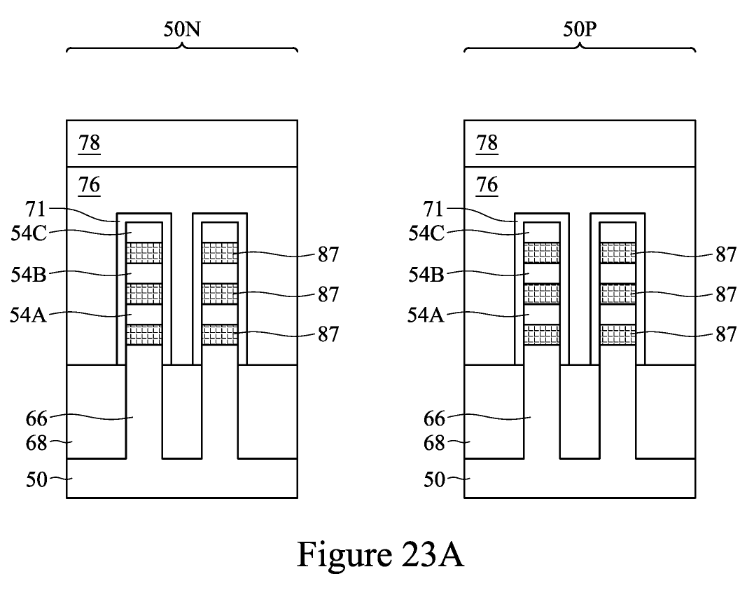

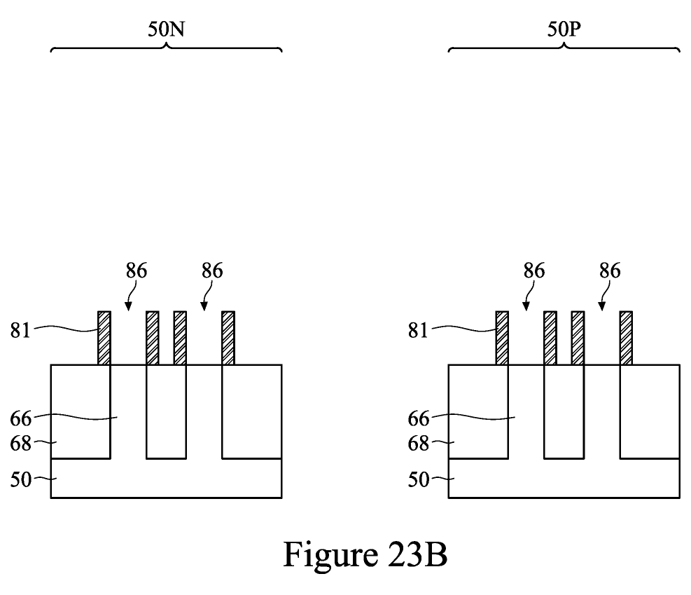

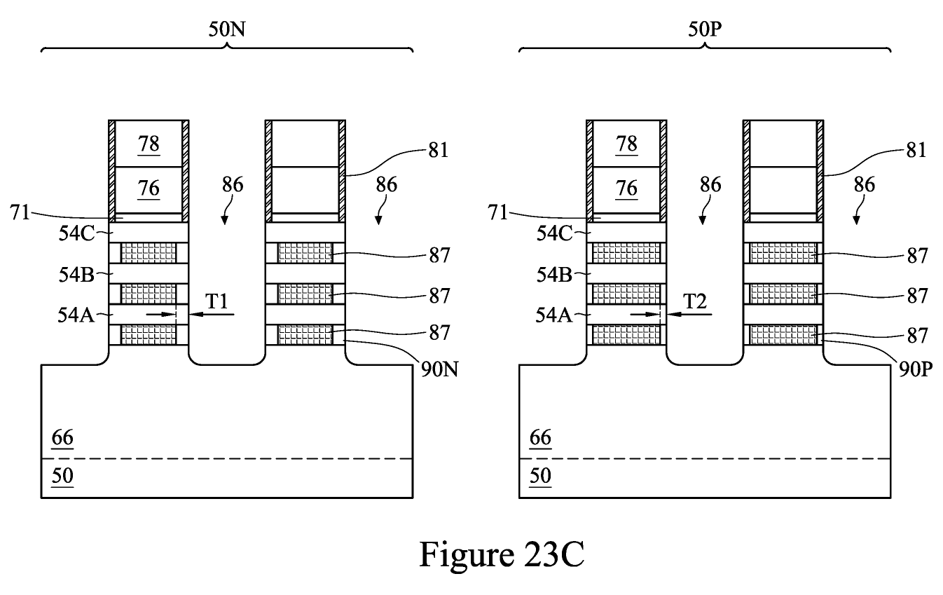

In FIGS. 23A - 23C, the inner spacers 90N are formed in the second recesses 88 in the n-type region 50N and the inner spacers 90P are formed in the p-type region 50P. The inner spacers 90N and the inner spacers 90P may be formed of the same or similar materials and by the same or similar methods as the ones described with respect to FIGS. 12A -12C. The inner spacers 90P may extend along sidewalls of the first sacrificial layers 87 in the p-type region 50P and the inner spacers 90N may extend along sidewalls of the second sacrificial layers 89 in the n-type region 50N. The inner spacers 90P and the inner spacers 90N may be in contact with top surfaces and bottom surfaces of the second nanostructures 54, as well as top surfaces of the fins 66. The inner spacers 90N may have the thickness T1 and the inner spacers 90P may have the thickness T2, as described with respect to FIGS. 12A -12C.

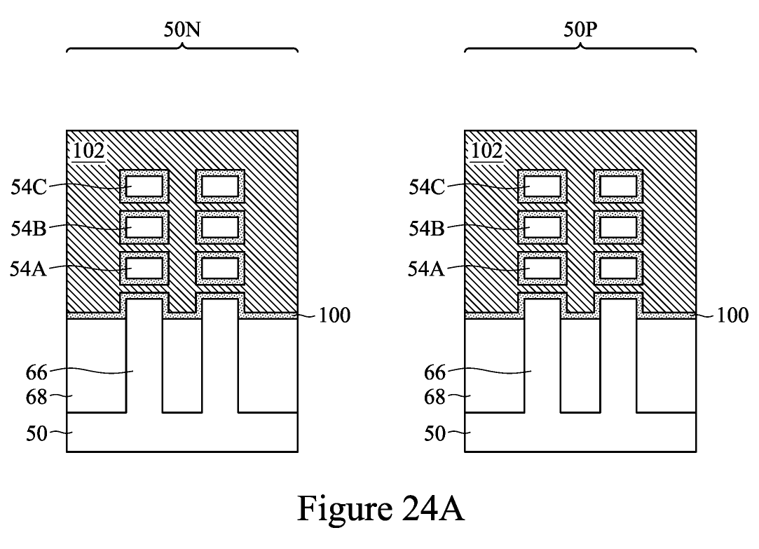

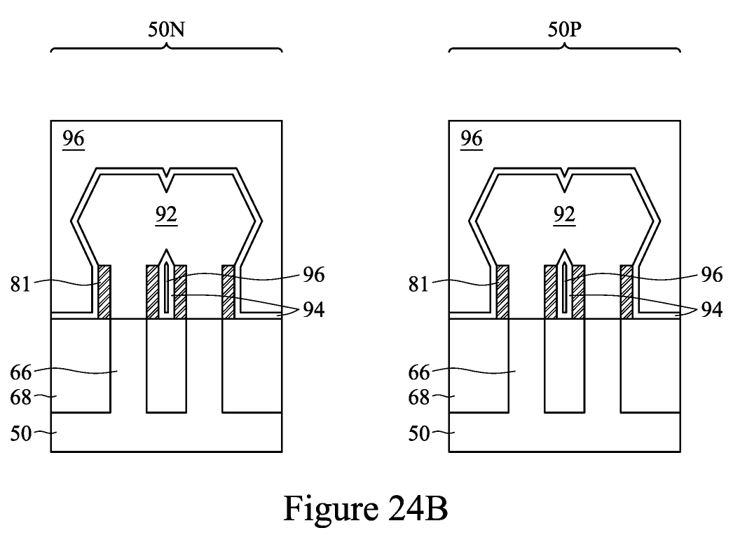

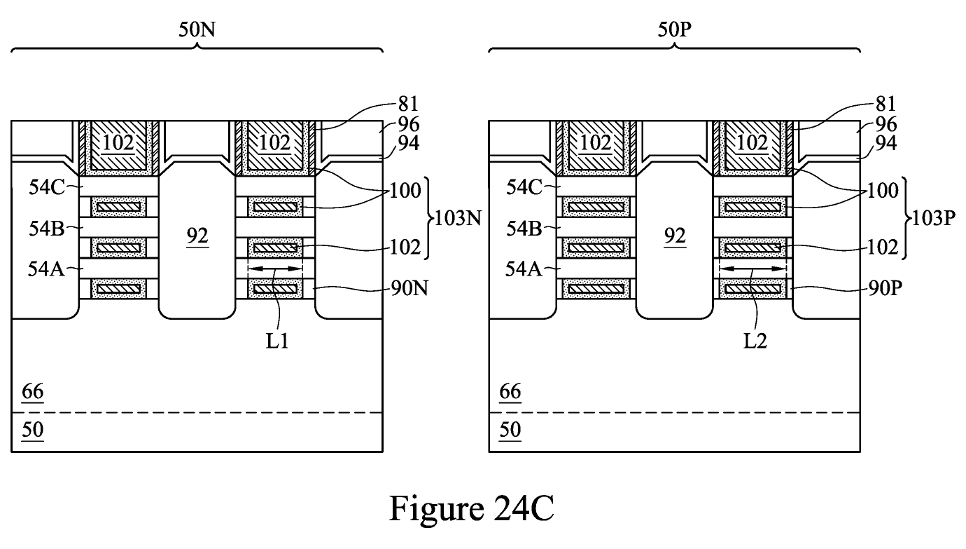

FIGS. 24A -24C illustrate structures same or similar to the ones shown in FIGS. 17A -17C, which may be based on structures formed by the processes same or similar to the ones shown in FIGS. 13A -16C, wherein like numerals refer to like features formed by like processes. In FIGS. 24A -24C, the gate structures 103N are formed in the n-type region 50N and the gate structures 103P are formed in the p-type region 50P. The gate structures 103N and the gate structures 103P may be formed of the same or similar materials and by the same or similar methods as the ones described with respect to FIGS. 17A -17C. The gate structures 103N may have the length L1 and the gate structures 103P may have the length L2, as described with respect to FIGS. 17A -17C.

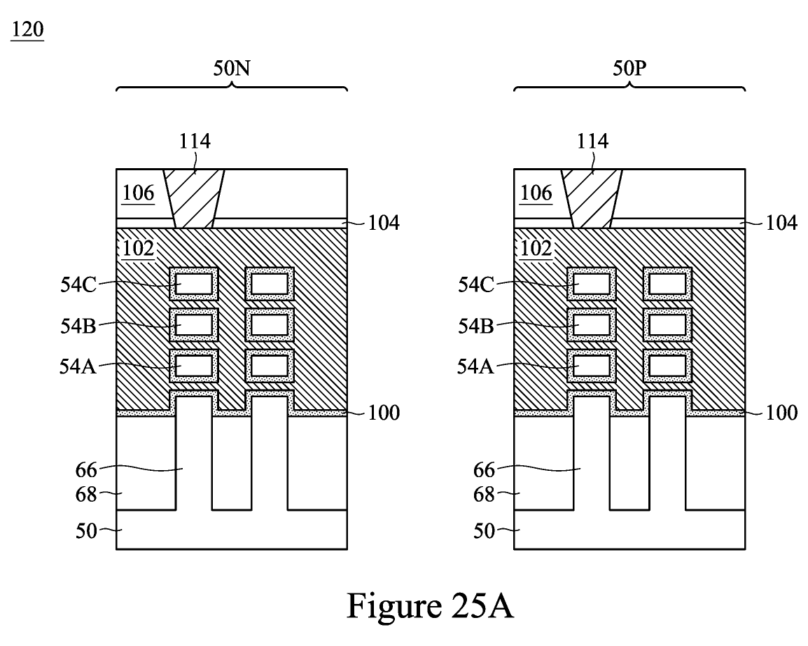

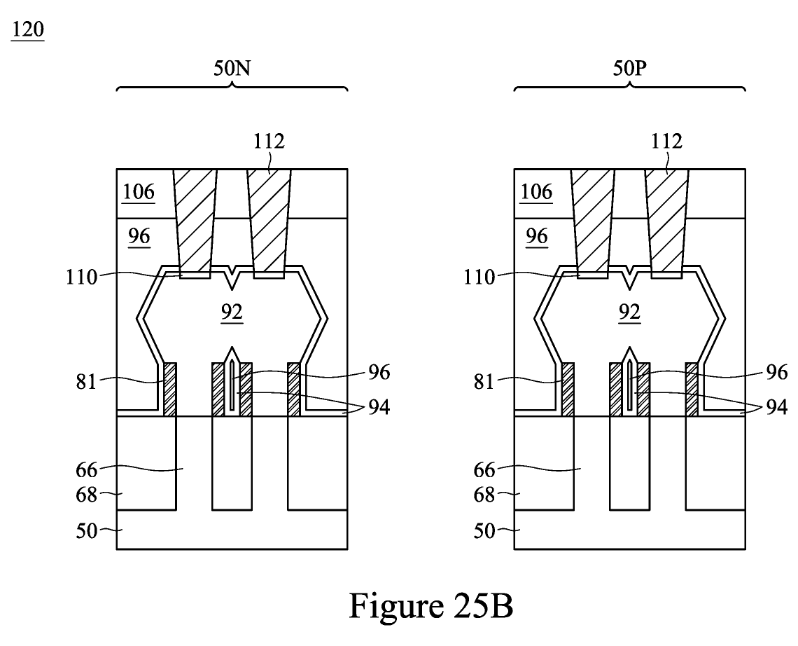

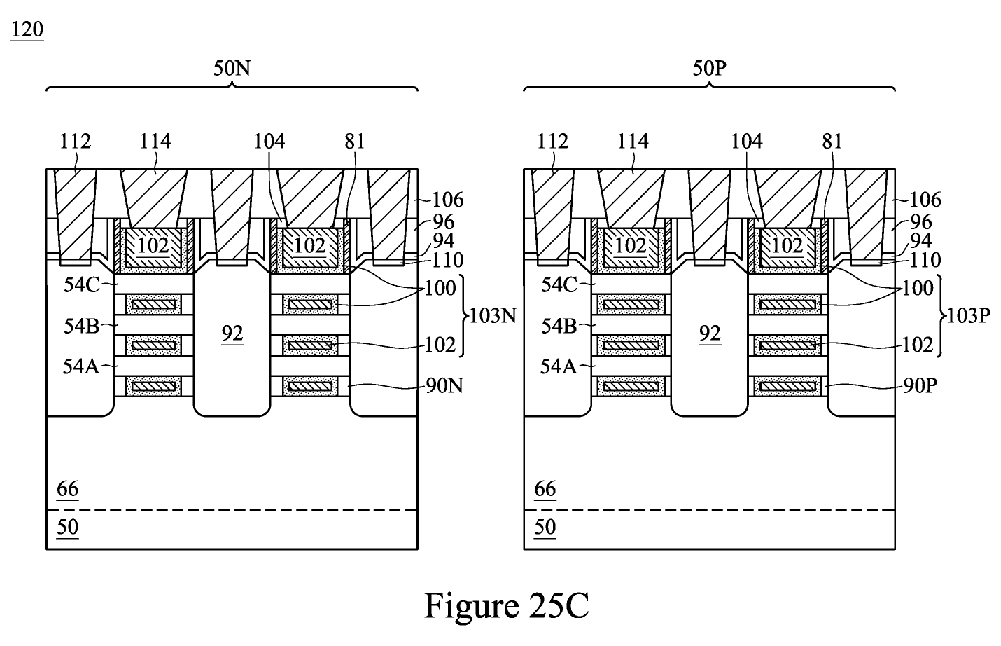

FIGS. 25A -25C illustrate structures same or similar to the ones shown in FIGS. 20A -20C, which may be based on structures formed by the processes same or similar to the ones shown in FIGS. 18A -19C, wherein like numerals refer to like features formed by like processes. In FIGS. 25A -25C, the source/drain contacts 112 and the gate contacts 114, which may be also referred to as the conductive contacts, are formed of the same or similar materials and by the same or similar methods as the ones described with respect to FIGS. 20A -20C. The structure shown in FIGS. 25A -25C may be referred to as the semiconductor device 120.

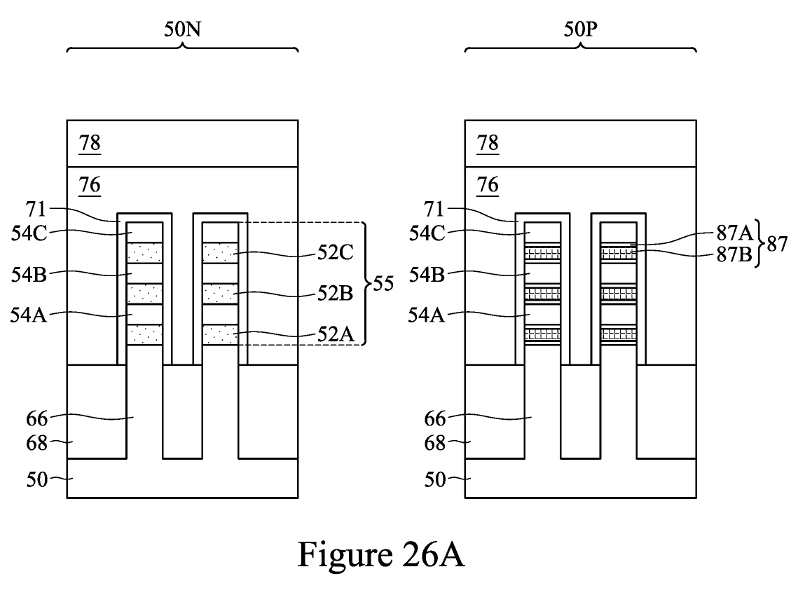

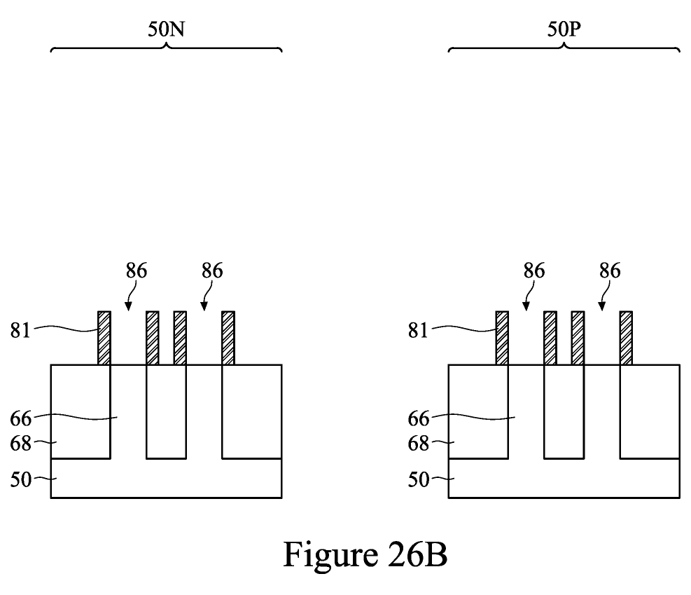

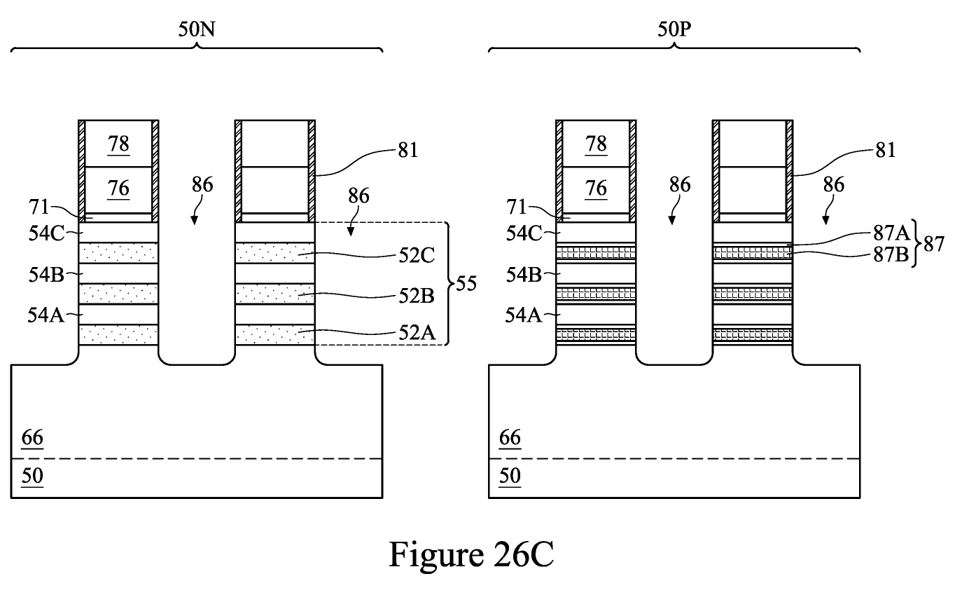

FIGS. 26A - 31C are views of intermediate processes of the manufacturing of a semiconductor device (e.g., a nano-FET), in accordance with some embodiments. FIGS. 26A, 27A, 28A, 29A, 30A and 31A illustrate cross-sectional views along the reference cross-section A-A’ illustrated in FIG. 1. FIGS. 26B, 27B, 28B, 29B, 30B and 31B illustrate cross-sectional views along the reference cross-section B-B’ illustrated in FIG. 1. FIGS. 26C, 27C, 28C, 29C, 30C and 31C illustrate cross-sectional views along the reference cross-section C-C’ illustrated in FIG. 1.

FIGS. 26A -26C illustrate structures same or similar to the ones shown in FIGS. 9A -9C, which may be based on structures formed by the processes same or similar to the ones shown in FIGS. 1 -8C, wherein like numerals refer to like features formed by like processes. In FIGS. 26A -26C, the first nanostructures 52 in the p-type region 50P are replaced with the first sacrificial layers 87, which may include first sublayers 87A and second sublayers 87B of the first sacrificial layers 87. The first sublayers 87A may be in contact with top surfaces and bottom surfaces of the second nanostructures 54, as well as top surfaces of the fins 66. The second sublayers 87B may be between and in contact with neighboring first sublayers 87A between neighboring second nanostructures 54.

The n-type region 50N may be covered and protected by a hard mask (not separately illustrated) during the replacement process. The hard mask may be formed by a suitable photolithography process. The replacement process in the p-type region 50P may include first removing the first nanostructures 52 using a suitable etching process, such as an isotropic etching process, performed through the first recesses 86. The etching process may be a wet or drying etching process using fluorine based chemicals as etchants. The etching process may selectively remove the material of the first nanostructures 52 without significantly removing materials of the second nanostructures 54 or the semiconductor fins 66.

Subsequently, the first sacrificial layers 87 may be formed in spaces where the first nanostructures 52 occupied before being removed in the p-type region 50P. The first sacrificial layers 87 may be formed by first forming the first sublayers 87A on the second nanostructures 54 and then forming the second sublayers 87B on the first sublayers 87A. The first sublayers 87A and the second sublayers 87B may be formed by suitable deposition processes, such as CVD, ALD, or the like, respectively. The hard mask covering and protecting the n-type region 50N may be removed after the replacement process in the p-type region 50P.

The first sublayers 87A and the second sublayers 87B may each comprise a dielectric material, such as silicon nitride, silicon oxide, silicon oxynitride, silicon carbonitride, silicon oxycarbonitride, silicon oxycarbide, or the like, which may have a high etching selectivity to the second nanostructures 54 and other subsequently formed features as described in greater details below. The dielectric material of the first sublayers 87A may have a high etching selectivity to the dielectric material of the second sublayers 87B. In some embodiments, the chemical composition of the dielectric material in the first sublayers 87A is different from the chemical composition of the dielectric material in the second sublayers 87B. In some embodiments, the chemical composition of the dielectric material in the first sublayers 87A is same as the chemical composition of the dielectric material in the second sublayers 87B, and the density of the dielectric material in the first sublayers 87A is higher than the density of the dielectric material in the second sublayers 87B.

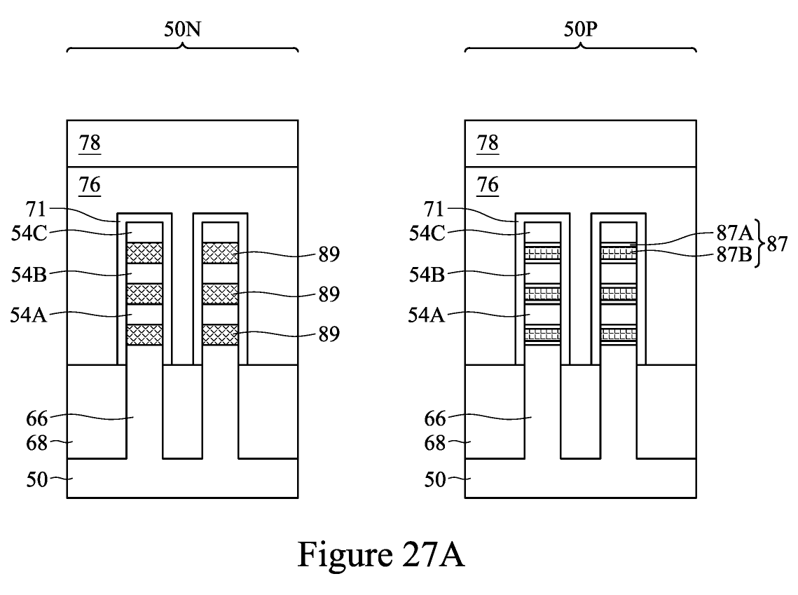

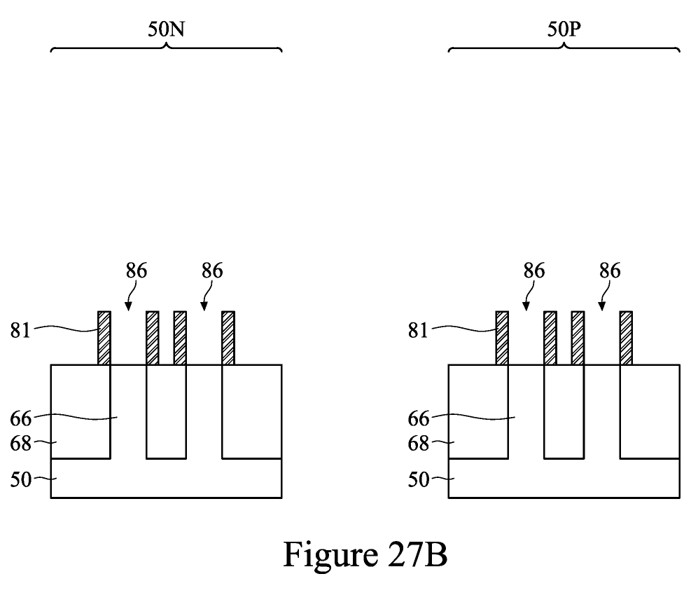

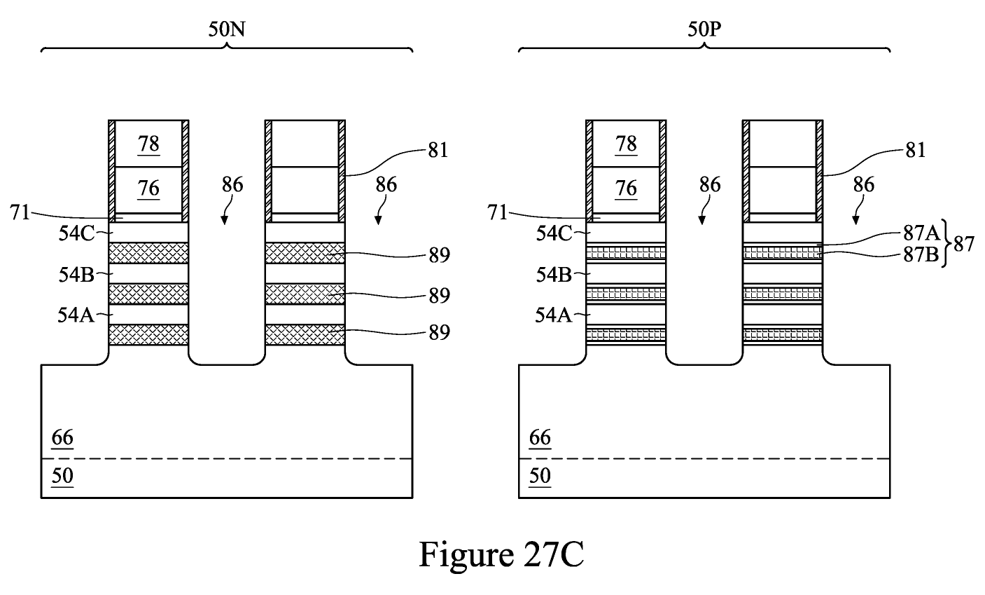

In FIGS. 27A -27C, the first nanostructures 52 in the n-type region 50N are replaced with the second sacrificial layers 89. The second sacrificial layers 89 may be formed of the same or similar materials and by the same or similar methods as the ones described with respect to FIGS. 10A -10C. The second sacrificial layers 89 may comprise a dielectric material, such as silicon nitride, silicon oxide, silicon oxynitride, silicon carbonitride, silicon oxycarbonitride, silicon oxycarbide, or the like, which may have a high etching selectivity to the second nanostructures 54, the first sacrificial layers 87, and other subsequently formed features as described in greater details below. In some embodiments, the chemical composition of the dielectric material in the second sacrificial layers 89 is different from the chemical composition of the dielectric material in the first sublayers 87A and/or the dielectric material in the second sublayers 87B. In some embodiments, the chemical composition of the dielectric material in the second sacrificial layers 89 is same as the dielectric material in the first sublayers 87A and/or the dielectric material in the second sublayers 87B, and the density of the dielectric material in the second sacrificial layers 89 is lower than the density of the dielectric material in the first sublayers 87A and/or the dielectric material in the second sublayers 87B.

FIGS. 26A -27C illustrate forming the first sacrificial layers 87 in the p-type region 50P before forming the second sacrificial layers 89 in the n-type region 50N as an example. In some embodiments, the second sacrificial layers 89 are formed in the n-type region 50N before the first sacrificial layers 87 are formed in the p-type region 50P.

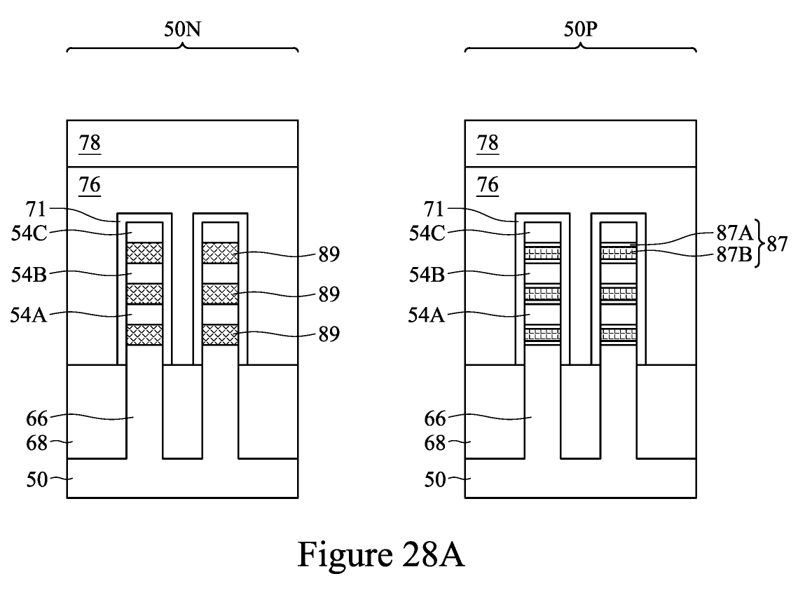

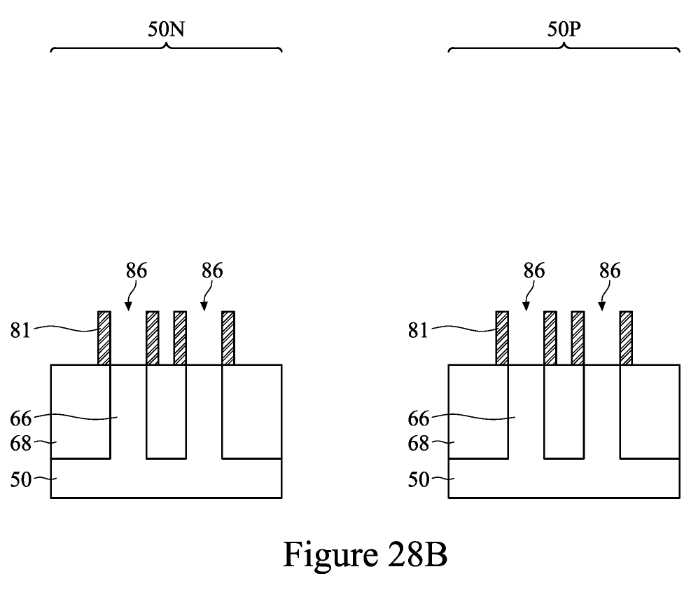

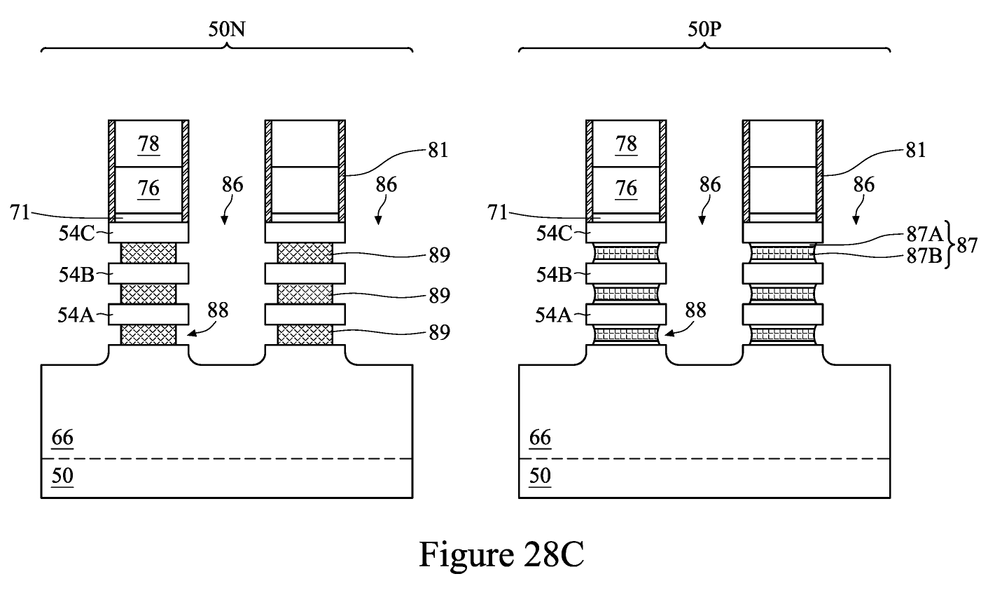

In FIGS. 28A -28C, the first sacrificial layers 87, including the first sublayers 87A and the second sublayers 87B, in the p-type region 50P and the second sacrificial layers 89 in the n-type region 50N are partially removed by an etching process to form second recesses 88. During the etching process, the second sublayers 87B may be etched at a faster rate than the first sublayers 87A, the second sacrificial layers 89 may be etched at a faster rate than the first sublayers 87A and/or the second sublayers 87B, and the second nanostructures 54 and the semiconductor fins 66 may be substantially intact. After the etching process, sidewalls of the first sacrificial layers 87 may be recessed from sidewalls of the second nanostructures 54 in the p-type region 50P and sidewalls of the second sacrificial layers 89 may be recessed from sidewalls of the second nanostructures 54 in the n-type region 50N. The second sacrificial layers 89 may be further recessed than the first sacrificial layers 87. The first sacrificial layers 87 may be wider than the second sacrificial layers 89. In the embodiments illustrated in FIG. 28C, the sidewalls of the first sacrificial layers 87 are concave and the sidewalls of the second sacrificial layers 89 are substantially straight. The etching process may be a wet or drying isotropic etching process using fluorine based chemicals as etchants.

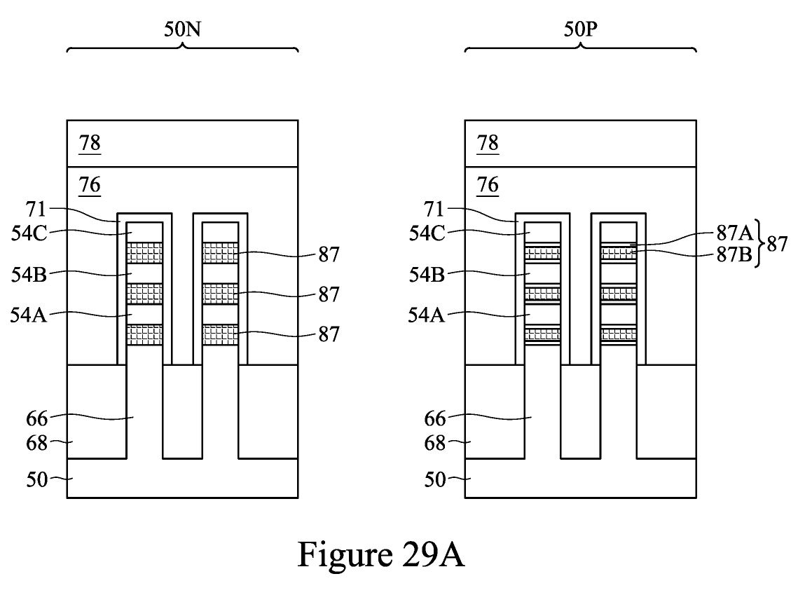

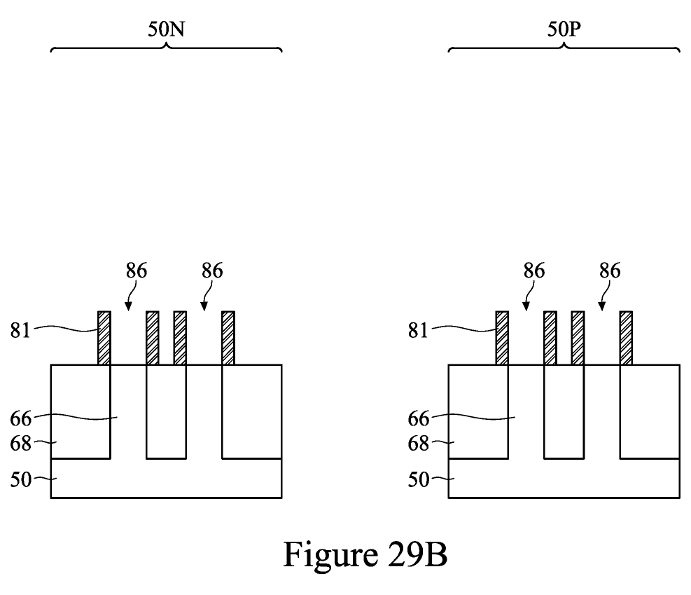

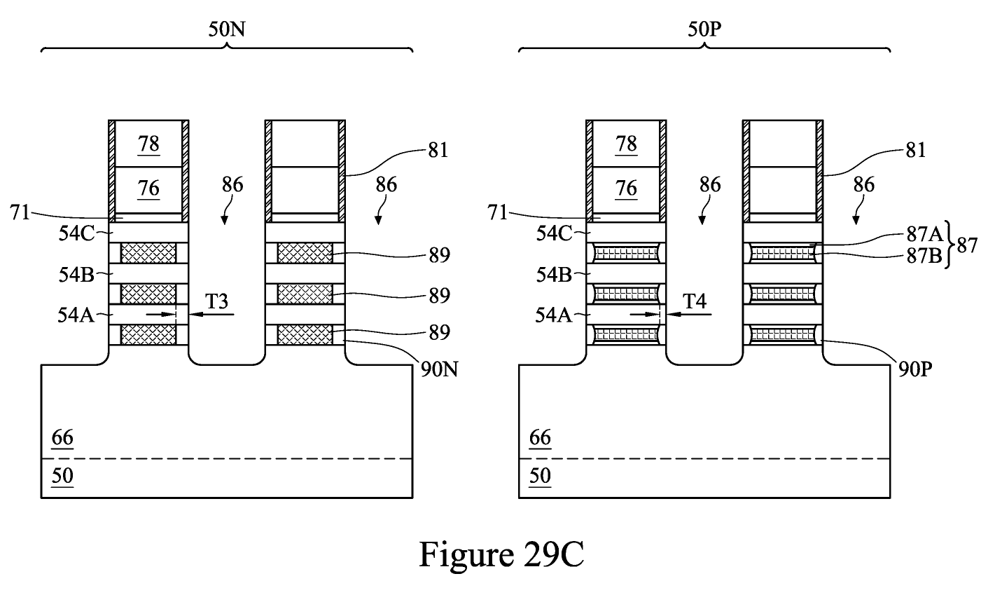

In FIGS. 29A -29C, the inner spacers 90N are formed in the second recesses 88 in the n-type region 50N and the inner spacers 90P are formed in the p-type region 50P. The inner spacers 90N and the inner spacers 90P may be formed of the same or similar materials and by the same or similar methods as the ones described with respect to FIGS. 12A -12C. The inner spacers 90P may extend along sidewalls of the first sacrificial layers 87 in the p-type region 50P and have convex sidewalls in contact with the first sacrificial layers 87. The inner spacers 90N may extend along sidewalls of the second sacrificial layers 89 in the n-type region 50N and have substantially straight sidewalls in contact with the second sacrificial layers 89. The inner spacers 90P and the inner spacers 90N may be in contact with top surfaces and bottom surfaces of the second nanostructures 54, as well as top surfaces of the fins 66.

The inner spacers 90N may have a thickness T3 and the inner spacers 90P may have a thickness T4. The thickness T3 may be a width of top surfaces or bottom surfaces of the inner spacers 90N in contact with the second nanostructures 54 or the fins 66 in the n-type region 50N. The thickness T4 may be a width of top surfaces or bottom surfaces of the inner spacers 90P in contact with the second nanostructures 54 or the fins 66 in the p-type region 50P. The thickness T3 may be larger than the thickness T4, which may lead to sufficient electrical insulation between the subsequently formed source/drain regions and the subsequently formed gate structures as well as reduced resistance in the channel regions (e.g., the second nanostructures 54) in the p-type region 50P as discussed in greater details below. The thickness T3 may be in a range from about 1 nm to about 50 nm. The thickness T4 may be in a range from about 0.5 nm to about 49.5 nm.

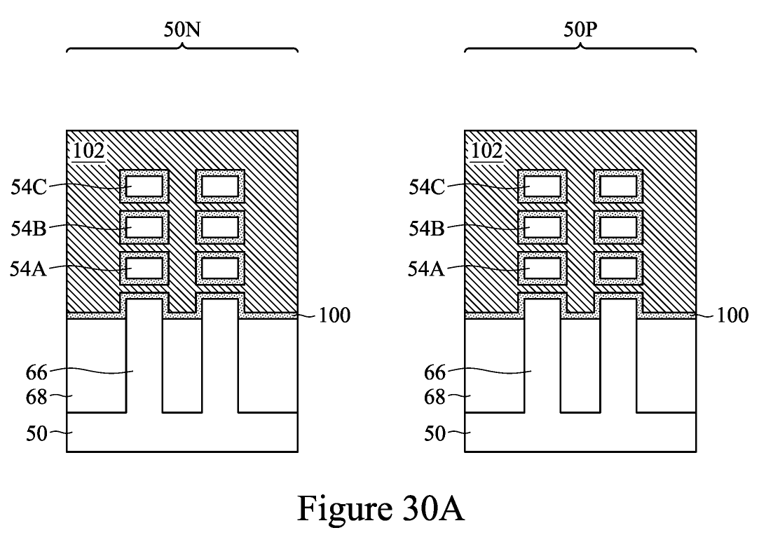

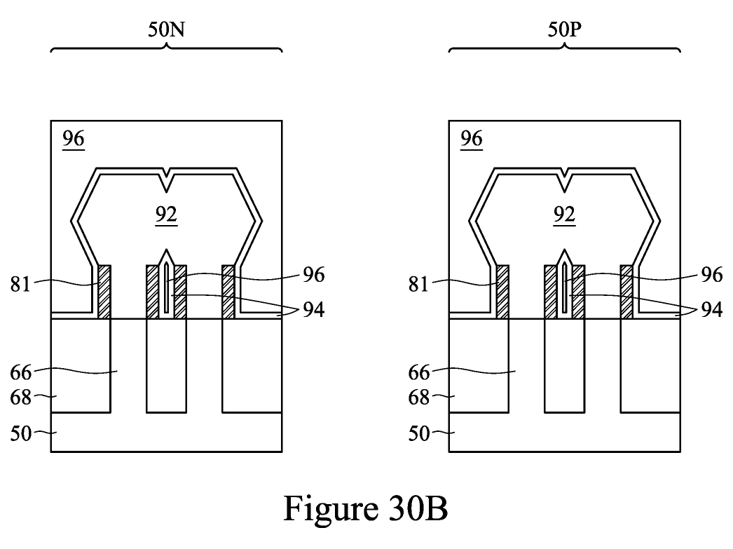

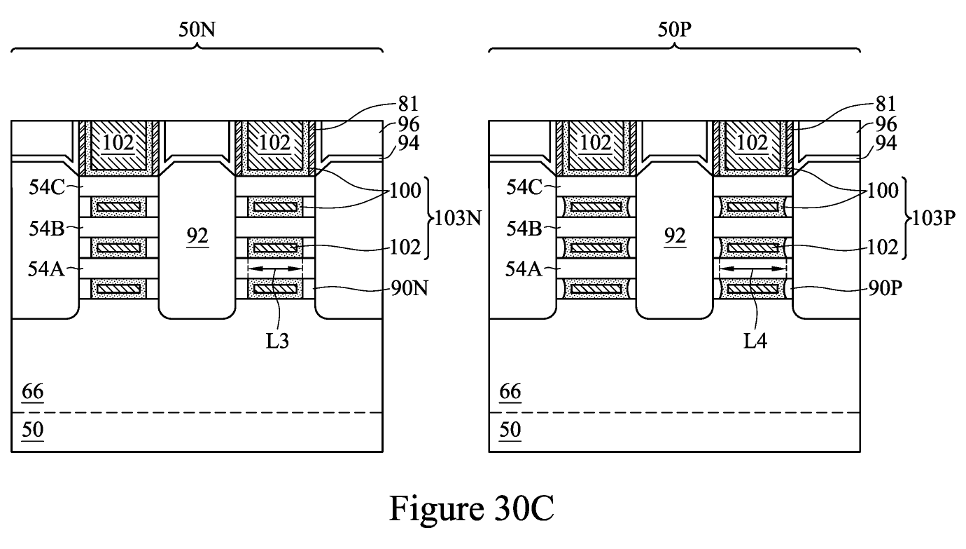

FIGS. 30A -30C illustrate structures same or similar to the ones shown in FIGS. 17A -17C, which may be based on structures formed by the processes same or similar to the ones shown in FIGS. 13A -16C, wherein like numerals refer to like features formed by like processes. In FIGS. 30A -30C, the gate structures 103N are formed in the n-type region 50N and the gate structures 103P are formed in the p-type region 50P. The gate structures 103N and the gate structures 103P may be formed of the same or similar materials and by the same or similar methods as the ones described with respect to FIGS. 17A -17C. In the embodiments illustrated in FIG. 30C, the sidewalls of the gate structures 103P are concave and the sidewalls of the gate structures 103N are substantially straight.

The gate structures 103N may have a length L3 and the gate structures 103P may have a length L4. The length L3 may be a length of top surfaces or bottom surfaces of the gate structures 103N in contact with the second nanostructures 54 or the fins 66 and the length L4 may be a length of top surfaces or bottom surfaces of the gate structures 103P in contact with the second nanostructures 54 or the fins 66. The length L3 may be a distance by which the inner spacers 90N on each side of gate structures 103N are spaced apart and the length L4 may be a distance by which the inner spacers 90P on each side of gate structures 103P are spaced apart. The length L4 may be larger than the length L3, which may lead to closer distances between the epitaxial source/drain regions 92 and the gate structures 103P in the p-type region 50P. As a result, sufficient electrical insulation between the epitaxial source/drain regions 92 and the gate structures 103P as well as reduced resistance in the channel regions (e.g., the second nanostructures 54) in the p-type region 50P may be achieved, thereby improving the performance and reliability of the subsequently formed semiconductor device. The length L3 may be in a range from about 5 nm to about 100 nm. The length L4 may be in a range from about 6 nm to about 101 nm. In some embodiments, the gate structures 103P has a larger volume than the gate structures 103N.

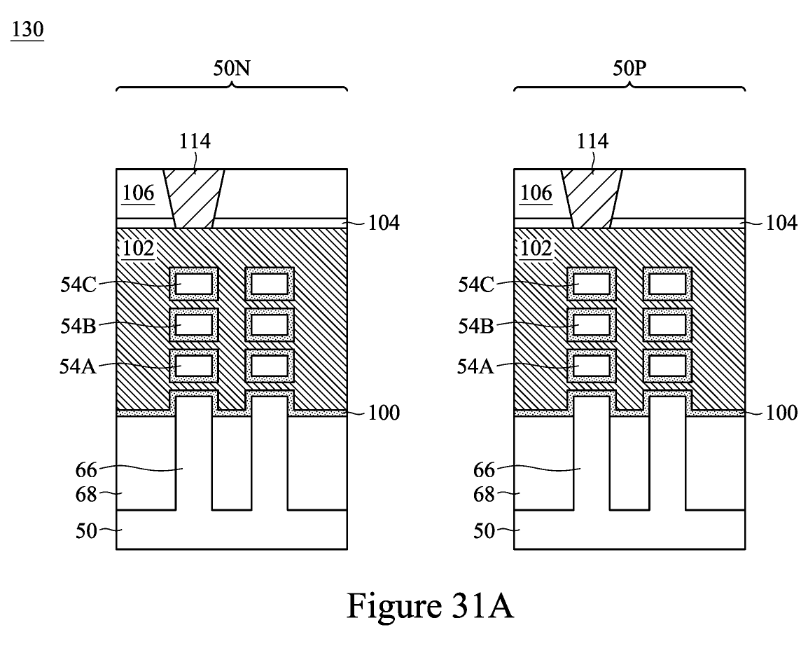

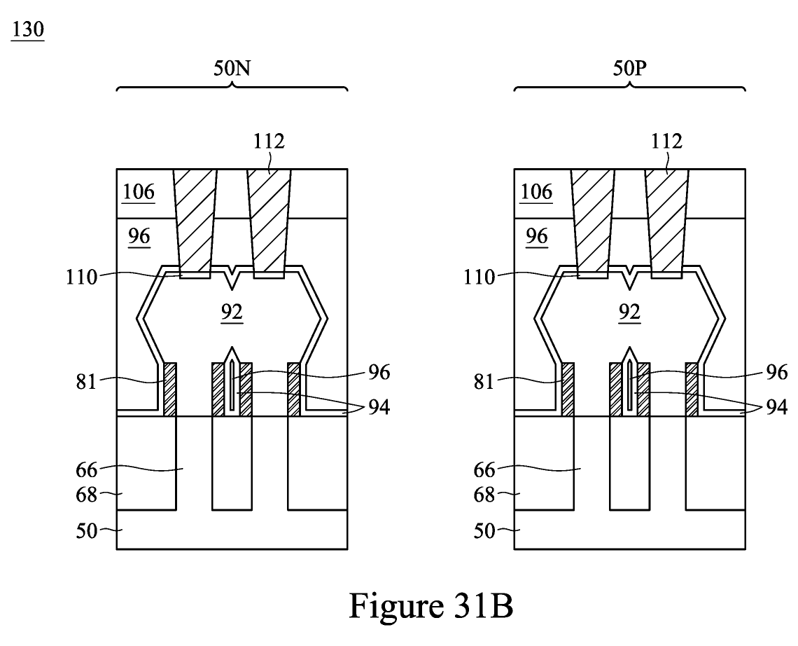

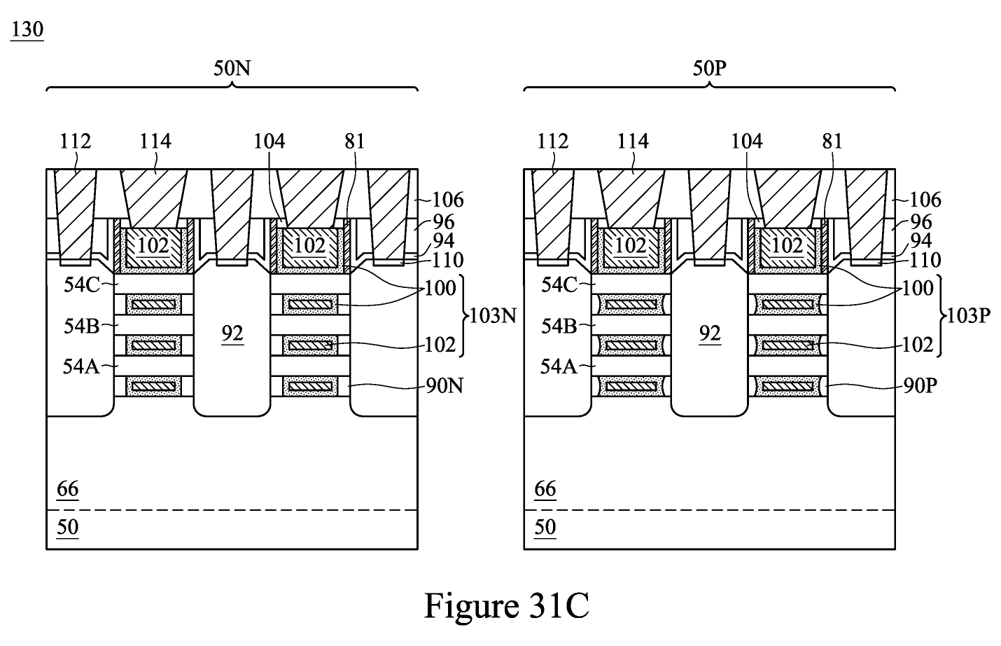

FIGS. 31A -31C illustrate structures same or similar to the ones shown in FIGS. 20A -20C, which may be based on structures formed by the processes same or similar to the ones shown in FIGS. 18A -19C, wherein like numerals refer to like features formed by like processes. In FIGS. 31A -31C, the source/drain contacts 112 and the gate contacts 114, which may be also referred to as the conductive contacts, are formed of the same or similar materials and by the same or similar methods as the ones described with respect to FIGS. 20A -20C. The structure shown in FIGS. 31A -31C may be referred to as a semiconductor device 130.

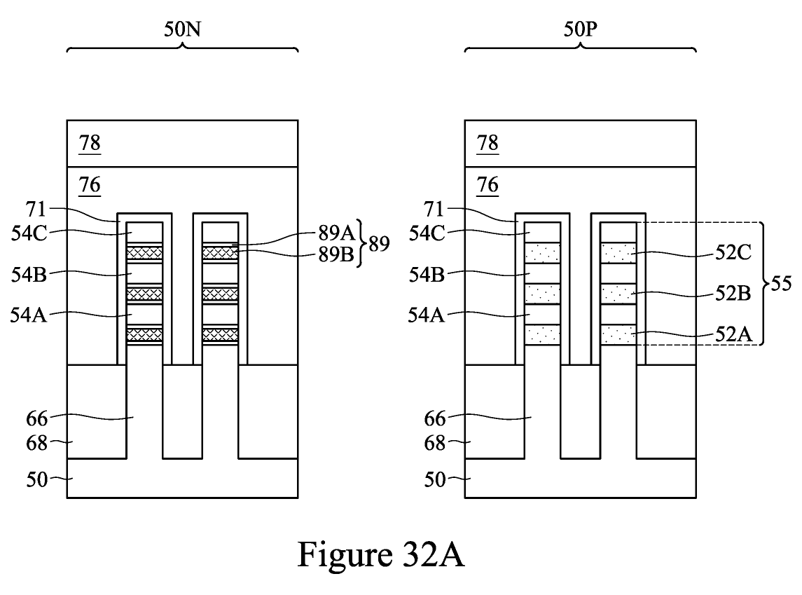

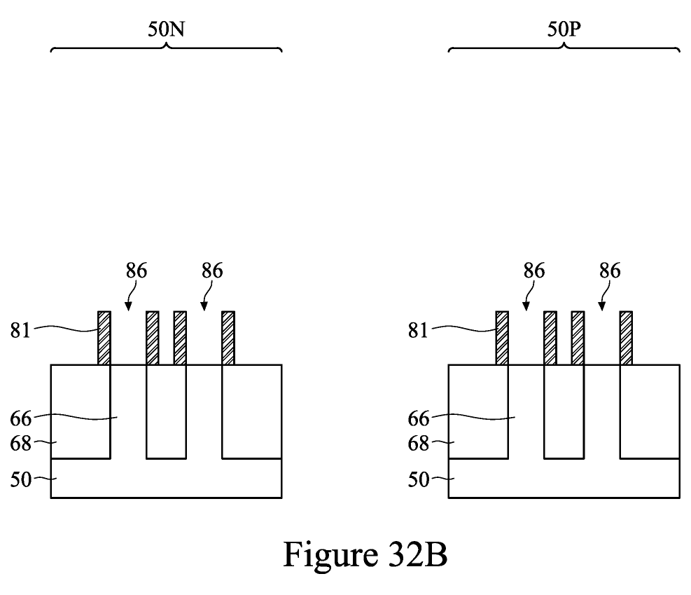

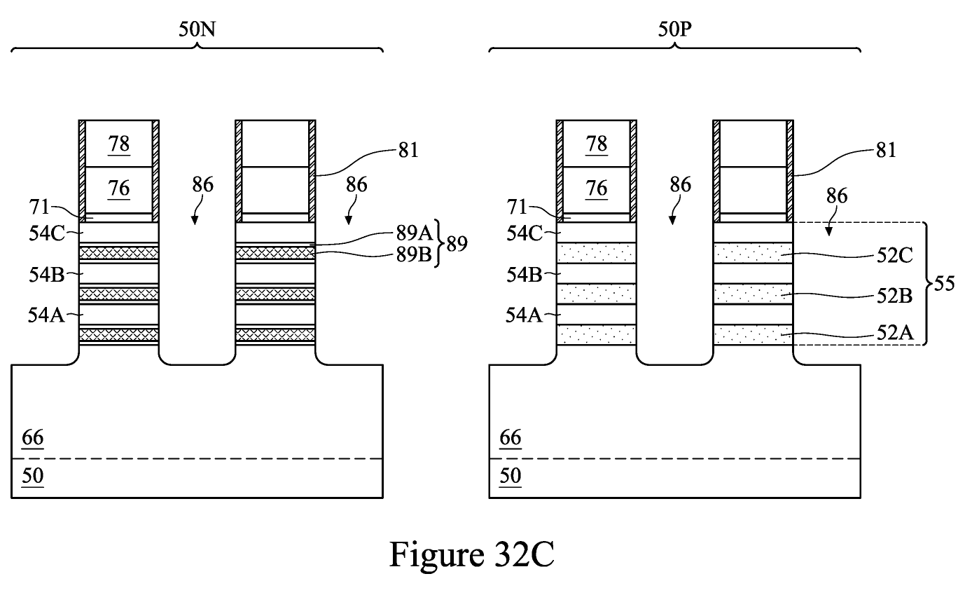

FIGS. 32A -37C are views of intermediate processes of the manufacturing of a semiconductor device (e.g., a nano-FET), in accordance with some embodiments. FIGS. 32A, 33A, 34A, 35A, 36A and 37A illustrate cross-sectional views along the reference cross-section A-A’ illustrated in FIG. 1. FIGS. 32B, 33B, 34B, 35B, 36B and 37B illustrate cross-sectional views along the reference cross-section B-B’ illustrated in FIG. 1. FIGS. 32C, 33C, 34C, 35C, 36C and 37C illustrate cross-sectional views along the reference cross-section C-C’ illustrated in FIG. 1.

FIGS. 32A - 32C illustrate structures same or similar to the ones shown in FIGS. 10A -10C, which may be based on structures formed by the processes same or similar to the ones shown in FIGS. 1 -9C, wherein like numerals refer to like features formed by like processes. In FIGS. 32A -32C, the first nanostructures 52 in the n-type region 50N are replaced with the second sacrificial layers 89, which may include first sublayers 89A and second sublayers 89B of the second sacrificial layers 89. The first sublayers 89A may be in contact with top surfaces and bottom surfaces of the second nanostructures 54, as well as top surfaces of the fins 66. The second sublayers 89B may be between and in contact with neighboring first sublayers 89A between neighboring second nanostructures 54.

The p-type region 50P may be covered and protected by a hard mask (not separately illustrated) during the replacement process. The hard mask may be formed by a suitable photolithography process. The replacement process in the n-type region 50N may include first removing the first nanostructures 52 using a suitable etching process, such as an isotropic etching process, performed through the first recesses 86. The etching process may be a wet or drying etching process using fluorine based chemicals as etchants. The etching process may selectively remove the material of the first nanostructures 52 without significantly removing materials of the second nanostructures 54 or the semiconductor fins 66.

Subsequently, the second sacrificial layers 89 may be formed in spaces where the first nanostructures 52 occupied before being removed in the n-type region 50N. The second sacrificial layers 89 may be formed by first forming the first sublayers 89A on the second nanostructures 54 and then forming the second sublayers 89B on the first sublayers 89A. The first sublayers 89A and the second sublayers 89B may be formed by suitable deposition processes, such as CVD, ALD, or the like, respectively. The hard mask covering and protecting the p-type region 50P may be removed after the replacement process in the n-type region 50N.

The first sublayers 89A and the second sublayers 89B may each comprise a dielectric material, such as silicon nitride, silicon oxide, silicon oxynitride, silicon carbonitride, silicon oxycarbonitride, silicon oxycarbide, or the like, which may have a high etching selectivity to the second nanostructures 54 and other subsequently formed features as described in greater details below. The dielectric material of the first sublayers 89A may have a high etching selectivity to the dielectric material of the second sublayers 89B. In some embodiments, the chemical composition of the dielectric material in the first sublayers 89A is different from the chemical composition of the dielectric material in the second sublayers 89B. In some embodiments, the chemical composition of the dielectric material in the first sublayers 89A is same as the chemical composition of the dielectric material in the second sublayers 89B, and the density of the dielectric material in the first sublayers 89A is lower than the density of the dielectric material in the second sublayers 89B.

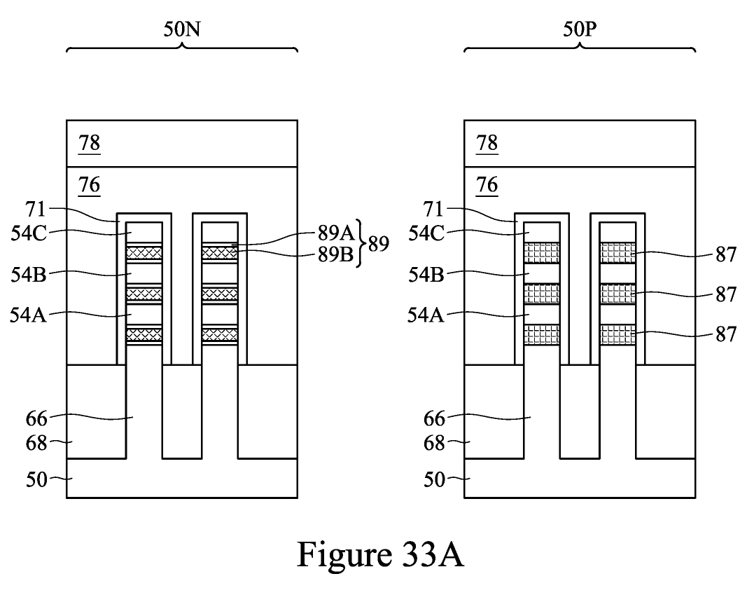

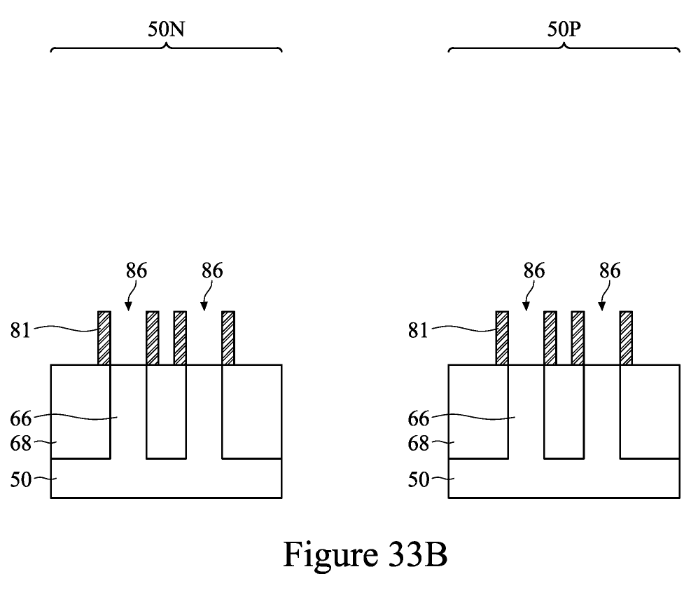

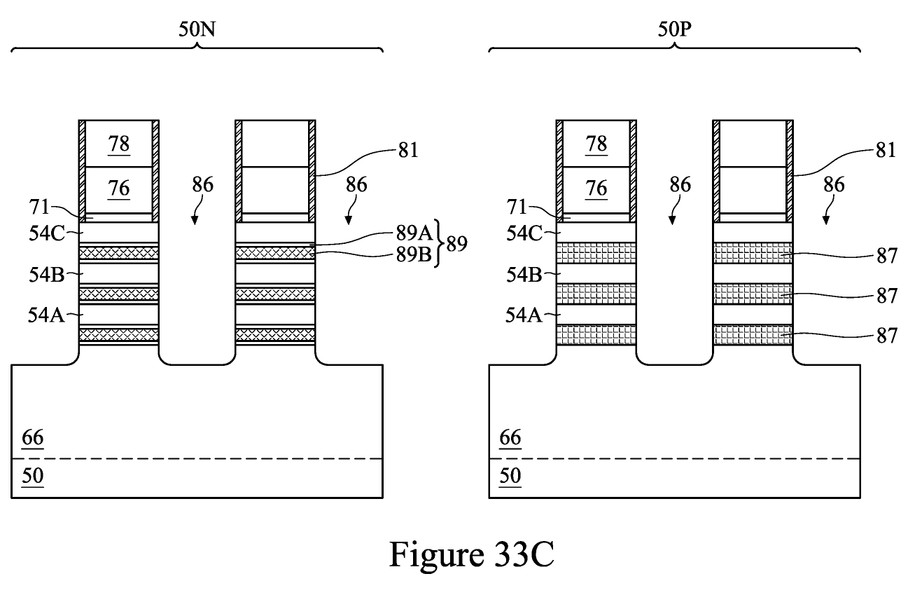

In FIGS. 33A -33C, the first nanostructures 52 in the p-type region 50P are replaced with the first sacrificial layers 87. The first sacrificial layers 87 may be formed of the same or similar materials and by the same or similar methods as the ones described with respect to FIGS. 9A -9C. The first sacrificial layers 87 may comprise a dielectric material, such as silicon nitride, silicon oxide, silicon oxynitride, silicon carbonitride, silicon oxycarbonitride, silicon oxycarbide, or the like, which may have a high etching selectivity to the second nanostructures 54, the second sacrificial layers 89, and other subsequently formed features as described in greater details below. In some embodiments, the chemical composition of the dielectric material in the first sacrificial layers 87 is different from the chemical composition of the dielectric material in the first sublayers 89A and/or the dielectric material in the second sublayers 89B. In some embodiments, the chemical composition of the dielectric material in the first sacrificial layers 87 is same as the dielectric material in the first sublayers 89A and/or the dielectric material in the second sublayers 89B, and the density of the dielectric material in the first sacrificial layers 87 is higher than the density of the dielectric material in the first sublayers 89A and/or the dielectric material in the second sublayers 89B.

FIGS. 32A -33C illustrate forming the second sacrificial layers 89 in the n-type region 50N before forming the first sacrificial layers 87 in the p-type region 50P as an example. In some embodiments, the second sacrificial layers 89 are formed in the n-type region 50N after the first sacrificial layers 87 are formed in the p-type region 50P.

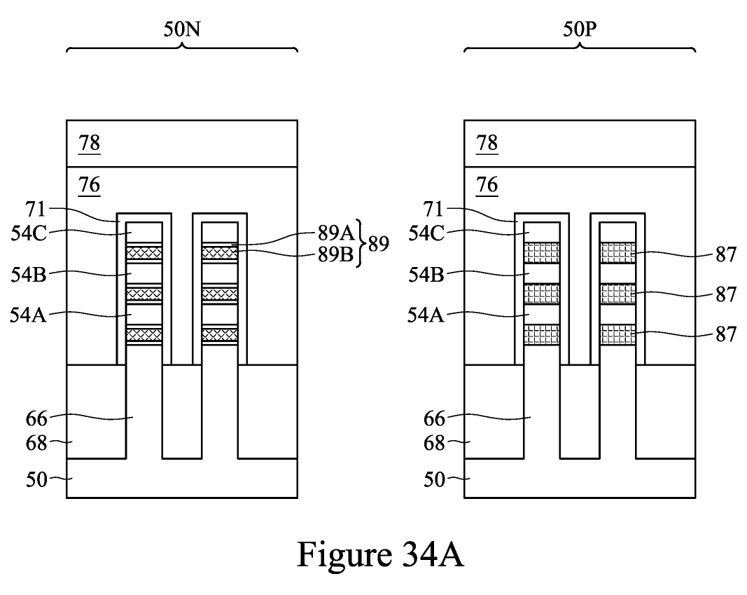

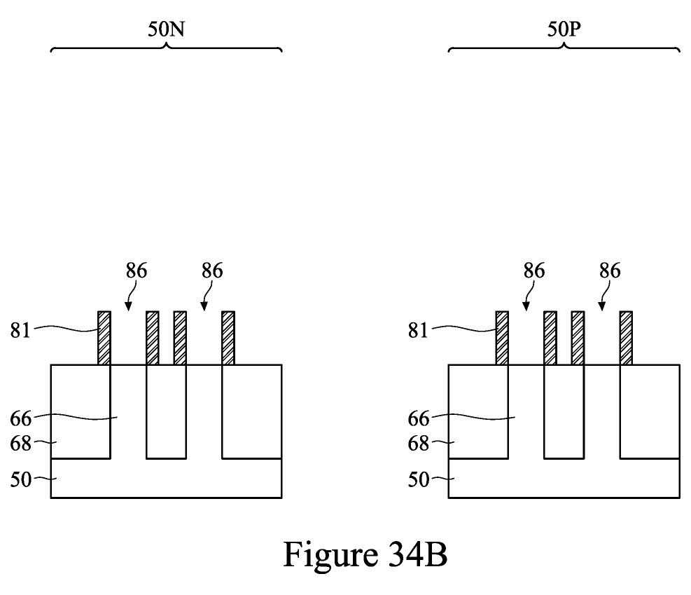

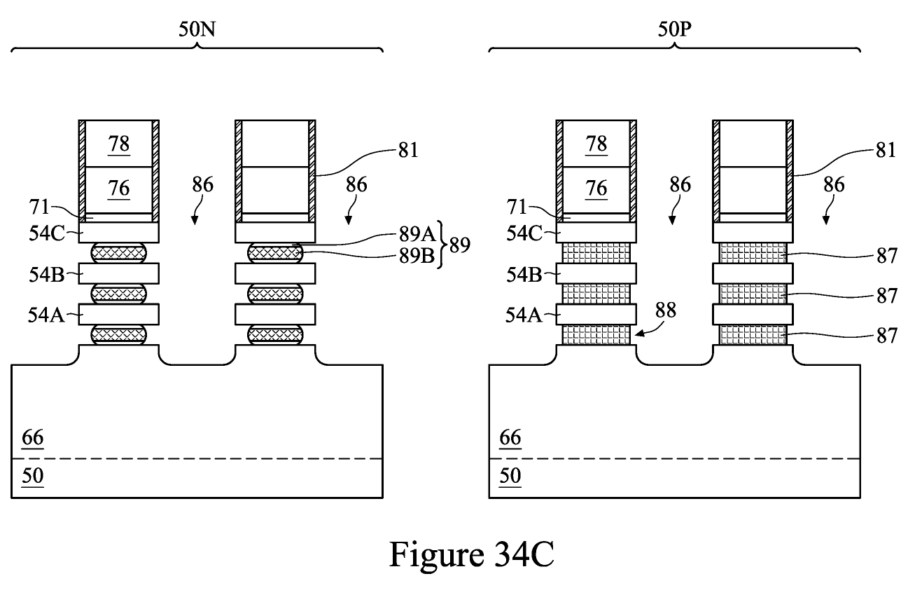

In FIGS. 34A -34C, the first sacrificial layers 87 in the p-type region 50P and the second sacrificial layers 89, including the first sublayers 89A and the second sublayers 89B, in the n-type region 50N are partially removed by an etching process to form second recesses 88. During the etching process, the first sublayers 89A may be etched at a faster rate than the second sublayers 89B, the first sacrificial layers 87 may be etched at a slower rate than the first sublayers 89A and/or the second sublayers 89B, and the second nanostructures 54 and the semiconductor fins 66 may be substantially intact. After the etching process, sidewalls of the first sacrificial layers 87 may be recessed from sidewalls of the second nanostructures 54 in the p-type region 50P and sidewalls of the second sacrificial layers 89 may be recessed from sidewalls of the second nanostructures 54 in the n-type region 50N. The second sacrificial layers 89 may be further recessed than the first sacrificial layers 87. The first sacrificial layers 87 may be wider than the second sacrificial layers 89. In the embodiments illustrated in FIG. 34C, the sidewalls of the first sacrificial layers 87 are substantially straight and the sidewalls of the second sacrificial layers 89 are convex. The etching process may be a wet or drying isotropic etching process using fluorine based chemicals as etchants.

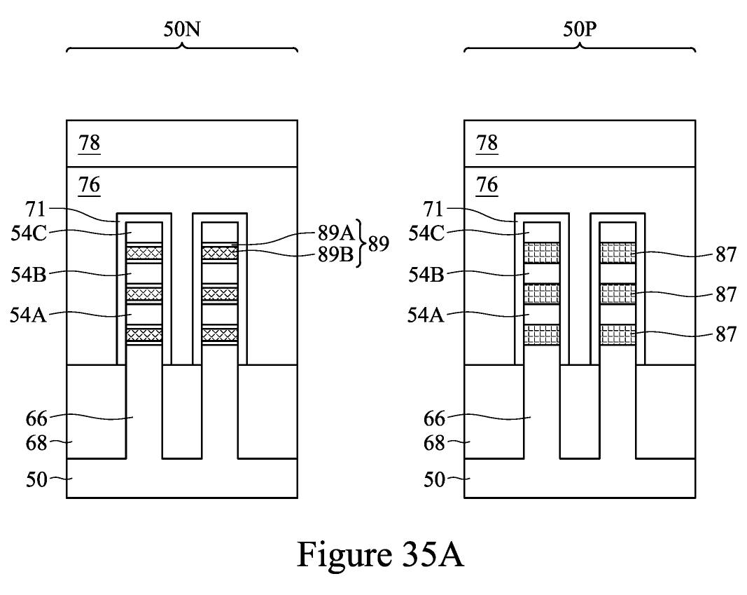

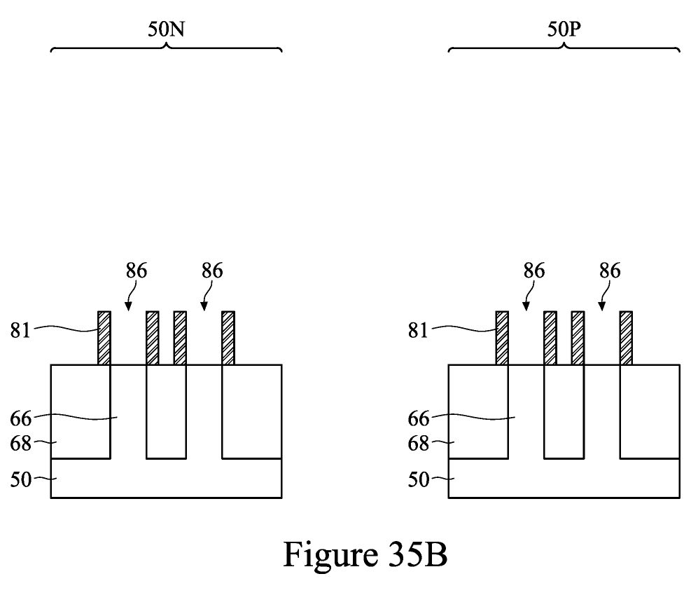

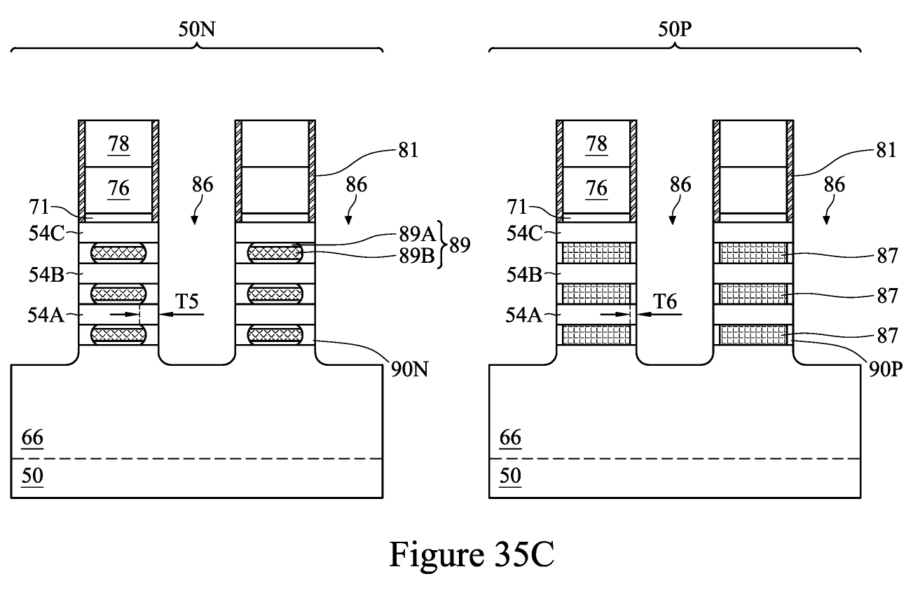

In FIGS. 35A -35C, the inner spacers 90N are formed in the second recesses 88 in the n-type region 50N and the inner spacers 90P are formed in the p-type region 50P. The inner spacers 90N and the inner spacers 90P may be formed of the same or similar materials and by the same or similar methods as the ones described with respect to FIGS. 12A -12C. The inner spacers 90P may extend along sidewalls of the first sacrificial layers 87 in the p-type region 50P and have substantially straight sidewalls in contact with the first sacrificial layers 87. The inner spacers 90N may extend along sidewalls of the second sacrificial layers 89 in the n-type region 50N and have concave sidewalls in contact with the second sacrificial layers 89. The inner spacers 90P and the inner spacers 90N may be in contact with top surfaces and bottom surfaces of the second nanostructures 54, as well as top surfaces of the fins 66.

The inner spacers 90N may have a thickness T5 and the inner spacers 90P may have a thickness T6. The thickness T5 may be a width of top surfaces or bottom surfaces of the inner spacers 90N in contact with the second nanostructures 54 or the fins 66 in the n-type region 50N. The thickness T6 may be a width of top surfaces or bottom surfaces of the inner spacers 90P in contact with the second nanostructures 54 or the fins 66 in the p-type region 50P. The thickness T5 may be larger than the thickness T6, which may lead to sufficient electrical insulation between the subsequently formed source/drain regions and the subsequently formed gate structures as well as reduced resistance in the channel regions (e.g., the second nanostructures 54) in the p-type region 50P as discussed in greater details below. The thickness T5 may be in a range from about 1 nm to about 50 nm. The thickness T6 may be in a range from about 0.5 nm to about 49.5 nm.

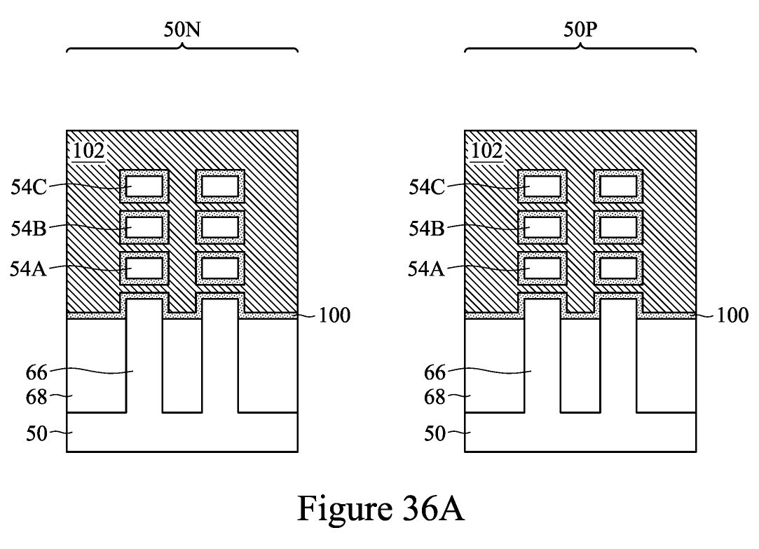

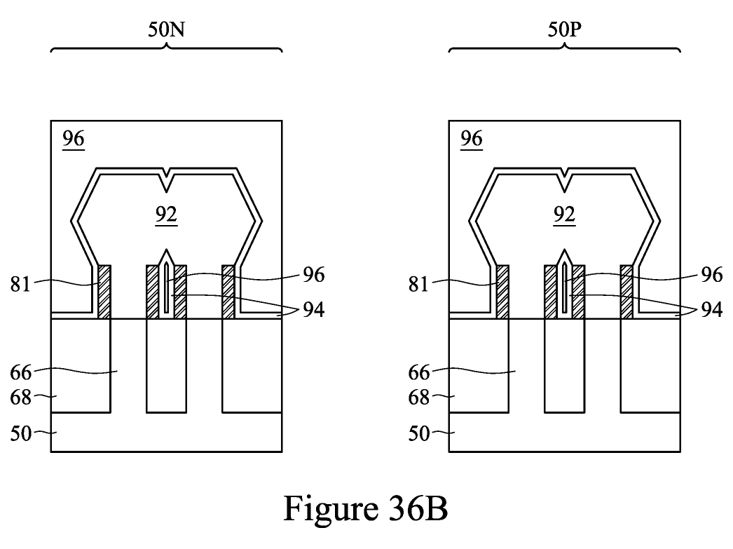

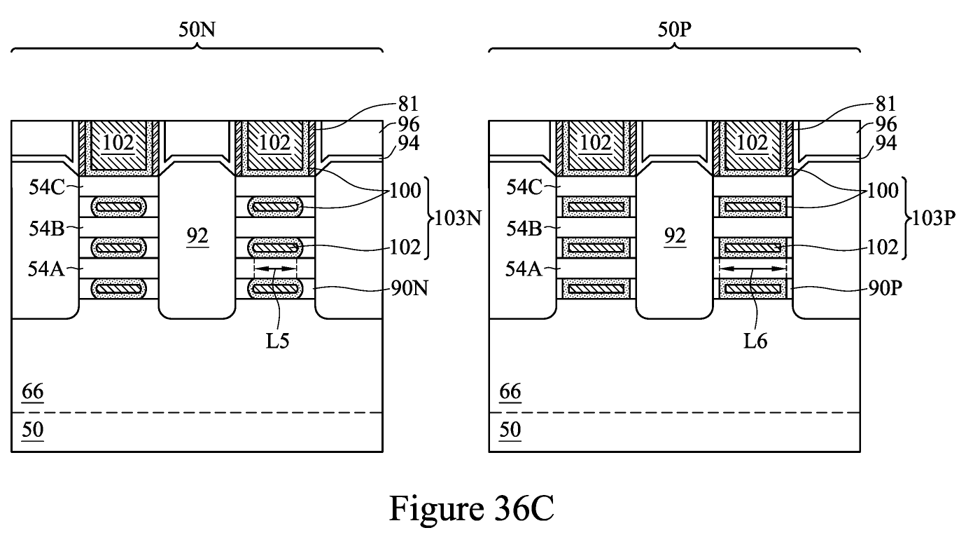

FIGS. 36A -36C illustrate structures same or similar to the ones shown in FIGS. 17A -17C, which may be based on structures formed by the processes same or similar to the ones shown in FIGS. 13A -16C, wherein like numerals refer to like features formed by like processes. In FIGS. 36A -36C, the gate structures 103N are formed in the n-type region 50N and the gate structures 103P are formed in the p-type region 50P. The gate structures 103N and the gate structures 103P may be formed of the same or similar materials and by the same or similar methods as the ones described with respect to FIGS. 17A -17C. In the embodiments illustrated in FIG. 36C, the sidewalls of the gate structures 103P are substantially straight and the sidewalls of the gate structures 103N are convex.

The gate structures 103N may have a length L5 and the gate structures 103P may have a length L6. The length L5 may be a length of top surfaces or bottom surfaces of the gate structures 103N in contact with the second nanostructures 54 or the fins 66 and the length L6 may be a length of top surfaces or bottom surfaces of the gate structures 103P in contact with the second nanostructures 54 or the fins 66. The length L5 may be a distance by which the inner spacers 90N on each side of gate structures 103N are spaced apart and the length L6 may be a distance by which the inner spacers 90P on each side of gate structures 103P are spaced apart. The length L6 may be larger than the length L5, which may lead to closer distances between the epitaxial source/drain regions 92 and the gate structures 103P in the p-type region 50P. As a result, sufficient electrical insulation between the epitaxial source/drain regions 92 and the gate structures 103P as well as reduced resistance in the channel regions (e.g., the second nanostructures 54) in the p-type region 50P may be achieved, thereby improving the performance and reliability of the subsequently formed semiconductor device. The length L5 may be in a range from about 5 nm to about 100 nm. The length L6 may be in a range from about 6 nm to about 101 nm. In some embodiments, the gate structures 103P has a larger volume than the gate structures 103N.

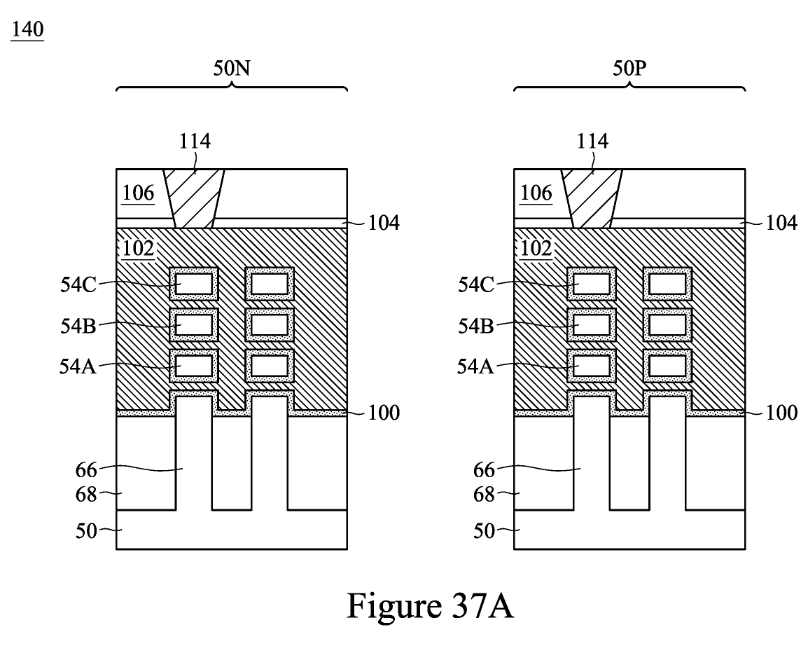

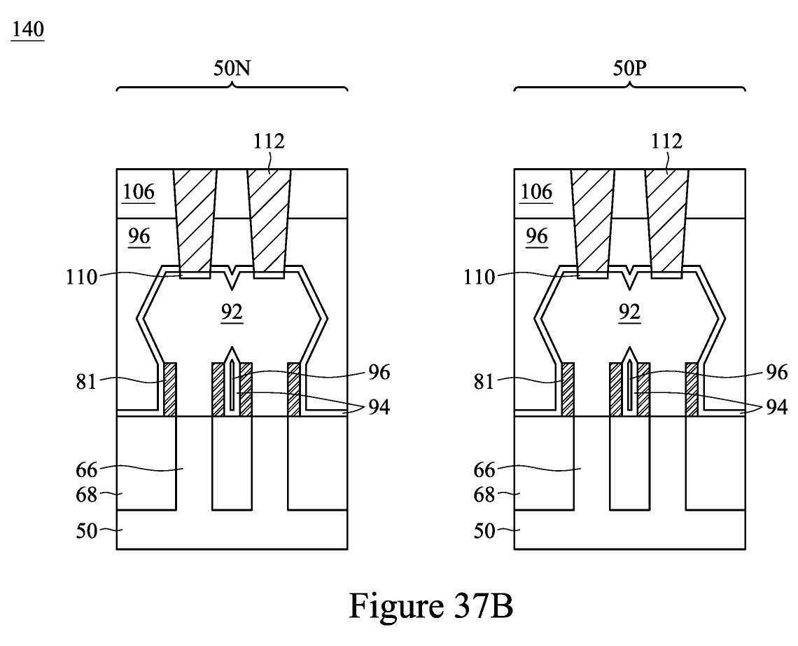

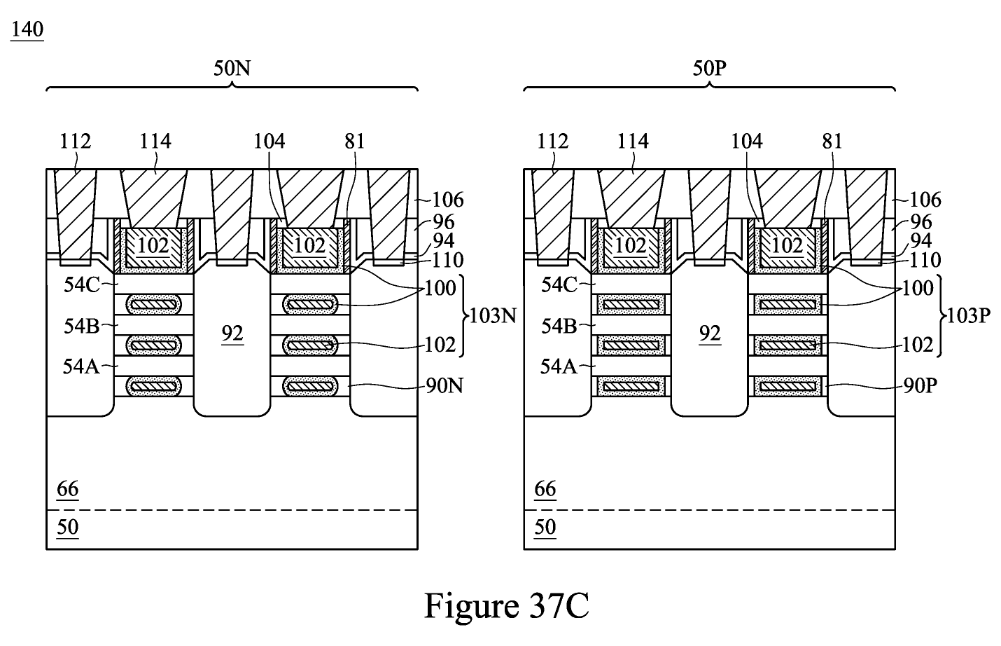

FIGS. 37A - 37C illustrate structures same or similar to the ones shown in FIGS. 20A -20C, which may be based on structures formed by the processes same or similar to the ones shown in FIGS. 18A -19C, wherein like numerals refer to like features formed by like processes. In FIGS. 37A -37C, the source/drain contacts 112 and the gate contacts 114, which may be also referred to as the conductive contacts, are formed of the same or similar materials and by the same or similar methods as the ones described with respect to FIGS. 20A -20C. The structure shown in FIGS. 37A -37C may be referred to as a semiconductor device 140.

The gate structures 103N in the n-type region 50N are described above to have substantially straight or convex sidewalls as examples. In some embodiments, the sidewalls of the gate structures 103N are concave. The inner spacers 90N in the n-type region 50N are described above to have substantially straight or concave sidewalls as examples. In some embodiments, the sidewalls of the inner spacers 90N are convex. The gate structures 103P in the p-type region 50P are described above to have substantially straight or concave sidewalls as examples. In some embodiments, the sidewalls of the gate structures 103N are convex. The inner spacers 90P in the p-type region 50P are described above to have substantially straight or convex sidewalls as examples. In some embodiments, the sidewalls of the inner spacers 90P are concave.

The embodiments of the present disclosure have some advantageous features. By forming the inner spacers 90P and the gate structures 103P with certain shapes and sizes, sufficient electrical insulation between the epitaxial source/drain regions 92 and the gate structures 103P as well as reduced resistance in the channel regions (e.g., the second nanostructures 54) in the p-type region 50P may be achieved, thereby improving the performance and reliability of the semiconductor devices 120, 130, and 140.

In an embodiment, a semiconductor device includes a first region, including: a first nanostructure and a second nanostructure; a first gate structure between the first nanostructure and the second nanostructure, wherein the first gate structure has a first length; a first dielectric layer on a sidewall of the first gate structure; and a first source/drain region, wherein the first nanostructure, the second nanostructure, and the first dielectric layer are adjacent to the first source/drain region; and a second region, including: a third nanostructure and a fourth nanostructure; a second gate structure between the third nanostructure and the fourth nanostructure, wherein the second gate structure has a second length, and wherein the second length is larger than the first length; a second dielectric layer on a sidewall of the second gate structure, wherein the first dielectric layer and the second dielectric layer include a same material; and a second source/drain region, wherein the third nanostructure, the fourth nanostructure, and the second dielectric layer are adjacent to the second source/drain region. In an embodiment, the sidewall of the first gate structure is straight and the sidewall of the second gate structure is straight. In an embodiment, the sidewall of the first gate structure is straight and the sidewall of the second gate structure is concave. In an embodiment, the sidewall of the first gate structure is convex and the sidewall of the second gate structure is straight. In an embodiment, the first dielectric layer has a first thickness, wherein the second dielectric layer has a second thickness, and wherein the second thickness is smaller than the first thickness. In an embodiment, a first top surface of the first dielectric layer is in contact with the second nanostructure, wherein the first thickness is equal to a first width of the first top surface, wherein a second top surface of the second dielectric layer is in contact with the fourth nanostructure, and wherein the second thickness is equal to a second width of the second top surface. In an embodiment, the first region is an n-type region and the second region is a p-type region.

In an embodiment, a semiconductor device including: an first region, including: a first nanostructure; a first gate structure on the first nanostructure, wherein the first gate structure has a first width at an interface between the first nanostructure and the first gate structure; and a first spacer layer on the first nanostructure, wherein a first portion of the first spacer layer is on a first side of the first gate structure and a second portion of the first spacer layer is on a second side of the first gate structure; and a second region, including: a second nanostructure; a second gate structure on the second nanostructure, wherein the second gate structure has a second width at an interface between the second nanostructure and the second gate structure, and wherein the second width is larger than the first width; and a second spacer layer on the second nanostructure, wherein a first portion of the second spacer layer is on a first side of the second gate structure and a second portion of the second spacer layer is on a second side of the second gate structure. In an embodiment, the first portion of the first spacer layer has a straight sidewall in contact with the first gate structure and the first portion of the second spacer layer has a convex sidewall in contact with the second gate structure. In an embodiment, the first portion of the first spacer layer has a concave sidewall in contact with the first gate structure and the first portion of the second spacer layer has a straight sidewall in contact with the second gate structure. In an embodiment, the first portion of the first spacer layer has a third width at an interface between the first nanostructure and the first portion of the first spacer layer, wherein the first portion of the second spacer layer has a fourth width at an interface between the second nanostructure and the first portion of the second spacer layer, and wherein the fourth width is smaller than the third width. In an embodiment, the first portion of the first spacer layer is spaced apart from the second portion of the first spacer layer by a first distance, wherein the first portion of the second spacer layer is spaced apart from the second portion of the second spacer layer by a second distance, and wherein the second distance is larger than the first distance. In an embodiment, the first region is an n-type region and the second region is a p-type region.

In an embodiment, a method of forming a semiconductor device includes forming a first nanostructure in a first region and a second nanostructure in a second region; forming a first sacrificial layer on the first nanostructure in the first region and forming a second sacrificial layer on the second nanostructure in the second region, wherein the first sacrificial layer includes a first material and the second sacrificial layer includes a second material; forming a first spacer layer on the first nanostructure along a sidewall of the first sacrificial layer in the first region and forming a second spacer layer on the second nanostructure along a sidewall of the second sacrificial layer in the second region, wherein the first spacer layer has a larger thickness than the second spacer layer; and forming a first source/drain structure in the first region and a second source/drain structure in the second region, wherein the first source/drain structure is in contact with the first nanostructure and the first spacer layer, and wherein the second source/drain structure is in contact with the second nanostructure and the second spacer layer. In an embodiment, the first material and the second material have a same chemical composition. In an embodiment, the first material and the second material have different chemical compositions. In an embodiment, the second sacrificial layer further includes a first sublayer and a second sublayer, and wherein the sidewall of the first sacrificial layer is straight and the sidewall of the second sacrificial layer is concave. In an embodiment, the first sacrificial layer further includes a first sublayer and a second sublayer, and wherein the sidewall of the first sacrificial layer is convex and the sidewall of the second sacrificial layer is straight. In an embodiment, the method further includes removing the first sacrificial layer and forming a first gate structure on the first nanostructure in the first region, and removing the second sacrificial layer and forming a second gate structure on the second nanostructure in the second region, wherein the first gate structure is in contact with the first spacer layer and the second gate structure is in contact with the second spacer layer. In an embodiment, the first gate structure is wider than the second gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first region, comprising:
a first nanostructure and a second nanostructure over the first nanostructure;
a first gate structure between the first nanostructure and the second nanostructure;
a first source/drain region adjacent to the first nanostructure and the second nanostructure; and
a first inner spacer between the first gate structure and the first source/drain region, wherein the first inner spacer is in contact with a top surface of the first nanostructure and a bottom surface of the second nanostructure, wherein the first inner spacer has a first sidewall in contact with the first gate structure, wherein the first sidewall is substantially straight, and wherein the first inner spacer has a first thickness; and
a second region, comprising:
a third nanostructure and a fourth nanostructure over the third nanostructure;
a second gate structure between the third nanostructure and the fourth nanostructure;
a second source/drain region adjacent to the third nanostructure and the fourth nanostructure; and
a second inner spacer between the second gate structure and the second source/drain region, wherein the second inner spacer is in contact with a top surface of the third nanostructure and a bottom surface of the fourth nanostructure, wherein the second inner spacer has a second sidewall in contact with the second gate structure, wherein the second sidewall is convex, and wherein the second inner spacer has a second thickness smaller than the first thickness.

2. The semiconductor device of claim 1, wherein the second gate structure has a length larger than a length of the first gate structure.

3. The semiconductor device of claim 1, wherein a sidewall of the first gate structure is substantially straight and a sidewall of the second gate structure is concave.

4. The semiconductor device of claim 1, wherein the second gate structure has a volume larger than a volume of the first gate structure.

5. The semiconductor device of claim 1, further comprising a first fin and a second fin, wherein the first nanostructure is over the first fin and the third nanostructure is over the second fin, wherein the first inner spacer is in contact with a top surface of the first fin and the second inner spacer is in contact with a top surface of the second fin.

6. The semiconductor device of claim 1, wherein the first region is an n-type region and the second region is a p-type region.

7. The semiconductor device of claim 1, wherein the first source/drain region comprises a first liner layer, a second liner layer on the first liner layer, and a fill layer on the second liner layer.

8. The semiconductor device of claim 1, wherein the first thickness is equal to a width of a top surface of the first inner spacer in contact with the second nanostructure, and the second thickness is equal to a width of a top surface of the second inner spacer in contact with the fourth nanostructure.

9. A method of forming a semiconductor device, the method comprising:
forming a first fin in a first region and a second fin in a second region, the first fin having alternating first nanostructures and second nanostructures over the first fin, and the second fin having alternating third nanostructures and fourth nanostructures over the second fin;
forming a first recess through the first nanostructures and the second nanostructures in the first region, and forming a second recess through the third nanostructures and the fourth nanostructures in the second region;
replacing the first nanostructures with first sacrificial layers in the first region and replacing the third nanostructures with second sacrificial layers in the second region, wherein the first sacrificial layers and the second sacrificial layers comprise dielectric materials;
partially removing the first sacrificial layers and the second sacrificial layers, wherein after the partially removing, the first sacrificial layers are recessed further than the second sacrificial layers;
forming first inner spacers along sidewalls of the first sacrificial layers and forming second inner spacers along sidewalls of the second sacrificial layers, wherein the first inner spacers have a thickness larger than a thickness of the second inner spacers;
forming a first source/drain structure in the first recess and a second source/drain structure in the second recess; and
removing the first sacrificial layers and forming a first gate structure between the second nanostructures in the first region, and removing the second sacrificial layers and forming a second gate structure between the fourth nanostructures in the second region, wherein the second gate structure has a length larger than a length of the first gate structure.

10. The method of claim 9, wherein the first sacrificial layers and the second sacrificial layers have a same chemical composition, and a density of the second sacrificial layers is higher than a density of the first sacrificial layers.

11. The method of claim 9, wherein the first sacrificial layers and the second sacrificial layers have different chemical compositions.

12. The method of claim 9, wherein after the partially removing, sidewalls of the first sacrificial layers and sidewalls of the second sacrificial layers are substantially straight.

13. The method of claim 9, wherein the first inner spacers are in contact with top surfaces and bottom surfaces of the second nanostructures and a top surface of the first fin, and the second inner spacers are in contact with top surfaces and bottom surfaces of the fourth nanostructures and a top surface of the second fin.

14. The method of claim 9, wherein the first region is an n-type region and the second region is a p-type region.

15. The method of claim 9, wherein partially removing the first sacrificial layers and the second sacrificial layers comprises forming a mask over the second region, etching the first sacrificial layers in the first region while the second region is protected by the mask, removing the mask, and then etching the first sacrificial layers in the first region and the second sacrificial layers in the second region.

16. A method of forming a semiconductor device, the method comprising:
forming a first fin in a first region and a second fin in a second region, the first fin having alternating first nanostructures and second nanostructures over the first fin, and the second fin having alternating third nanostructures and fourth nanostructures over the second fin;
forming a first recess through the first nanostructures and the second nanostructures in the first region, and forming a second recess through the third nanostructures and the fourth nanostructures in the second region;
replacing the first nanostructures with first sacrificial layers in the first region, wherein forming the first sacrificial layers comprises forming first sublayers on the second nanostructures and forming second sublayers on the first sublayers, the second sublayers being between neighboring first sublayers, and wherein the first sublayers and the second sublayers have different etch rates;
replacing the third nanostructures with second sacrificial layers in the second region;
partially removing the first sacrificial layers and the second sacrificial layers by an etching process to form recesses, wherein during the etching process the second sublayers are removed at a faster rate than the first sublayers, and wherein after the etching process, sidewalls of the first sacrificial layers are concave and sidewalls of the second sacrificial layers are substantially straight;
forming first inner spacers along the sidewalls of the first sacrificial layers and forming second inner spacers along the sidewalls of the second sacrificial layers, wherein the second inner spacers have a thickness larger than a thickness of the first inner spacers; and
removing the first sacrificial layers and forming a first gate structure between the second nanostructures in the first region, and removing the second sacrificial layers and forming a second gate structure between the fourth nanostructures in the second region.

17. The method of claim 16, wherein the first sublayers and the second sublayers have a same chemical composition, and a density of the first sublayers is higher than a density of the second sublayers.

18. The method of claim 16, wherein the first sublayers and the second sublayers have different chemical compositions.

19. The method of claim 16, wherein the first gate structure has a length larger than a length of the second gate structure.

20. The method of claim 16, wherein a sidewall of the first gate structure is concave and a sidewall of the second gate structure is substantially straight.
